(19) United States
(12) Patent Application Publication
(10) Pub. No.: US 2024/0059616 A1
(43) Pub. Date: Feb. 22, 2024

(54) PLASMA RESISTANT YTTRIUM ALUMINUM OXIDE CHAMBER COMPONENTS

(71) Applicant: Heraeus Conamic North America LLC, Chandler, AZ (US)

(72) Inventors: Matthew Joseph DONELON, Chandler, AZ (US); Luke WALKER, Chandler, AZ (US); Saurav BISTA, Chandler, AZ (US); Saurabh WAGHMARE, Chandler, AZ (US); Lillian THOMPSON, Chandler, AZ (US)

(21) Appl. No.: 18/257,203

(22) PCT Filed: Dec. 17, 2021
(86) PCT No.: PCT/US2021/064054

§ 371 Date: Jun. 13, 2023

Related U.S. Application Data
(60) Provisional application No. 63/127,984, filed on Dec. 18, 2020.
(60) Provisional application No. 63/131,010, filed on Dec. 28, 2020.
(60) Provisional application No. 63/177,232, filed on Apr. 20, 2021.

(51) Int. Cl. C04B 35/119; C04B 35/44; H01J 37/32; C04B 38/00

(52) U.S. Cl. CPC C04B 35/119; C04B 35/44; H01J 37/32119; H01J 37/32642; C04B 38/0054; H01J 37/3244; C04B 2235/94; C04B 2235/3222; C04B 2235/3246

(57) ABSTRACT

Disclosed herein are plasma chamber components that comprise a ceramic sintered body comprising at least one first layer comprising a surface having a surface area and at least one crystalline phase of from 90% to 99.8% by volume of poly crystalline yttrium aluminum garnet (YAG), at least one second layer comprising alumina and zirconia wherein the zirconia comprises at least one of stabilized and partially stabilized zirconia, and optionally, at least one third layer comprising at least one selected from the group consisting of YAG, alumina, and zirconia.

### FIELD

The disclosure relates to a ceramic sintered body comprising an outer layer comprising one or more forms of yttrium aluminum oxides, to include Y₃Al₅O₁₂ (YAG, garnet phase), YAlO₃ (YAP, perovskite phase), and Y₄Al₂O₉ (YAM, monoclinic phase), and optionally aluminum oxide (Al₂O₃) and/or yttrium oxide (Y₂O₃).

The disclosure also relates to a ceramic sintered body comprising highly phase pure (>98% by volume) Y₃Al₅O₁₂ (YAG, garnet phase) having high purity, high density and low volumetric porosity.

The disclosure also relates to a ceramic sintered body comprising phase pure (>95% by volume) Y₃Al₅O₁₂ (YAG, garnet phase) further comprising an aluminum oxide (Al₂O₃) phase and/or a yttrium oxide (Y₂O₃) phase in amounts of 5% and less by volume which has high purity, high density and low volumetric porosity.

The properties of high density, low volumetric porosity and high purity translate into exceptional etch resistance when used as a component in a plasma etch chamber. Moreover, the present disclosure provides a process for making the ceramic sintered body.

### BACKGROUND

Semiconductor processing requires the use of halogen-based gases as well as oxygen and other gases in combination with high electric and magnetic fields to create a plasma etch environment. This plasma etch environment is made within vacuum chambers for etching materials on semiconductor substrates. The harsh plasma etch environment necessitates the use of highly corrosion resistant materials for chamber components. These chambers include component parts such as disks or windows, liners, gas injectors, rings, and cylinders that confine the plasma over the wafer being processed. These components have been formed from materials that provide resistance to corrosion and erosion in plasma environments and have been described, for example, in U.S. Pat. Nos. 5,798,016, 5,911,852, 6,123,791 and 6,352,611. However, these parts used in plasma processing chambers are continuously attacked by the plasma and, consequently, corrode, erode and roughen on the surfaces of the chamber parts that are exposed to the plasma. This corrosion and erosion contribute to wafer level contamination through the release of particles from the component surface into the chamber, resulting in semiconductor device yield loss.

Rare earth oxides, and among those in particular YAG (Y₃Al₅O₁₂, garnet phase) and the family of yttrium aluminum oxides such as YAG, YAP and YAM are known to have a wide range of technological and industrial applications. YAG having a cubic, garnet crystallographic phase has received much attention due to applications such as host materials for solid-state lasers, transparent armors, ballistic window materials and it's remarkable mechanical, thermal and optical features. For laser applications in particular, single crystal YAG is a requirement thus much effort has been expended to fabricate single crystal YAG. YAG is also known to be very chemically inert and exhibit high halogen-based plasma corrosion and erosion resistance.

However, there are several drawbacks to the use of rare earth oxides, and especially the use of yttrium aluminum oxide having cubic garnet (YAG) crystallographic structure.

Yttrium aluminum oxides are known to be difficult to sinter to the high densities required with traditional methods, resulting in significant volumetric porosity remaining in the final part. Residual porosity, and thereby reduced density, leads to accelerated corrosion during plasma etch processes, deteriorating etch performance in the component, as well as decreasing mechanical strength. Sintering the family of yttrium aluminum oxides typically requires high temperatures of about 1600° C. and higher for prolonged periods of time such as 8 hours or more. The high temperatures and lengthy sintering durations leads to exaggerated grain growth, adversely affecting mechanical strength of solid yttrium aluminum oxide bodies. In order to promote densification of the yttrium aluminum oxide compounds, and in particular those of YAG composition to form sintered bodies for use as etch chamber components, sintering aids are frequently used to lower sintering temperatures. However, the addition of sintering aids effectively degrades the corrosion and erosion resistance of the yttrium aluminum oxide materials and increases the probability of impurity contamination at a semiconductor device level during use in chambers. Thus, a highly pure, high density body of yttrium aluminum oxide, and in particular a body having the cubic garnet crystallographic phase (YAG, Y₃Al₅O₁₂) is desirable.

Films or coatings of yttrium aluminum oxides have been known to be deposited atop a base or substrate formed of a different material which is lower in price and higher in strength than yttrium aluminum oxides. Such yttrium aluminum oxide films have been made through several methods. However, these methods are limited in film thicknesses that may be produced, displaying poor adhesion between film and substrate, and high levels of volumetric porosity, resulting in the shedding of particles into the process chamber.

As semiconductor device geometries shrink to the nanometer scale, temperature control becomes increasingly important to minimize process yield loss. This variation in temperature within the processing chamber affects control over critical dimensions of nanometer scale features, adversely affecting device yields. Material selection for chamber components having low dielectric loss, such as for example less than 1×10⁻⁴, may be desirable to prevent generation of heat, resulting in temperature nonuniformity within the chamber. Dielectric loss may be affected by grain size, purity and use of dopants and/or sintering aids in the material, among other factors. The use of sintering aids and extended sintering conditions may result in larger grain size, lower purity materials which may not provide the low loss tangents necessary for application to high frequency chamber processes common in the industry, minimal particle generation and the high mechanical strength for fabrication of large component sizes.

In particular, formation of the YAG phase of yttrium aluminum oxide is preferable due to its cubic crystallographic structure and, as a result, isotropic material properties. As such, its material properties do not vary based upon crystallographic plane or direction thus the cubic, garnet form, YAG, is preferable for its consistent material properties and resultant predictable performance in a number of applications, in particular as applies to use as a corrosion resistant component in a semiconductor processing chamber. However, fabrication of polycrystalline YAG yttrium aluminum oxide ceramic bodies which are highly phase pure (>90% by volume) poses difficulty and often other crystalline phases may be present.

YAG according to the established yttria/alumina phase diagram may exist as a line compound in accordance with the stoichiometric composition, and thus YAG forms in a phase pure sintered body across a very narrow compositional range. Variations in composition during powder batching and processing from that required to form stoichiometric YAG often may result in other crystallographic phases present in the sintered body, making formation of highly phase pure YAG challenging.

YAG formed as a film or coating or sintered body may have low hardness values owing to low densities and often mixed phase composition. These low hardness values result in materials which are susceptible to erosion or spalling from ion bombardment of component surfaces through use of inert plasma gases such as argon used as a process gas during semiconductor processing.

Attempts to fabricate ceramic bodies for corrosion resistant components of large dimension made from rare earth oxides such as YAG have been limited in success. Solid body, phase pure and high chemical purity components having diameters on the order of 100 mm and greater which may be handled and used as a part of a chamber without breakage or cracking are difficult to produce beyond a laboratory scale. This is owing to the typically low densities (for example of 95% and less of theoretical density of YAG) of YAG bodies at larger dimensions. Attempts thus far to prepare large, phase pure yttrium aluminum oxide components comprising YAG have resulted in high porosity and correspondingly low density, mixed crystalline phases, breakage and an inferior quality for their use in corrosion resistant applications. There are currently no economically feasible methods of making high purity, crystalline-phase pure YAG sintered bodies or components of diameter on the order of 100 mm to 625 mm and greater for use in semiconductor etch and deposition applications.

As a result, there is a need for a ceramic sintered body having uniform and high density, low porosity and high purity comprising phase pure YAG, providing enhanced plasma resistance to corrosion and erosion under plasma etch and deposition conditions and a commercially suitable method of production, particularly suited to fabrication of components of large dimension.

### SUMMARY

These and other needs are addressed by the various embodiments, aspects and configurations as disclosed herein:

Embodiment 1. A process ring for use in a plasma vacuum processing chamber, the process ring comprising: an annular body comprising at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and, optionally, at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, and wherein the at least one first, second and third layers form a unitary sintered ceramic body; and an opening surrounded by the annular body, wherein the surface comprises pores having a pore size not exceeding 5 μm and having a maximum pore size of 1.5 μm for at least 95% of the pores.

Embodiment 2. The process ring of embodiment 1 wherein the polycrystalline yttrium aluminum garnet comprises pores having a pore size not exceeding 1.75 μm for at least 97% or more of all pores.

Embodiment 3. The process ring of embodiment 1 or 2 wherein the at least one polycrystalline yttrium aluminum garnet has a maximum pore size not exceeding 2 μm for at least 99% or more of all pores.

Embodiment 4. The process ring according to embodiments 1-3 wherein the polycrystalline yttrium aluminum garnet has a volumetric porosity of from 0.1 to 3%.

Embodiment 5. The process ring according to embodiment 4 wherein the volumetric porosity is from 0.1 to 2%.

Embodiment 6. The process ring according to embodiment 5 wherein the volumetric porosity is from 0.1 to 1%.

Embodiment 7. The process ring according to embodiment 6 wherein the volumetric porosity is from 0.1 to 0.75%.

Embodiment 8. The process ring according to embodiment 7 wherein the volumetric porosity is from 0.1 to 0.5%.

Embodiment 9. The process ring according to embodiments 1-8 wherein the polycrystalline yttrium aluminum garnet (YAG) is present in an amount of from 90 to 99.8% by volume.

Embodiment 10. The process ring according to embodiments 1-9 wherein the polycrystalline yttrium aluminum garnet is present in an amount of from 93 to 99.8% by volume.

Embodiment 11. The process ring according to embodiments 1-10 wherein the polycrystalline yttrium aluminum garnet has a purity of 99.995% or higher as measured using ICPMS.

Embodiment 12. The process ring according to embodiments 1-11 wherein the pores occupy less than 0.2% of the surface area.

Embodiment 13. The process ring according to embodiments 1-12 wherein the pores occupy less than 0.15% of the surface area.

Embodiment 14. The process ring according to embodiments 1-13 wherein the pores occupy less than 0.10% of the surface area.

Embodiment 15. A showerhead assembly of a plasma vacuum processing chamber, the showerhead assembly comprising: a) a backplate portion comprising at least one gas inlet; b) a frontplate portion opposite the backplate portion, wherein the frontplate portion comprises a plurality of gas distribution holes; and c) an inner volume in communication with the gas distribution holes and the gas inlet, wherein the backplate portion and the frontplate portion each comprise at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and, optionally, at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores.

Embodiment 16. The showerhead assembly of embodiment 15 wherein the polycrystalline yttrium aluminum garnet comprises pores having a pore size not exceeding 1.75 nm for at least 97% or more of all pores.

Embodiment 17. The showerhead assembly of embodiment 15 or 16 wherein the at least one polycrystalline yttrium aluminum garnet has a maximum pore size not exceeding 2 nm for at least 99% or more of all pores.

Embodiment 18. The showerhead assembly according to embodiments 15-17 wherein the polycrystalline yttrium aluminum garnet has a volumetric porosity of from 0.1 to 3%.

Embodiment 19. The showerhead assembly according to embodiment 18 wherein the volumetric porosity is from 0.1 to 2%.

Embodiment 20. The showerhead assembly according to embodiment 19 wherein the volumetric porosity is from 0.1 to 1%.

Embodiment 21. The showerhead assembly according to embodiment 20 wherein the volumetric porosity is from 0.1 to 0.75%.

Embodiment 22. The showerhead assembly according to embodiment 21 wherein the volumetric porosity is from 0.1 to 0.5%.

Embodiment 23. The showerhead assembly according to embodiments 18-22 wherein the polycrystalline yttrium aluminum garnet (YAG) is present in an amount of from 90 to 99.8% by volume.

Embodiment 24. The showerhead assembly according to embodiments 15-23 wherein the polycrystalline yttrium aluminum garnet is present in an amount of from 93 to 99.8% by volume.

Embodiment 25. The showerhead assembly according to embodiments 15-24 wherein the polycrystalline yttrium aluminum garnet has a purity of 99.995% or higher as measured using ICPMS.

Embodiment 26. The showerhead assembly according to embodiments 15-25 wherein the pores occupy less than 0.2% of the surface area.

Embodiment 27. The showerhead assembly according to embodiments 15-26 wherein the pores occupy less than 0.15% of the surface area.

Embodiment 28. The showerhead assembly according to embodiments 15-27 wherein the pores occupy less than 0.10% of the surface area.

Embodiment 29. A gas distribution nozzle for use in a plasma vacuum processing chamber, the gas distribution nozzle comprising: a body having at least one gas injection passage, wherein the body comprises at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and, optionally, at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores.

Embodiment 30. The gas distribution nozzle of embodiment 29 wherein the polycrystalline yttrium aluminum garnet comprises pores having a pore size not exceeding 1.75 μm for at least 97% or more of all pores.

Embodiment 31. The gas distribution nozzle of embodiment 29 or 30 wherein the at least one polycrystalline yttrium aluminum garnet has a maximum pore size not exceeding 2 μm for at least 99% or more of all pores.

Embodiment 32. The gas distribution nozzle according to embodiments 19-31 wherein the polycrystalline yttrium aluminum garnet has a volumetric porosity of from 0.1 to 3%.

Embodiment 33. The gas distribution nozzle according to embodiment 32 wherein the volumetric porosity is from 0.1 to 2%.

Embodiment 34. The gas distribution nozzle according to embodiment 33 wherein the volumetric porosity is from 0.1 to 1%.

Embodiment 35. The gas distribution nozzle according to embodiment 34 wherein the volumetric porosity is from 0.1 to 0.75%.

Embodiment 36. The gas distribution nozzle according to embodiment 35 wherein the volumetric porosity is from 0.1 to 0.5%.

Embodiment 37. The gas distribution nozzle according to embodiments 29-36 wherein the polycrystalline yttrium aluminum garnet (YAG) is present in an amount of from 90 to 99.8% by volume.

Embodiment 38. The gas distribution nozzle according to embodiments 29-37 wherein the polycrystalline yttrium aluminum garnet is present in an amount of from 93 to 99.8% by volume.

Embodiment 39. The gas distribution nozzle according to embodiments 29-38 wherein the polycrystalline yttrium aluminum garnet has a purity of 99.995% or higher as measured using ICPMS.

Embodiment 40. The gas distribution nozzle according to embodiments 29-39 wherein the pores occupy less than 0.2% of the surface area.

Embodiment 41. The gas distribution nozzle according to embodiments 29-40 wherein the pores occupy less than 0.15% of the surface area.

Embodiment 42. The gas distribution nozzle according to embodiments 29-41 wherein the pores occupy less than 0.10% of the surface area.

Embodiment 43. A dielectric window for use in a plasma vacuum processing chamber, the dielectric window comprising: a body comprising at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and, optionally, at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores.

Embodiment 44. The dielectric window of embodiment 43 wherein the polycrystalline yttrium aluminum garnet comprises pores having a pore size not exceeding 1.75 μm for at least 97% or more of all pores.

Embodiment 45. The dielectric window of embodiment 43 or 44 wherein the at least one polycrystalline yttrium aluminum garnet has a maximum pore size not exceeding 2 μm for at least 99% or more of all pores.

Embodiment 46. The dielectric window according to embodiments 43-45 wherein the polycrystalline yttrium aluminum garnet has a volumetric porosity of from 0.1 to 3%.

Embodiment 47. The dielectric window according to embodiment 46 wherein the volumetric porosity is from 0.1 to 2%.

Embodiment 48. The dielectric window according to embodiment 47 wherein the volumetric porosity is from 0.1 to 1%.

Embodiment 49. The dielectric window according to embodiment 48 wherein the volumetric porosity is from 0.1 to 0.75%.

Embodiment 50. The dielectric window according to embodiment 49 wherein the volumetric porosity is from 0.1 to 0.5%.

Embodiment 51. The dielectric window according to embodiments 43-50 wherein the polycrystalline yttrium aluminum garnet (YAG) is present in an amount of from 90 to 99.8% by volume.

Embodiment 52. The dielectric window according to embodiments 43-51 wherein the polycrystalline yttrium aluminum garnet is present in an amount of from 93 to 99.8% by volume.

Embodiment 53. The dielectric window according to embodiments 43-52 wherein the polycrystalline yttrium aluminum garnet has a purity of 99.995% or higher as measured using ICPMS.

Embodiment 54. The dielectric window according to embodiments 43-53 wherein the pores occupy less than 0.2% of the surface area.

Embodiment 55. The dielectric window according to embodiments 43-54 wherein the pores occupy less than 0.15% of the surface area.

Embodiment 56. The dielectric window according to embodiments 43-55 wherein the pores occupy less than 0.10% of the surface area.

Embodiment 57. The dielectric window according to embodiments 43-56 wherein the body is a multilayered body comprising a later of zirconia toughened alumina.

Embodiment 58. The process ring according to embodiments 1-14 wherein the annular body is a multilayered body comprising a later of zirconia toughened alumina.

Embodiment 59. The showerhead assembly according to embodiments 15-28 wherein the backplate portion and the front plate portion are a multilayered and comprise a later of zirconia toughened alumina.

Embodiment 60. The gas distribution nozzle according to embodiments 29-42 wherein the body is a multilayered body comprising a later of zirconia toughened alumina.

The embodiments of the invention can be used alone or in combinations with each other.

### BRIEF DESCRIPTION OF THE DRAWINGS

FIG. 1 depicts the phase diagram of the two-component yttrium oxide/aluminum oxide phase diagram, illustrating the yttrium aluminum oxide phases of YAG (Y₃Al₅O₁₂), YAP (YAlO₃) and YAM (Y₄Al₂O₉) and the molar proportions and temperatures necessary to form them;

FIG. 2 depicts an exemplary schematic of a multilayer sintered ceramic body according to embodiments as disclosed herein;

FIG. 3 is a graph illustrating variation in CTE for the at least one second layer 102 comprising zirconia in alumina according to embodiments as disclosed herein;

FIG. 4 is a graph illustrating x ray diffraction results of the at least one second layer 102 according to embodiments as disclosed herein;

FIG. 5 is a cross-sectional view of a SPS sintering apparatus having a tool set located in a vacuum chamber (not shown) with a simple arrangement used for sintering yttrium aluminum oxide ceramic materials;

FIG. 6A illustrates an embodiment of FIG. 5 showing one foil layer;

FIG. 6B illustrates an alternative embodiment of FIG. 5 showing two foil layers;

FIG. 6C illustrates another alternative embodiment of FIG. 5 showing three foil layers;

FIGS. 7A and 7B are top plan views of the SPS sintering apparatus of FIG. 5;

FIG. 8 is a graph depicting radial variance in average coefficient of thermal expansion (CTE) of graphite materials A and B at 1200° C.;

FIG. 9 a) illustrates the standard deviation of coefficient of thermal expansion of graphite materials A and B in ppm/° C. and b) variance in coefficient of thermal expansion of graphite materials A and B each as measured over the operating temperatures of 200 to 1200° C.;

FIG. 10 is a graph illustrating a coefficient of thermal expansion of graphite materials A and B from 400 to 1400° C.;

FIG. 11A illustrates a prospective view of an exhaust ring in accordance with an embodiment;

FIG. 11B illustrates a cross-sectional view of the exhaust ring of FIG. 11A;

FIG. 11C illustrates a prospective view and a cross-sectional view of a multilayer embodiment of an exhaust ring;

FIG. 12 illustrates an isometric section of an example showerhead assembly;

FIGS. 12A and 12B illustrate a cross-section of a multilayer shower head faceplate comparing different through hole geometries;

FIGS. 13A and 13B illustrate cross-sections of a single layer and a multilayer gas distribution nozzle, respectively;

FIG. 14 is a cross-sectional view of a second embodiment of a gas distribution component;

FIGS. 15A, 15B, 15C and 15D are cross-sectional views of embodiments of a dielectric window component;

FIG. 16 is an SEM microstructure at 1000× of a first comparator material;

FIG. 17 depicts x ray diffraction results of the YAG powder used to form the first comparator material of FIG. 16.

FIG. 18 is an SEM microstructure at 1000× of a second comparator material;

FIG. 19 depicts a 1000× micrograph of a ceramic sintered body comprising YAG, YAP and Alumina;

FIG. 20 depicts x ray diffraction results of the ceramic sintered body of FIG. 19;

FIG. 21 depicts x ray diffraction results of a powder mixture of yttrium oxide and aluminum oxide prior to sintering, and samples prepared therefrom using pressureless sintering methods sintered at 1400° C. and 1600° C. for 8 hours;

FIG. 22 depicts x ray diffraction results of an as prepared yttria/alumina crystalline powder mixture prior to sintering, and a corresponding ceramic sintered body comprising a single crystalline phase of about 100% YAG, according to embodiments as disclosed herein;

FIG. 23 depicts exemplary x ray diffraction patterns for representative starting crystalline powders of a) yttria and b) alumina as disclosed herein;

FIG. 24 a) and b) show x-ray diffraction results for calcined powder mixtures as disclosed herein;

FIG. 25 depicts x-ray diffraction results for powder mixtures calcined under various conditions as disclosed herein;

FIG. 26 depicts 1000× micrographs of 3 ceramic sintered bodies having YAG phase with YAP or YAM in accordance with examples 2, 3 and 4;

FIG. 27 depicts 5000× micrographs of exemplary sintered ceramic bodies comprising at least one yttrium aluminum oxide as disclosed herein in accordance with Examples 1, 2, 3 and 4;

FIG. 28 illustrates phase identification through x ray diffraction measurements for ceramic sintered body examples 1 through 4 of FIG. 27 as disclosed herein;

FIG. 29 a) depicts an exemplary ceramic sintered body having excess alumina from sample 153 at 1000× comprising highly phase pure YAG; b) results from thresholding of the SEM image illustrating YAG in an amount of 99.6% by volume with about 0.4% of aluminum oxide phase, according to an embodiment as disclosed herein;

FIG. 30 shows corresponding x ray diffraction results for the ceramic sintered body of FIG. 29;

FIG. 31 depicts an exemplary SEM micrograph of a highly dense ceramic sintered body according to an embodiment as disclosed herein;

FIG. 32 illustrates an example of a capacitively coupled semiconductor processing chamber; and

FIG. 33 depicts an example of an inductively coupled semiconductor processing chamber.

### DETAILED DESCRIPTION

Reference will now be made in detail to specific embodiments. Examples of the specific embodiments are illustrated in the accompanying drawings. While the disclosure will be described in conjunction with these specific implementations, it will be understood that it is not intended to limit the disclosure to such specific embodiments. On the contrary, it is intended to cover alternatives, modifications, and equivalents as may be included within the spirit and scope as defined by the appended claims. In the following description, numerous specific details are set forth in order to provide a thorough understanding of the disclosed embodiments. The present disclosure may be practiced without some or all of these specific details.

Embodiments are described, including the best mode known to the inventors for carrying out the invention. Variations of those embodiments may become apparent to those of ordinary skill in the art upon reading the following detailed description. The inventors expect skilled artisans to employ such variations as appropriate, and the inventors intend for the invention to be practiced otherwise than as specifically described. Accordingly, this invention includes all modifications and equivalents of the subject matter recited in the appended claims as permitted by applicable law. Moreover, any combination of the above-described elements in all possible variations is encompassed by the invention unless otherwise indicated or otherwise clearly contradicted by context. Further, all features disclosed with respect to the methods also apply to the ceramic sintered body, at least one of the crystalline phases of yttrium aluminum oxide and solid or multilayered components formed therefrom.

All references, including publications, patent applications, and patents, cited are hereby incorporated by reference to the same extent as if each reference were individually and specifically indicated to be incorporated by reference and were set forth in its entirety.

### Definitions

In this application, the term “yttrium aluminum oxide” is understood to mean at least one of the forms of crystalline phases of yttrium aluminum oxides, including Y₃Al₅O₁₂ (YAG; yttrium aluminum garnet/cubic phase), YAlO₃ (YAP; yttrium aluminum perovskite phase), and Y₄Al₂O₉ (YAM; yttrium aluminum monoclinic phase) and combinations of these. The terms “YAG” and “YAG phase” are used interchangeably herein.

As used herein, the term “alumina” is understood to be aluminum oxide, comprising Al₂O₃, and the term “yttria” is understood to be yttrium oxide, comprising Y₂O₃.

As used herein, the terms “semiconductor wafer,” “wafer,” “substrate,” and “wafer substrate,” are used interchangeably. A wafer or substrate used in the semiconductor device industry typically has a diameter of 200 mm, or 300 mm, or 450 mm.

As used herein, the term “ceramic sintered body” is synonymous with “sinter”, “body” “multilayer sintered ceramic body”, “multilayer corrosion resistant ceramic”, or “sintered body” and refers to a unitary, integral sintered ceramic article formed from co-compacting more than one powder mixture by application of pressure and heat which creates a unitary, dense, multilayer sintered ceramic body. The unitary, multilayer sintered ceramic body may be machined into a unitary, multilayer sintered ceramic component useful as a chamber component in plasma processing applications. As used herein, the term “co-compacting” or “co-compaction” refers to the process by which at least two loose powder materials are disposed within a die and subjected to pressure to form a powder compact. The powder compact is free of binders, dispersants, and other similar organic matter as is required for the formation of green or shaped bodies, or tapes as is common in the art.

By “unitary” or “integral” is meant a single piece or a single unitary part that is complete by itself without additional pieces, i.e., the part is of one monolithic piece formed as a unit with another part.

The term “substantially,” as used in this document, is a descriptive term that denotes approximation and means “considerable in extent” or “largely but not wholly that which is specified” and is intended to avoid a strict numerical boundary to the specified parameter. As used herein, the term “nanopowder” is intended to encompass those powders having a specific surface area of 20 m²/g and greater.

As used herein, the term “ambient temperature” refers to a temperature range of from 22° C. to 25° C.

As used herein, the term “coefficient of thermal expansion (CTE) is measured in accordance with ASTM E228-17 across a temperature range of from 25 to 200° C. to 25 to 1400° C., preferably of from 25 to 1200° C., more preferably of from 25 to 1000° C., more preferably 25 to 800° C., more preferably of from 25 to 600° C., more preferably of from 25 to 400° C., more preferably of from 25 to 200° C. The CTE describes how the size of an object changes with a change in temperature. Specifically, it measures the fractional change in size per degree change in temperature at a constant pressure. To determine the coefficient at a certain temperature, the volume of the material is measured at a reference temperature and the volume of the material is measured at the temperature, for which one would like to determine the CTE. Afterward, based on the differences in volume and temperature the fractional change is determined.

All CTE values for this disclosure were made according to ASTM E228-17. Especially, the reference temperature used was the ambient temperature, especially 25° C. Thus, if a CTE for a given temperature is disclosed (i.e., 200° C.), then the CTE has been determined by the comparison of the volume (or linear expansion for isotropic materials) at said temperate to the volume (or linear expansion for isotropic materials) at ambient temperature, especially 25° C. In any case of contradictions with respect to CTE, the ASTM E228-17 is always the dominating disclosure. In the disclosed examples, the CTE was measured using a vertical dilatometer, in particular, the L75 model, available from Linseis Messgeraete GmbH of Selb, Germany.

As used herein, the term “purity” refers to the absence of various contaminants in a) a starting material from which a powder mixture may be formed, b) a powder mixture after processing, and c) a ceramic sintered body as disclosed herein. Higher purity, closer to 100%, represents a material having essentially no contaminants or impurities, comprising only the intended material composition of Y, Al and O and optionally dopants.

As used herein, the term “impurity” refers to those compounds/contaminants present in a) the starting materials from which a powder mixture may be formed, b) a powder mixture after processing, and c) a ceramic sintered body comprising impurities other than the starting material itself which comprises Y, Al and O and optionally dopants. Impurities may arise from the starting materials, powder processing or during sintering.

The term “dopants” as used herein do not include the starting materials of yttrium oxide and aluminum oxide to the extent they may remain in the ceramic sintered body. Impurities differ from dopants in that dopants as defined herein are those compounds intentionally added to the starting powders or to the powder mixture to achieve certain electrical, mechanical, optical or other properties such as grain size modification for example, in the ceramic sintered body.

The term “sintering aid” as used herein refers to additives, such as zirconia, calcia, silica or magnesia, that enhance densification, and thereby reduce porosity, during the sintering process.

As used herein, the term “ceramic sintered component” refers to a ceramic sintered body after a machining step which creates a form or shape of a specific component for use in a semiconductor processing chamber as disclosed herein.

As used herein, the term “powder mixture” means more than one starting powder mixed together prior to a sintering process which after a sintering step are thereby formed into the “ceramic sintered body.”

As used herein, the term “tool set” is one that may comprise at least a die and at least two punches and optionally additional spacers. When fully assembled, the tool set defines a volume for disposition of the calcined powder mixture as disclosed.

The term “phase” as used herein is understood to mean a distinct, crystalline region, portion or layer of a sintered ceramic body having a specific crystallographic structure.

As used herein, the term “layer” is understood to mean a thickness of material, typically one of several. The material can be, for example, a ceramic powder, a powder mixture, a calcined powder mixture, or a sintered region or sintered portion.

A “solid solution” as used herein is defined as a mixture of different elements that share the same crystal lattice structure. The mixture within the lattice may be substitutional, in which the atoms of one starting crystal replace those of the other, or interstitial, in which the atoms occupy positions normally vacant in the lattice.

The term “calcination” when used as relates to heat treatment processes is understood herein to mean heat treatment steps which may be conducted on a powder or a powder mixture in air to for example remove moisture and/or impurities, increase crystallinity and in some instances modify powder surface areas.

The term “annealing” when applied to heat treatment of ceramics is understood herein to mean a heat treatment conducted on the disclosed ceramic sintered bodies in air to relieve stress and/or normalize stoichiometry.

As used here, the terms “approximately” and “about” as is used in connection with numbers allows for a variance of plus or minus 10%.

### Compositions

The following detailed description assumes the disclosure is implemented within equipment such as etch or deposition chambers necessary as part of the making of a semiconductor wafer substrate. However, the invention is not so limited. The work piece may be of various shapes, sizes, and materials. In addition to semiconductor wafer processing, other work pieces that may take advantage of this invention include various articles such as fine feature size inorganic circuit boards, magnetic recording media, magnetic recording sensors, mirrors, optical elements, micro-mechanical devices and the like.

During processing of semiconductor devices, corrosion resistant parts or chamber components are used within etch chambers and exposed to harsh corrosive environments which cause the release of particles into the etch chamber, resulting in yield loss due to wafer-level contamination. The ceramic sintered body and related components as disclosed herein provide improved plasma etch resistance and enhanced ability to be cleaned within semiconductor processing chambers by way of specific material properties and features to be described following.

In an embodiment, disclosed herein is a multilayer ceramic sintered body comprising at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and, optionally, at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores. The YAG surface preferably has a volumetric porosity of from 0.1 to 4% as calculated from density measurements performed in accordance with ASTM B962-17. In some embodiments, the surface may comprise YAG in an amount of from 90 to 99.6% by volume, preferably from 90 to 99.4% by volume, preferably from 95 to 99.6% by volume, preferably from 95 to 99.4% by volume of a cubic crystallographic structure through use of the materials and methods as disclosed herein. The YAG surface of the multilayer ceramic sintered body may comprise a volumetric porosity in amounts of from 0.1 and 4%, preferably from 0.1 and 3%, preferably from 0.1 and 2%, preferably from 0.1 and 1%, preferably from 0.1 and 0.5%, wherein the volumetric porosity is calculated from density measurements performed in accordance with ASTM B962-17 or ASTM B311-17 if porosity is less than 2%.

The multilayer sintered ceramic body can be machined into, for example, components of a plasma etch chamber, wherein the components exhibit excellent corrosion resistance to the harsh plasma conditions in use.

In another embodiment, disclosed herein is a ceramic sintered body comprising a layer of yttrium aluminum garnet (YAG) of composition Y₃Al₅O₁₂ comprising from 90 to 99.8% by volume of a cubic crystallographic structure and aluminum oxide in an amount from 0.2 to 10% by volume, preferably from 0.2 to 8% by volume, preferably from 0.2 to 5% by volume, preferably from 0.2 to 3% by volume, preferably from 0.2 to 2% by volume, and preferably from 0.2 to 1% by volume of aluminum oxide.

In embodiments, disclosed herein is a ceramic sintered body comprising a layer comprising at least one form of polycrystalline yttrium aluminum oxide in an amount by volume of from 70 to 100% as determined by x ray diffraction, a volumetric porosity of from 0.1 to less than 5% as calculated from density measurements performed in accordance with ASTM B962-17, a purity of greater than 99.99% as measured by ICPMS method, and a hardness of at least 1200 HV as measured in accordance with ASTM Standard C1327. The ceramic sintered body comprises at least one polycrystalline yttrium aluminum oxide phase or a combination of the phases of yttrium aluminum oxides, to include in specific embodiments yttrium aluminum garnet the Y₃Al₅O₁₂ (YAG) phase, yttrium aluminum perovskite YAlO₃ (YAP), and yttrium aluminum monoclinic Y₄Al₂O₉ (YAM) and combinations thereof. In preferred embodiments, the ceramic sintered body comprises from 90% to 99.8% by volume of polycrystalline yttrium aluminum garnet (YAG).

Semiconductor processing reactors as relates to etch or deposition processes require chamber components fabricated from materials having high resistance to chemical corrosion by reactive plasmas necessary for semiconductor processing. These plasmas or process gases may be comprised of various halogen, oxygen and nitrogen-based chemistries such as O₂, F, Cl₂, HBr, BCl₃, CCl₄, N₂, NF₃, NO, N₂O, C₂H₄, CF₄, SF₆, C₄F₈, CHF₃, CH₂F₂. Use of the corrosion resistant materials as disclosed herein provides for reduced chemical corrosion and degradation during use. Additionally, providing a chamber component material such as a ceramic sintered body having a very high purity provides a uniformly corrosion resistant body low in impurities, which may serve as a site for initiation of corrosion or erosion. High resistance to erosion or spalling is also required of materials for use as chamber components. Erosion or spalling may result from ion bombardment of component surfaces through use of inert plasma gases such as Ar. Those materials having a high value of hardness may be preferred for use as components due to their enhanced hardness values providing greater resistance to ion bombardment and thereby, erosion. Further, components fabricated from highly dense materials having minimal porosity distributed at a fine scale may provide greater resistance to corrosion and erosion during etch and deposition processes. As a result, preferred chamber components may be those fabricated from materials having high erosion and corrosion resistance during plasma etching, deposition and chamber cleaning processes. This resistance to corrosion and erosion prevents the release of particles from the component surfaces into the etch or deposition chambers during semiconductor processing. Such particle release or shedding into the process chamber contributes to wafer contamination, semiconductor process drift and semiconductor device level yield loss.

Additionally, chamber components must possess sufficient flexural strength and rigidity for handleability as required for component installation, removal, cleaning and during use within process chambers. High mechanical strength allows for machining intricate features of fine geometries into the ceramic sintered body without breakage, cracking or chipping. Flexural strength or rigidity becomes particularly important at large component sizes used in state-of-the-art process tools. In some component applications such as a chamber window of diameter on the order of 200 to 610 mm and greater, significant stress is placed upon the window during use under vacuum conditions, necessitating selection of corrosion resistant materials of high strength and rigidity.

For use in semiconductor processing chamber applications where ion bombardment occurs as part of the plasma process, it is preferable that chamber components formed from ceramic sintered bodies having high hardness values may be preferable in order to resist erosion during use. High hardness values also may allow for the ability to create fine features in the ceramic sintered body upon machining into a specific component form without chipping, flaking or damage to the surface of the sintered body.

Preferable for semiconductor chamber components are those materials which have as low dielectric loss as possible in order to improve plasma generation efficiency, in particular at the high frequencies of from 1 MHz to 20 GHz used in plasma processing chambers. Heat generated by absorption of microwave energy in those component materials having higher dielectric loss causes non-uniform heating and increased thermal stresses upon components, and the combination of thermal and mechanical stresses during use may result in limitations to product designs and complexity.

To meet the aforementioned requirements, the ceramic sintered body as disclosed herein is preferably made from a ceramic sintered body comprising at least one or a combination of the forms of yttrium aluminum oxide or, in multilayer embodiments, a first layer comprising at least one or a combination of the forms of yttrium aluminum oxide. These include the cubic garnet phase of composition Y₃Al₅O₁₂ (YAG), the perovskite phase of composition YAlO₃ (YAP), and the monoclinic phase having composition Y₄Al₂O₉ (YAM). In preferred embodiments, the ceramic sintered body comprises from 90% to 99.8% by volume of polycrystalline yttrium aluminum garnet (YAG).

In an embodiment, the ceramic sintered body as disclosed herein may comprise about 100% of a single crystalline phase of any one of the yttrium aluminum oxides of YAG, YAP or YAM or, in a multilayer embodiment, comprise a first layer comprising about 100% of a single crystalline phase of any one of the yttrium aluminum oxides of YAG, YAP or YAM. In other embodiments, the ceramic sintered body may comprise a matrix or composite structure of two or more discrete or continuous phases of the yttrium aluminum oxides as disclosed herein. In further embodiments, the ceramic sintered body may comprise minority phases of aluminum oxide and/or yttrium oxide with a majority of any one or combination of the yttrium aluminum oxides YAG, YAP and YAM.

In some embodiments, the ceramic sintered body as disclosed herein may comprise a first layer comprising from 90 and 99.6% by volume of the cubic crystalline phase, YAG. In certain embodiments, the ceramic sintered body as disclosed herein may comprise a first layer comprising from 95 and 99.6% by volume of the cubic crystalline phase of YAG and from 0.01 to 5% of an aluminum oxide phase. Embodiments of the ceramic sintered body as disclosed herein are polycrystalline and as such the ceramic sintered body may comprise two or more crystals, without limitation.

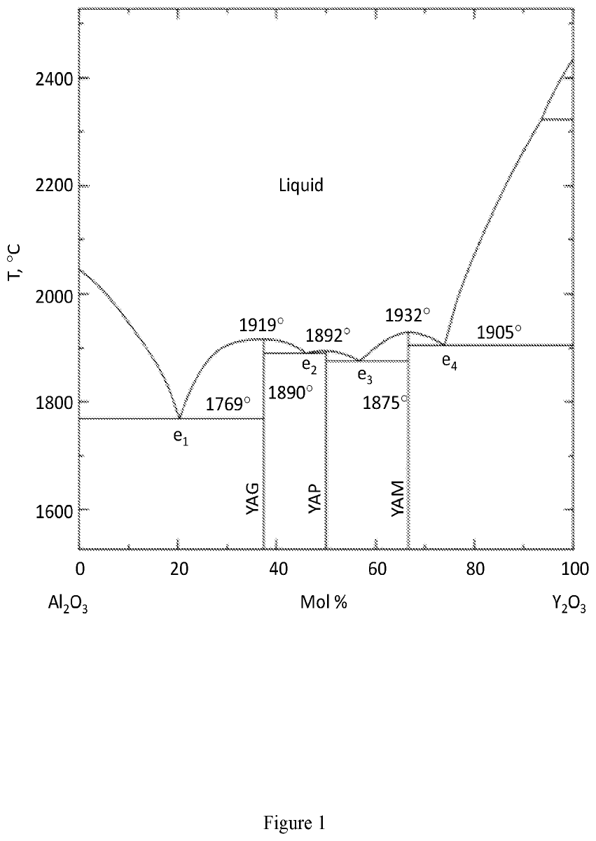

As a guide, FIG. 1 depicts the yttrium oxide/aluminum oxide two-component phase diagram. The horizontal axis corresponds to mixture proportions in mole percent of yttria and alumina, while the vertical axis is temperature in Celsius. The left of the horizontal axis corresponds to 100% alumina while the right corresponds to 100% yttria. The phase diagram of FIG. 1 illustrates regions where the yttrium aluminum oxide phases of YAG, YAP, and YAM are formed and the conditions of molar composition and temperature necessary to produce the forms. The formation of YAG may require precise batching of powders and careful processing in order to maintain stoichiometry and thus form a ceramic sintered body comprising phase pure YAG of 37.5 mol % yttrium oxide and 62.5 mol % aluminum oxide.

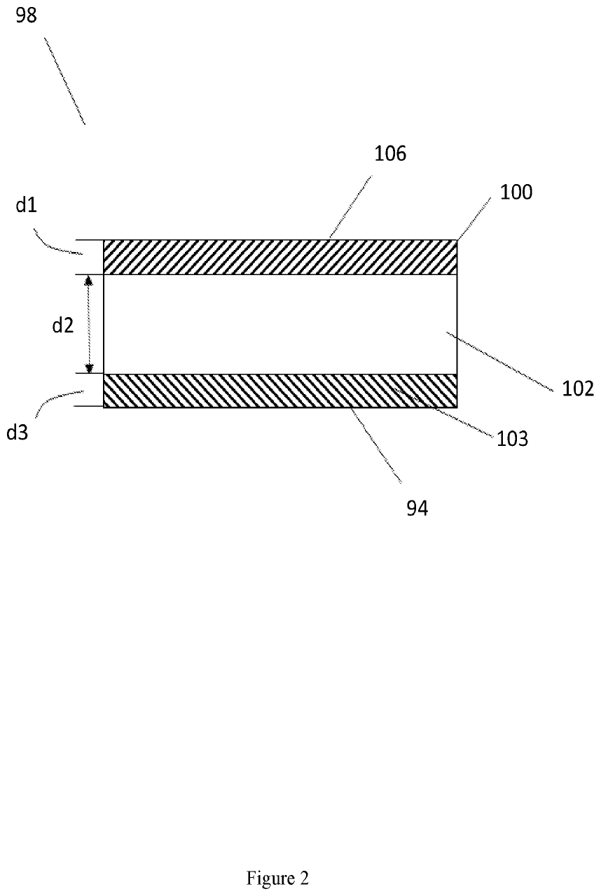

FIG. 2 depicts a schematic of the multilayer sintered ceramic body 98 embodiment as disclosed herein where 100 represents at least one first layer having a thickness d1, 102 illustrates at least one second layer 102 having a thickness d2, and 103 illustrates at least one third layer 103 having a thickness d3. The multilayer sintered ceramic bodies 98 produced according to the method as disclosed herein (depicting at least one first layer 100 wherein the first layer has a thickness, a second layer 102 wherein the second layer has a thickness, and a third layer 103 wherein the third layer has a thickness) preferably have a thickness of the second layer 102 which is from 70% to 95%, preferably from 70% to 90%, preferably from 70% to 85%, preferably from 80% to 95%, preferably from 85% to 95% of the combined thickness of the 3 layers 100, 102 and 103, respectively.

The at least one first layer 100 is described above and comprises at least one or a combination of the forms of yttrium aluminum oxide. These include the cubic garnet phase of composition Y₃Al₅O₁₂ (YAG), the perovskite phase of composition YAlO₃ (YAP), and the monoclinic phase having composition Y₄Al₂O₉ (YAM).

The at least one second layer 102 provides mechanical strength and electrical properties of low dielectric loss tangent (less than 7×10⁻⁴ at 1 MHz) and high dielectric constant of about 12. As such, in some embodiments it may be preferable that a thickness d2 is maximized. In order to provide high mechanical strength and rigidity combined with machinability to form sintered ceramic components from the multilayer sintered bodies as disclosed herein, the thickness d2 of the at least one second layer 102 as depicted in FIG. 1 is preferably greater than each of the thicknesses d1 of the at least one first layer 100, and/or the thickness d3 of the at least one third layer 103. The thickness d1 of the at least one first layer 100 and/or the thickness d3 of the at least one third layer may each be from 0.5 to 5 mm, preferably from 0.5 to 4 mm, preferably from 0.5 to 3 mm, preferably from 0.5 to 2 mm, preferably from 0.5 to 1 mm, preferably from 0.75 to 5 mm, preferably from 0.75 to 3 mm, preferably from 1 to 5 mm, preferably from 1 to 4 mm, preferably from 1 to 3 mm. A multilayer sintered ceramic body as disclosed herein may have a total thickness (d1+d2+d3) of from about 5 to about 50 mm, preferably from about 5 to about 40 mm, preferably from about 5 to about 35 mm, preferably from about 5 to about 33 mm, preferably from about 5 to about 30 mm, preferably from about 8 to about 25 mm, and preferably from about 10 to about 20 mm. In certain embodiments where it may be desirable to minimize the thickness d1 of the at least one first layer 100 and/or the thickness (d3) of the at least one third layer 103, the multilayer sintered ceramic body may be machined after sintering and/or after annealing to reduce the thicknesses d1 and/or d3 of layers 100 and/or 103 to modify electrical properties such as dielectric loss, dielectric constant, thermal conductivity or other properties of the multilayer sintered ceramic body 98 or component formed therefrom.

The multilayer sintered ceramic bodies produced according to the method as disclosed herein may have a first layer 100 wherein the first layer has a thickness, a second layer 102 wherein the second layer has a thickness, and a third layer 103 wherein the third layer has a thickness, wherein the thickness of the second layer 102 is from 70% to 95%, preferably from 70% to 90%, preferably from 70% to 85%, preferably from 80% to 95%, preferably from 85% to 95% of the combined thickness of the 3 layers 100, 102 and 103, respectively.

In certain embodiments, the thickness d2, of the at least one second layer is from 60% to 85%, preferably from 60% to 80%, preferably from 60% to 75%, preferably from 60% to 70%, preferably from 70% to 85%, preferably from 75% to 85%, preferably from 70% to 80%, preferably from 70% to 75% of the combined thicknesses of the at least one first, second and third layers (d1+d2+d3). The at least one first layer having a thickness d1 comprises a plasma facing surface 106 providing corrosion and erosion resistance to halogen-based plasmas. In embodiments, the thickness d1, of the at least one first layer is from 0.75% to 20%, preferably from 0.75% to 15%, preferably from 0.75% to 12%, preferably from 3% to 20%, preferably from 5% to 20%, preferably from 3% to 15%, preferably from 5% to 12% of the combined thicknesses of the at least one first, second and third layers (d1+d2+d3).

Stresses arising from layers comprising materials having mismatched CTE may impact the mechanical strength and integrity of the multi-layer sintered ceramic body. Accordingly, if the difference in absolute value of the CTE between the at least one first layer 100, the at least one second layer 102, and the at least one third layer 103 of the sintered ceramic body is too great, at least one layer of the multilayer sintered ceramic body may crack, warp and/or fracture upon performing the steps of the method as disclosed herein. This CTE difference is important across all process temperatures, and particularly at elevated temperatures such as those experienced during sintering, annealing and upon cooling, where differences in CTE may result in significant interfacial stresses between layers of the sintered body. As a result, in order to form a multilayer, unitary sintered ceramic body having high mechanical strength, high adhesion strength between layers and sufficient handleability (without cracking or breakage), the CTE difference between the at least one first layer 100, the at least one second layer 102, and the at least one third layer 103 of the multi-layer sintered ceramic body is preferred to be within the disclosed ranges, and further as closely matching as possible. In preferred embodiments at least one first, second and third layers may have respective CTEs which are the same, or substantially the same, in absolute value of CTE, across a temperature range of from ambient temperature (or about 200° C. as disclosed in the figures) to about 1700° C. (or at least to 1400° C. as depicted in the figures) in accordance with the method as disclosed. The term “CTE match” as used herein refers to combinations of the at least one first layer 100, the at least one second layer 102, and the at least one third layer 103 which differ in CTE within the preferred ranges as disclosed (from 0 to about 0.75×10−6/° C. in absolute value). According to one embodiment, the at least one first layer 100 may comprise at least one crystalline phase of a ceramic material comprising YAG, whereby the at least one first layer 100 is CTE matched to the at least one second layer 102 (comprising alumina and at least one of stabilized and partially stabilized zirconia), and the at least one third layer 103 (comprising combinations of the at least one first and second layers) to form a unitary, multilayer sintered ceramic body. On a percentage basis, combinations of the at least one first layer 100, the at least one second layer 102, and the at least one third layer 103 may have CTE values (across the temperature ranges as disclosed herein) which match one another in a percentage of about 10% and less, preferably 9% and less, preferably 8% and less, preferably 6% and less, preferably 4% and less, preferably 3% and less, preferably 2.5% and less, preferably 2% and less, preferably 1.5% and less, preferably 1% and less, preferably 0.5% and less, and preferably 0.25% and less of the at least one first, second and third layers (as measured relative to the at least one first layer 100).

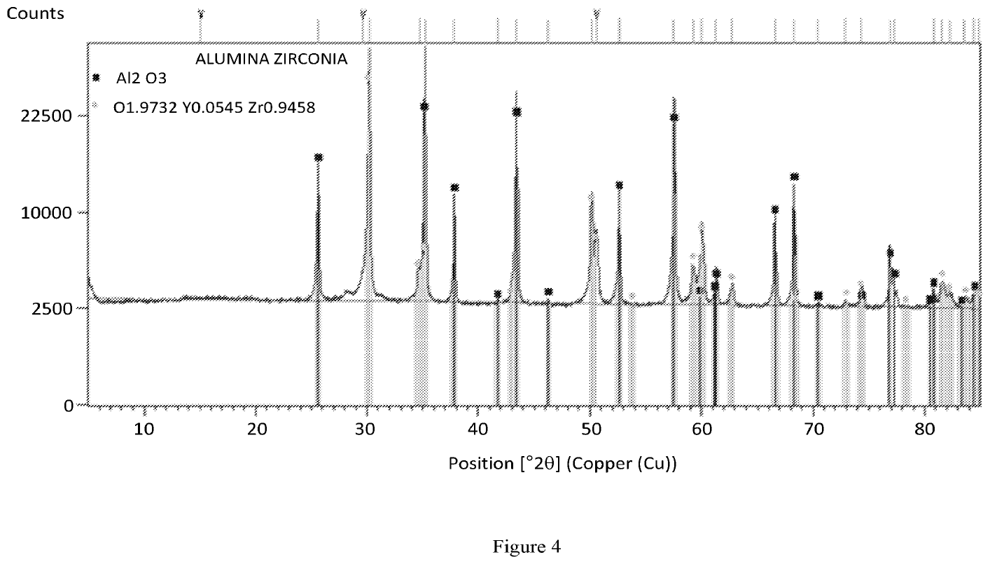

In embodiments, the at least one second layer 102 may comprise particles or grains of zirconia (PSZ, SZ and combinations thereof) dispersed in a host matrix of alumina wherein the least one second layer comprises a particle composite (composite oxide) having two separate crystalline phases of alumina and zirconia. Preferably, the at least one second layer 102 does not form a solid solution. Formation of a solid solution may degrade thermal conductivity and as such the at least one second layer 102 comprises separate crystalline phases of zirconia and alumina. FIG. 4 depicts separate crystalline phases of zirconia and alumina from x ray diffraction results, confirming the at least one second layer 102 comprises separate crystalline phases, without formation of a solid solution. X ray diffraction for all measurements as disclosed herein was performed using a PANanlytical Aeris model XRD capable of crystalline phase identification to about +/−5%. Small amounts of yttria present in the x-ray diffraction pattern of FIG. 4 may result from the partial stabilization of zirconia (partially yttria stabilized zirconia, PYSZ) according to embodiments of the at least one second layer.

Further, use within the at least one second layer 102 of those compounds known to form glasses (such as magnesia, silica and calcia) as sintering aids may result in a low thermal conductivity, glassy phase present between grains, thus adversely affecting thermal conductivity. As a result, in some embodiments, it is preferred that the at least one second layer 102 comprises magnesia and/or calcia in the ranges of from about 2 to 100 ppm, preferably from about 2 to 75 ppm, preferably from about 2 to 50 ppm, preferably from about 2 to 25 ppm, preferably from about 2 to 20 ppm, preferably from about 2 to 10 ppm, preferably about 8 ppm, preferably about 2 ppm and less, relative to the mass of the at least one second layer as measured using ICPMS methods. In further embodiments, the at least one second layer 102 may comprise silica in an amount of from about 14 ppm to 100 ppm, preferably from about 14 ppm to about 75 ppm, more preferably from about 14 ppm to about 50 ppm, preferably from about 14 ppm to about 30 ppm preferably about 14 ppm and less (as measured using ICPMS methods), relative to a mass of the at least one second layer 102. A second layer 102 comprising sintering aids within the disclosed ranges may provide a multilayer sintered ceramic body which is free of, or substantially free of, a glassy phase, providing high thermal conductivity of the multilayer sintered ceramic body. Disclosed herein is a multilayer sintered ceramic body comprising at least one second layer 102 which is free of, or substantially free of, dopants and/or sintering aids as disclosed herein.

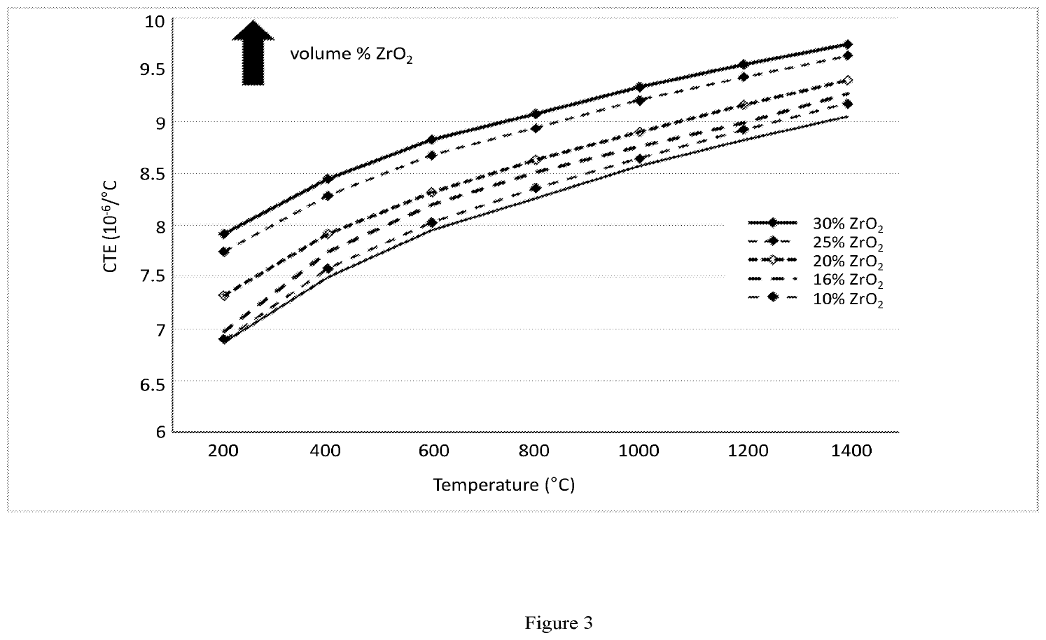

Compositions of the at least one second layer 102 may be selected to produce specific CTE characteristics based upon the volume % of zirconia in alumina as depicted in FIG. 3, which shows exemplary CTE results of the at least one second layer 102 as disclosed herein wherein the second layer comprises zirconia in amounts from 10 to 30% by volume and the balance comprising Al₂O₃. The amount of zirconia, and the resultant CTE values of the at least one second layer 102, are preferably CTE matched with the at least one first and third layers across a temperature range corresponding to that of the method, of from ambient temperature (or 200° C. in accordance with the figures) to about 1700° C. (or 1400° C. in accordance with the figures) to fabricate the unitary, multilayer sintered bodies as disclosed herein.

According to one embodiment, the at least one second layer 102 may comprise alumina and zirconia wherein the zirconia comprises at least one of stabilized zirconia and partially stabilized zirconia in an amount by volume of from 5 to 30%, preferably from 5 to 25%, preferably from 5 to 20%, preferably from 5 to 16%, preferably from 10 to 30%, preferably from 16 to 30%, preferably from 10 to 25%, and preferably from 15 to 20% relative to a volume of the at least one second layer (and the balance comprising Al₂O₃).

These volume percentages of the at least one second layer 102 correspond to weight percentages of a second powder mixture comprising zirconia (and the balance alumina) of from about 7% to about 40%, preferably from about 7% to about 35%, preferably from about 7% to about 28%, preferably from about 7% to about 23%, preferably from about 15% to about 40%, preferably from about 23% to about 40%, preferably from about 15% to about 34%, preferably from about 21% to about 28%, and preferably about 23%. Across this compositional and temperature range, the coefficient of thermal expansion (CTE) of the at least one second layer 102 may vary from an at least one second layer 102 comprising 5% by volume of zirconia, having a CTE of about 6.8×10-6/° C. as measured at 200° C., to an at least one second layer 102 comprising about 30% by volume of zirconia and having a CTE of about 9.75×10-6/° C. as measured at 1400° C. The volumetric amount of at least one of stabilized or partially stabilized zirconia in the at least one second layer 102 provides the ability to modify the CTE to be the same as, or substantially the same as, and within the disclosed CTE matching ranges, as that of the at least one first layer 100 and the at least one third layer 103.

FIG. 3 illustrates coefficient of thermal expansion results from 200 to 1400° C. for the at least one second layer 102 as disclosed herein, having zirconia present in amounts of from 10 to 30% by volume. The CTE values with temperature for the at least one second layer comprising 5% by volume zirconia (not shown) are typically between the ranges of pure alumina and the at least one second layer comprising 10% by volume zirconia. The at least one second layer 102 comprises at least two separate crystalline phases of zirconia and alumina as illustrated in FIG. 4, thus the volumetric mixing rule as known to those skilled in the art was used to calculate CTE values for 5%, 25% and 30% by volume zirconia. The CTE is shown to increase with increasing amounts by volume of zirconia as illustrated in FIG. 3. Dependent upon the volume of zirconia in the ZTA (zirconia toughened alumina), at least one second layer 102, the CTE of the at least one second layer may be greater than, substantially equal to, equal to, or less than (varying in amounts within the ranges as disclosed herein) that of the at least one first layer 100 (comprising YAG) comprising the unitary, multilayer sintered ceramic body. Thus, the difference in CTE as used herein typically means the absolute value of the difference in CTE, unless specifically stated otherwise.

Referring again to FIG. 3, experimental data was taken to measure the coefficient of thermal expansion (CTE) of the at least one second layer 102 using dilatometry methods as performed in accordance with ASTM E228-17 for 10, 16 and 20 vol % ZrO₂ (and the balance alumina) compositions. An exemplary at least one second layer 102 comprising about 16% by volume of zirconia was measured to have a coefficient of thermal expansion (CTE) of from 6.98×10⁻⁶/° C. to 9.26×10⁻⁶/° C. throughout a temperature range of from about 25-200° C. to about 25-1400° C. as measured in accordance with ASTM E228-17. The at least one second layer 102 comprises at least two separate crystalline phases of zirconia and alumina (referred to herein as a composite oxide or particulate composite or a zirconia toughened alumina, ZTA) as illustrated from x ray diffraction results of FIG. 4. As such, the volumetric mixing rule as known to those skilled in the art was used to calculate CTE values for 5%, 25% and 30% by volume of zirconia (as depicted in FIG. 3). The CTE values with temperature for the at least one second layer comprising 5% by volume zirconia (not shown) are typically between the ranges of pure alumina and the at least one second layer comprising 10% by volume zirconia. The ability to modify the CTE characteristics of the at least one second layer 102 provides CTE matching between the at least one second layer 102, the at least one third layer 103, and the at least one first layer 100 in particular across a temperature range consistent with that of the method and sintering temperatures as disclosed herein. In some embodiments, across the disclosed temperature range of from ambient to about 1700° C., (or from 200° C. to 1400° C. as illustrated in the figures), the CTE of the at least one second layer 102 may be both greater and less than the CTE of the at least one first layers, thereby having a CTE difference of zero across the temperature range. In other embodiments, across the disclosed temperature range (from ambient to about 1700° C., or from 200° C. to 1400° C. as illustrated in the figures), the CTE of the at least one second layer 102 may be either greater or less than the CTE of the at least one first layer 100, and as such, the absolute value of the difference in coefficient of thermal expansion (CTE) between the at least one first layer 100 and the at least one second layer 102 may be from 0.003×10-6/° C. to 0.75×10-6/° C., preferably from 0.003×10-6/° C. to 0.7×10-6/° C., preferably from 0.003×10⁻⁶/° C. to 0.6×10-6/° C., preferably from 0.003×10-6/° C. to 0.5×10-6/° C., preferably from 0.003×10-6/° C. to 0.45×10-6/° C., preferably from 0.003×10-6/° C. to 0.4×10-6/° C., preferably from 0.003×10-6/° C. to 0.35×10-6/° C., preferably from 0.003×10-6/° C. to 0.3×10⁻⁶/° C., preferably from 0.003×10-6/° C. to 0.25×10-6/° C., preferably from 0.003×10-6/° C. to 0.2×10-6/° C., preferably from 0.003×10-6/° C. to 0.15×10-6/° C., preferably from 0.003×10⁻⁶/° C. to 0.1×10-6/° C., preferably from 0.003×10-6/° C. to 0.08×10-6/° C., preferably from 0.003×10-6/° C. to 0.06×10-6/° C., preferably from 0.003×10-6/° C. to 0.04×10-6/° C., preferably from 0.003×10-6/° C. to 0.02×10-6/° C., and preferably from 0.003×10-6/° C. to 0.01×10-6/° C. as measured in accordance with ASTM E228-17 across a temperature range of from 25 to 1700° C. or across a temperature range of from 200 to 1400° C.

In addition to CTE matching, the multilayer sintered ceramic bodies must have high thermal conductivity for use as components in semiconductor plasma processing chambers. Zirconia toughened alumina (ZTA) compositions selected for use as the at least one second layer 102 (and at least a portion of the at least one third layer 103) will significantly impact properties of the unitary, multilayer sintered bodies. High thermal conductivity of the at least one second layer 102 is an important material property to effectively distribute heat and thereby avoid localized overheating within the at least one second layer during use, in particular when used as a dielectric or RF window component. This localized overheating may result in cracking or fracture of the unitary, multilayer sintered body. Zirconia is reported in the literature to have a lower thermal conductivity than that of alumina, thus the amount of zirconia will affect the thermal conductivity of the at least one second layer 102. Although pure aluminum oxide is known to have a high thermal conductivity, the mismatch in CTE precludes it's use in combination with the materials for use as at least one first layer 100 as disclosed herein. While there may be no practical lower limit to the minimum amount of zirconia in the at least one second layer 102 for thermal conductivity reasons, in order to provide CTE matching to the at least one first layer 100 as well as high thermal conductivity (about the same as that of alumina), at least one second layer 102 comprising at least one of stabilized zirconia and partially stabilized zirconia in an amount of about 5% by volume and greater, up to and including 30% by volume (with the balance comprising a second crystalline phase of about 70% to 95% by volume alumina) are preferable.

In order to provide at least one second layer 102 having thermal conductivity sufficient for use for example in high frequency applications (such as an RF or dielectric window or lid component), the at least one second layer 102 having up to and including about 30% by volume, and in some embodiments preferably not greater than 25% by volume of zirconia may be preferable. A second layer 102 having greater than 30% by volume of zirconia may not provide sufficient thermal conductivity for use as components in semiconductor plasma processing chambers for which high thermal conductivity is a requirement. Compositions of the at least one second layer 102 having greater than 30% by volume of zirconia may result in high thermal gradients within the at least one second layer 102 and may lead to fracture and/or cracking.

In further embodiments, the at least one second layer 102 may have a CTE which is greater than that of the at least one first layer 100 across a temperature range of from about 600° C. to about 1700° C. (or to at least 1400° C. as depicted in the figures), and a CTE which is less than that of the at least one first layer 100 across a temperature range of from ambient (or to at least 200° C. as depicted in the figures) to about 600° C. The temperature at which the CTE changes in magnitude between the at least one first and second layers may occur at any temperature from about 200° C. to about 800° C. Without intending to be bound by a particular theory, the lower CTE of the at least one second layer 102 relative to the at least one first layer 100 at lower temperatures (for example of 800° C. to ambient) functions to provide compression of the at least one first layer 100, thereby reducing the likelihood of crack propagation, fracture, and spalling, which may lead to particle generation during use as components in semiconductor plasma processing chambers.

The combination of zirconia and alumina in the at least one second layer may provide a transformation toughening effect through a dispersion of tetragonal zirconia particles, at least a portion of which transform to monoclinic upon crack propagation. The volume expansion from tetragonal to monoclinic zirconia provides the transformation or dispersion toughening effect in the at least one second layer 102 as known to those skilled in the art. In embodiments, the at least one second layer 102 may comprise a particle composite (also referred to herein as a composite oxide or ZTA, representing a dispersion or transformation toughened ceramic) of the crystalline phases of zirconia and alumina in the amounts by volume as disclosed. This method of toughening may be affected by powder particle size, shape and location of the tetragonal and monoclinic, dispersed zirconia phases in the alumina matrix.

Referring now to an embodiment of FIG. 2, disclosed is a multilayer sintered ceramic body 98 comprising at least one optional third layer 103. The at least one third layer 103 comprises multiple phases comprising at least one of YAG, alumina, and zirconia. The zirconia may comprise at least one of unstabilized, partially stabilized and stabilized zirconia. The at least one third layer 103 may provide improved machinability and CTE matching (within the ranges as disclosed herein) to the at least one first layer 100 and at least one second layer 102.

In embodiments where present, the at least one third layer 103 may comprise YAG in an amount by area of from greater than 50% to 90%, preferably from greater than 50% to 80%, preferably from greater than 50% to 60%, and more preferably about 51% to 55%, relative to the area of an exemplary, polished surface of the at least one third layer. Area measurements were completed using backscatter detection images from SEM which were imported into ImageJ software, and thereafter the respective phases of YAG and alumina/zirconia were measured as to their percentage of surface area across an exemplary image area. The at least one third layer 103 of the multilayer sintered ceramic body may comprise an integral body, thus comprising throughout the crystalline phases of at least YAG, zirconia and alumina made according to the process disclosed herein. In other words, a structure measured on a surface is representative of a structure within a volume of the bulk at least one third layer. As such, the at least one third layer of the multilayer sintered ceramic body may comprise the crystalline phases of YAG, zirconia and alumina in the same relative amounts over a surface, and throughout a volume of the sintered body.

In embodiments, the at least one third phase comprises a zirconia toughened alumina (ZTA) phase comprising at least one of unstabilized, partially stabilized or stabilized zirconia in an amount of about 16% by volume and the balance alumina. The at least one third layer 103 typically has a CTE within the ranges as disclosed for the at least one first and second layers. The CTE of the at least one third layer 103 may be adjusted to match that of the at least one first and second layers through variations in the amount of zirconia. As such, the absolute value of the difference in coefficient of thermal expansion (CTE) between the at least one first layer 100, the at least one second layer 102, and the at least one third layer 103 may in some embodiments be from 0 to 0.75×10-6/° C., preferably from 0 to 0.7×10-6/° C., preferably from 0 to 0.6×10-6/° C., preferably from 0 to 0.5×10-6/° C., preferably from 0 to 0.45×10-6/° C., preferably from 0 to 0.4×10-6/° C., preferably from 0 to 0.35×10-6/° C., preferably from 0 to 0.3×10-6/° C., preferably from 0 to 0.25×10-6/° C., preferably from 0 to 0.2×10-6/° C., preferably from 0 to 0.15×10-6/° C., preferably from 0 to 0.1×10-6/° C., preferably from 0 to 0.08×10-6/° C., preferably from 0 to 0.06×10-6/° C., preferably from 0 to 0.04×10-6/° C., preferably from 0 to 0.02×10-6/° C., and preferably from 0 to 0.01×10⁻⁶/° C. as measured in accordance with ASTM E228-17 across a temperature range of from 25 to 1700° C. or across a temperature range of from 200 to 1400° C.

In other embodiments, the absolute value of the difference in coefficient of thermal expansion (CTE) between the at least one first layer 100, the at least one second layer 102, and the at least one third layer 103 may be from 0.003×10-6/° C. to 0.75×10-6/° C., preferably from 0.003×10-6/° C. to 0.7×10-6/° C., preferably from 0.003×10-6/° C. to 0.6×10-6/° C., preferably from 0.003×10-6/° C. to 0.5×10-6/° C., preferably from 0.003×10-6/° C. to 0.45×10-6/° C., preferably from 0.003×10-6/° C. to 0.4×10-6/° C., preferably from 0.003×10-6/° C. to 0.35×10-6/° C., preferably from 0.003×10-6/° C. to 0.3×10-6/° C., preferably from 0.003×10-6/° C. to 0.25×10-6/° C., preferably from 0.003×10-6/° C. to 0.2×10-6/° C., preferably from 0.003×10-6/° C. to 0.15×10-6/° C., preferably from 0.003×10-6/° C. to 0.1×10-6/° C., preferably from 0.003×10-6/° C. to 0.08×10-6/° C., preferably from 0.003×10-6/° C. to 0.06×10-6/° C., preferably from 0.003×10-6/° C. to 0.04×10-6/° C., preferably from 0.003×10-6/° C. to 0.02×10-6/° C., and preferably from 0.003×10-6/° C. to 0.01×10-6/° C. as measured in accordance with ASTM E228-17, across a temperature range of from 25 to 1700° C. or across a temperature range of from 200 to 1400° C.

In order to prevent localized hot spots and overheating during use, in particular for RF applications, a low dielectric loss is preferable. Dielectric loss may be affected by such material properties as grain size and presence of impurities, sintering aids and/or dopants for example. The presence of impurities and/or sintering aids and/or dopants, such as in particular silica in the at least one second layer 102 may result in a higher dielectric loss. The use of highly pure/low impurity content starting powders and a method that preserves the purity results in an at least one second layer 102 of high total purity and correspondingly low in total impurity content. As such, in embodiments, the at least one second layer 102 as disclosed may have a total impurity content of from 5 to 200 ppm, preferably from 5 to 150 ppm, preferably less than 100 ppm, preferably less than 50 ppm, preferably less than 25 ppm, preferably less than 15 ppm, preferably from 10 to 100 ppm, preferably from 10 to 80 ppm, preferably from 10 to 60 ppm, preferably from 10 to 40 ppm, preferably from 20 to 80 ppm, and preferably from 30 to 60 ppm relative to the mass of the at least one second layer as measured using ICPMS methods. In embodiments, the at least one second layer 102 is formed from a powder mixture which comprises silica in amounts of from about 14 to 100 ppm, preferably from about 14 to 75 ppm, preferably from about 14 to 50 ppm, preferably from about 14 to 25 ppm, preferably about 14 ppm relative to total mass of the calcined powder mixture. In embodiments, the at least one second layer 102 may comprise magnesia (MgO) in an amount of from about 2 to 100 ppm, preferably from about 2 to 75 ppm, preferably from about 2 to 50 ppm, preferably from about 2 to 25 ppm, preferably from about 2 to 20 ppm, preferably from about 2 to 10 ppm, preferably about 8 ppm and less, and preferably about 2 ppm relative to a mass of the at least one second layer 102 as measured using ICPMS methods.

The ceramic sintered bodies prepared in accordance with the method as disclosed herein, and ceramic sintered components made from the sintered body whether a single layer, a two-layer, or a three-layer body preferably have high densities. Density measurements were performed using the Archimedes buoyancy method according to ASTM B962-17 and ASTM B311-17 (when porosity levels are 2% and less). Density values and standard deviations reported are for an average across 5 or more measurements. A commercially available, single crystal sample of YAG was measured for density using the methods as disclosed herein. A theoretical density of 4.556 g/cc across 5 measurements was obtained. The ceramic sintered bodies comprising phase pure YAG and further phase pure YAG including up to 1% by weight excess alumina as disclosed in embodiments herein may have density of for example from 4.374 to 4.556 g/cc, from 4.419 to 4.556 g/cc, from 4.465 to 4.556 g/cc, from 4.510 to 4.556 g/cc, from 4.533 to 4.556 g/cc, or by percentage of from 96 to 99.999%, from 97 to 99.999%, 98 to 99.999%, from 99 to 99.999%, from 99.5 to 99.999% of theoretical density of YAG. Corresponding volumetric porosities (Vp) may be from 0.010 to less than 5%, from 0.010 to 4%, from 0.010 to 3%, from 0.010 to 3%, from 0.010 to 2%, from 0.010 to 1%, preferably less than 1%, preferably less than 0.5% as calculated from the density measurements performed in accordance with the specifications as disclosed herein. The relative density (RD) for a given material is defined as the ratio of the measured density of the sample to the reported theoretical density for the same material, as shown in the following equation. Volumetric porosity (Vp) is calculated from density measurements as follows:

$$R D = \frac{ρ sample}{ρ theoretical} = 1 - V p$$

where p sample is the measured (Archimedes) density according to ASTM B962-17, p theoretical is the reported theoretical density, and RD is the relative fractional density. Using this calculation, porosity levels by percent of from 0.1 and 5% and less were calculated from measured density values for the ceramic sintered bodies as disclosed herein. Thus, in embodiments, the ceramic sintered body comprising at least one yttrium aluminum oxide phase as disclosed herein comprises volumetric porosity in amounts of from 0.1 to 5%, preferably from 0.1 to 4%, preferably from 0.1 to 3%, preferably from 0.1 to 2%, preferably from 0.1 to 1% in the ceramic sintered body.

These density, purity and porosity levels may provide enhanced resistance to the effects of erosion and corrosion resulting from plasma etch and deposition processing. The method and materials as disclosed are particularly useful in the preparation of ceramic sintered bodies of large dimension, for example from a greatest dimension of from 200 to 610 mm. The high densities, and thereby high mechanical strength, of the ceramic sintered body also provide increased handleability, in particular at large dimensions. Successful fabrication of sintered yttrium aluminum oxide bodies or multilayered bodies comprising sintered yttrium aluminum oxide, and in particular bodies formed of phase pure YAG in ranges as disclosed herein, across a longest (from about 200 to 610 mm) dimension may be enabled by controlling variation in density across at least one, longest dimension. An average density of 96% and greater is desirable, with a variation in density of 5% and less, preferably 4% and less, preferably 3% and less, preferably 2% and less, preferably 1% and less across the greatest dimension, whereby the greatest dimension may be for example about 625 mm and less, 622 mm and less, 610 mm and less, preferably 575 mm and less, preferably 525 mm and less, preferably from 100 to 625 mm, preferably from 100 to 622 mm, preferably from 100 to 575 mm, preferably from 200 to 625 mm, preferably from 200 to 510 mm, preferably from 400 to 625 mm, preferably from 500 to 625 mm. Low densities of less than 95% of theoretical density for YAG may have lower strengths and thereby higher porosities, in excess of 5%, which results in breakage and inferior handleability. Table 1 lists density, crystalline phase purity and percent of volumetric porosity for embodiments of the ceramic sintered bodies as disclosed herein. Densities of the ceramic sintered bodies as disclosed herein range from 4.378 g/cc to 4.564 g/cc.

TABLE 1

| | | % | | |
|---|---|---|---|---|
| | Ave | Theoretical | | % |
| | Density | (YAG/ | Phase Purity | Volumetric |
| Sample | (g/cc) | YAG/YAP) | (xrd/SEM) % | Porosity |
| 519 | 4.534 | 99.517 | 100 YAG | 0.48 |
| 529 | 4.564 | 98.968 | 93 YAG/7 | 1.03 |
| | | | YAP | |
| 531 | 4.552 | 99.049 | 95 YAG/5 | 0.95 |
| | | | YAP | |
| 514 | 4.549 | 99.846 | 100 YAG | 0.15 |
| 196 | 4.452 | 97.717 | N/A | 2.28 |
| 535 | 4.524 | 99.298 | 100 YAG | 0.70 |
| 162 | 4.546 | 99.782 | 100 YAG | 0.22 |
| 162-1 | 4.537 | 99.585 | 100 YAG | 0.41 |
| 158 | 4.536 | 99.563 | 100 YAG | 0.44 |
| 158-1 | 4.523 | 99.271 | 100 YAG | 0.73 |
| 153 | 4.541 | 99.674 | 100 YAG | 0.33 |
| 153-1 | 4.524 | 99.304 | 100 YAG | 0.70 |
| 165 | 4.515 | 99.095 | 100 YAG | 0.90 |
| 6 | 4.545 | 99.766 | N/A | 0.23 |
| 134 | 4.521 | 99.232 | 100 YAG | 0.77 |
| 135 | 4.525 | 99.320 | 100 YAG | 0.68 |
| 402 | 4.546 | 99.784 | N/A | 0.22 |
| 402-1 | 4.537 | 99.573 | N/A | 0.43 |
| 401 | 4.550 | 99.867 | 100 YAG | 0.13 |
| 401-1 | 4.516 | 99.122 | 100 YAG | 0.88 |
| 401-2 | 4.525 | 99.320 | 100 YAG | 0.68 |
| 377 | 4.513 | 99.056 | N/A | 0.94 |
| 423 | 4.528 | 99.385 | 100 YAG | 0.61 |
| 191 | 4.464 | 97.971 | N/A | 2.03 |
| 258 | 4.542 | 99.693 | N/A | 0.31 |
| 355 | 4.429 | 97.220 | N/A | 2.78 |
| 408 | 4.378 | 96.093 | N/A | 3.91 |
| 395 | 4.389 | 96.335 | N/A | 3.67 |
| 399 | 4.458 | 97.849 | N/A | 2.15 |
| 195 | 4.492402 | 98.604 | N/A | 1.396 |
| 93 | 4.543699 | 99.730 | N/A | 0.270 |
| 322 | 4.544 | 99.728 | N/A | 0.272 |
| 322-1 | 4.531 | 99.451 | N/A | 0.549 |
| 272-5 | 4.433 | 97.300 | N/A | 2.700 |
| 298 | 4.540 | 99.649 | N/A | 0.351 |

Along with high density, the variation in density across a greatest dimension of the ceramic sintered body as disclosed may impact the ability to be handled in particular at large (>100 mm) dimension, machined and use as a ceramic sintered component. The density was measured across a greatest dimension of several examples of ceramic sintered bodies as disclosed herein. Table 13 lists results of density and density variations and volumetric porosity as measured.

In addition to high density, high hardness values may further provide enhanced resistance to erosion during use as a plasma chamber component. As such, Vickers hardness measurements were performed in accordance with ASTM Standard C1327 “Standard Test Method for Vickers Indentation Hardness of Advanced Ceramics.” The test equipment used for all hardness measurements was a Wilson Micro Hardness Tester Model VH1202. Hardness values of at least 1200 HV, preferably at least 1400 HV, preferably at least 1800 HV, preferably at least 2000 HV, from 1300 to 1600 HV, from 1300 to 1500 HV, from 1300 to 1450 HV, from 1300 to 1400 HV, from 1400 to 1600 HV, from 1450 and 1600 HV, from 1450 and 1550 HV may be obtained for the ceramic sintered body as disclosed herein. Measurements performed using Vickers hardness methods as known in the art were converted to SI units of GPa. Hardness values of from 12.75 to 15.69 GPa, from 12.75 to 14.71 GPa, from 12.75 to 14.22 GPa, from 12.75 to 13.73 GPa, from 13.73 and 15.69 GPa, from 14.22 and 15.69 GPa, preferably from 14.22 and 15.20 GPa may be obtained for the ceramic sintered body as disclosed herein. These high hardness values may contribute to enhanced resistance to ion bombardment during semiconductor etch processes and reduced erosion during use, providing extended lifetimes when the ceramic sintered body is machined into ceramic sintered components having fine scale features. Table 2 lists hardness values for the ceramic sintered bodies as disclosed herein. Averages are reported across eight test repetitions using a 2 kgf load cell/applied load for samples 514, 519 and 531, and a 0.025 kgf load for sample 506.

TABLE 2

| | Average | | Max | Min |
|---|---|---|---|---|
| Sample | (GPa) | St Dev | (GPa) | (GPa) |
| 514 | 13.47 | 0.69 | 14.7 | 12.4 |
| 531 | 14.14 | 0.58 | 15.0 | 13.2 |
| 519 | 14.5 | 0.4 | 16.1 | 14.5 |
| 506 | 14.8 | 1.0 | 16.0 | 12.7 |

In one embodiment, the ceramic sintered body disclosed herein has an average hardness of from 13.0 to 15.0 GPa for eight samples using an applied load of 0.2 kgf as measured in accordance with ASTM Standard C1327. In another embodiment, the ceramic sintered body disclosed herein has an average hardness of about 13.5 to 14.5 GPa for eight samples using an applied load of 0.2 kgf as measured in accordance with ASTM Standard C1327.

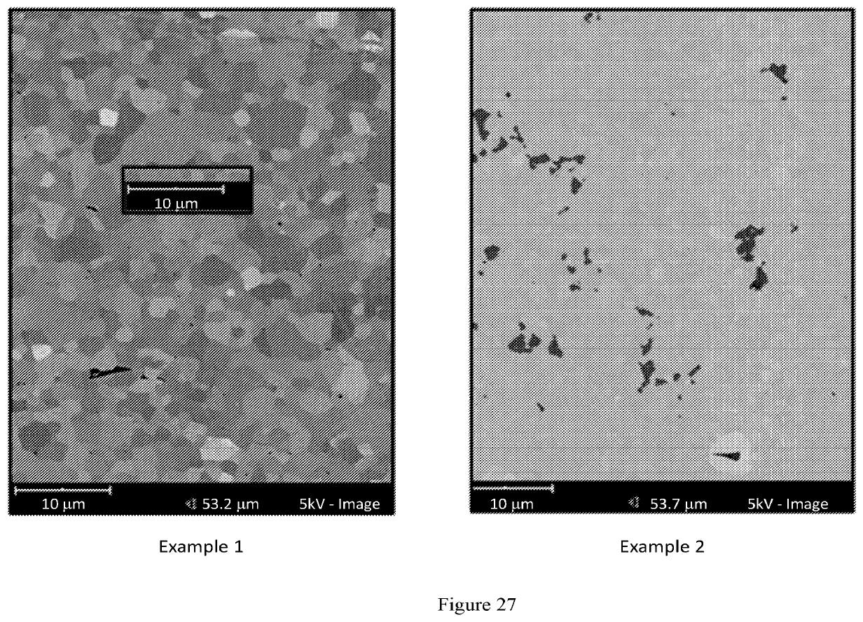

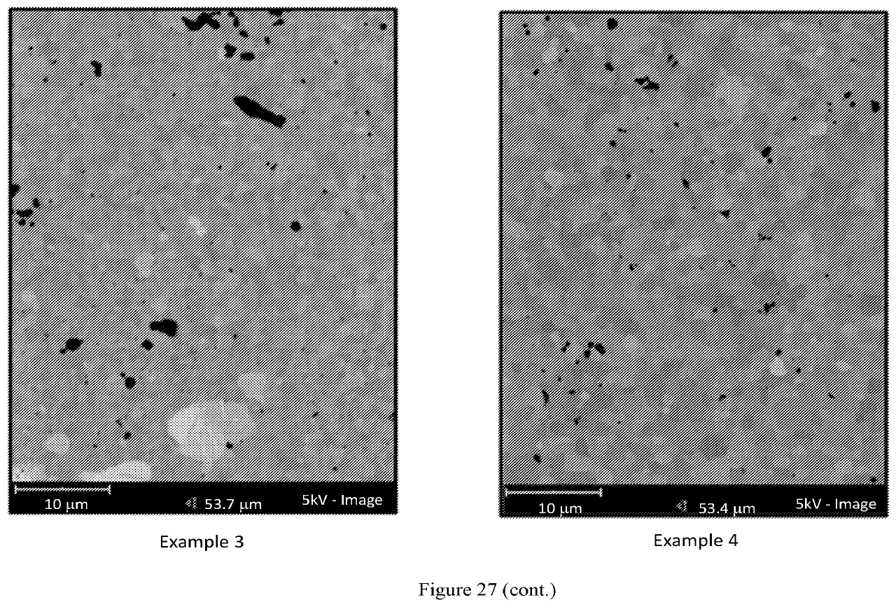

Mechanical strength properties are known to improve with decreasing grain size. In order to assess grain size, linear intercept grain size measurements were performed in accordance with the Heyn Linear Intercept Procedure described in ASTM standard E112-2010 “Standard Test Method for Determining Average Grain Size.” Grain size may also be measured by SEM, as depicted in Example 1 of FIG. 27, showing grain sizes of about 8 um and less. To meet the requirements of high flexural strength and rigidity for use in reactor chambers as large components of from 200 to 610 mm, the ceramic sintered body may have a fine grain size of, for example, a maximum grain size of about 10 um and less, preferably a maximum grain size of 8 um and less, preferably an average grain size of 5 um and less, preferably an average grain size of 3 um and less, preferably 2 um and less, preferably 1.5 um and less, preferably 1.0 um and less, preferably from 0.5 and 8 um, preferably a grain size of from 1 to 5 um. Table 3 lists results of grain size measurements on the ceramic sintered body as disclosed in embodiments herein. 75 and 125 measurements were taken across samples 519 and 531, respectively.

TABLE 3

| | | Average | Median | | | |
|---|---|---|---|---|---|---|
| | d10 | Grain | (d50) | d90 | Min | Max |
| Sample | (μm) | Size (μm) | (μm) | (μm) | (um) | (um) |
| 519 | 1.1 | 2.1 | 1.8 | 3.1 | 0.5 | 7 |
| 531 | 0.6 | 1.1 | 1.0 | 1.5 | 0.4 | 2 |
| 506 | 6.3 | 0.7 | N/A | N/A | 5 | 7.7 |

These grain sizes may result in a ceramic sintered body having a 4 point bend flexural strength as measured in accordance with ASTM C1161-18 of 300 MPa and less, preferably 350 MPa and less, preferably 400 MPa and less, preferably from 300 to 450 MPa, preferably from 300 to 400 MPa, preferably from 350 to 450 MPa, preferably from 375 to 425 MPa. Table 4 lists four-point flexural strength measurements for the ceramic sintered body of sample 006 as disclosed. Grain sizes too large in size, on the order of 20 um and greater, may result in ceramic sintered bodies having low flexural strength values which may make them unsuitable for use as etch chamber components in particular of large dimension, thus it is preferable for the ceramic sintered body to have an average grain size of less than about 10 um.

TABLE 4
4 pt flexural strength, N = 20

| | Average | | Max | |
|---|---|---|---|---|
| Sample | (MPa) | St Dev | (Mpa) | Min (Mpa) |
| 006 | 386 | 27 | 440 | 336 |

Providing materials low in dielectric loss also becomes important at increasing frequencies. The ceramic sintered bodies disclosed herein may be tailored within a certain application-specific range of from about 5×10⁻³ to 1×10−4 and less across a frequency range of from 1 MHz to 1 GHz. Material properties such as purity of the starting powders, and for example, the silica content in the ceramic sintered body may affect dielectric loss. In embodiments, low silica content may provide a ceramic sintered body to meet the corrosion resistance and dielectric loss requirements as stated. Embodiments of the ceramic sintered body as disclosed herein are low or free of, silica, as listed in Table 12 herein. In addition, dielectric loss may be affected by grain size and grain size distribution. Fine grain size also may provide reduced dielectric loss, and thereby reduced heating upon use at higher frequencies. These material properties may be adjusted through material synthesis to meet specific loss values dependent upon the specific component application within semiconductor processing chambers. Table 5 discloses dielectric properties of constant and loss at 1 MHz and 1 GHz as measured in accordance with ASTM D150M, and dielectric strength as measured in accordance with ASTM D149-09 of the ceramic sintered body as disclosed herein.

TABLE 5

| | | | | | Dielectric |
|---|---|---|---|---|---|
| | | dielectric | | | Strength |
| sample | Frequency | constant | loss tangent | sample | (MV/m) |
| 134 | 1 MHz | 11.56 | <0.0001 | 165 | 14.2 |
| 135 | 1 MHz | 11.65 | 0.0055 | 166 | 13.0 |
| 134 | 1 GHz | 11.03 | <0.0001 | 167 | 11.5 |
| 135 | 1 GHz | 11.06 | <0.0001 | | |

In one embodiment, the ceramic sintered body comprising YAG as disclosed herein has a dielectric loss at ambient temperature of less than 1×10⁻⁴ at a frequency of 1 MHz as measured in accordance with ASTM D150. In another embodiment, the ceramic sintered body disclosed herein has a dielectric loss at ambient temperature of less than 1×10⁻⁴ at a frequency of 1 GHz as measured in accordance with ASTM D150.

Dielectric strengths as listed in Table 5 become important for those applications where high voltage may be applied across the ceramic sintered body or at least a portion of the ceramic sintered body. For example, use as a ceramic sintered body in an electrostatic chucking application, where very high voltages are required to maintain the precise location of a semiconducting substrate during fabrication may require high dielectric strengths to prevent dielectric breakdown, and related conductance, through the ceramic sintered body. In embodiments, the polycrystalline ceramic sintered body as disclosed herein may provide dielectric strengths of greater than 11 MV/m, greater than 12 MV/m, greater than 12.5 MV/m. In alternate embodiments, the polycrystalline ceramic sintered body as disclosed herein may provide dielectric strengths of less than 15 MV/m, less than 14.5 MV/m, less than 14 MV/m. In further embodiments, the ceramic sintered body as disclosed herein may provide dielectric strengths of from 10 to 15 MV/m, from 11 to 15 MV/m, from 12 to 15 MV/m, and from 11 to 14.5 MV/m.

The volume resistivity as measured in accordance with ASTM D257 is listed in Table 6. Those ceramic sintered bodies having high volume resistivities, on the order of from 1×10⁺¹² to 10×10⁺¹³ at ambient temperature may be preferable when used to form ceramic sintered components therefrom useful as wafer chucks, RF or dielectric windows, showerheads and other components where high volume resistivity are required. The polycrystalline ceramic sintered body as disclosed herein may have a volume resistivity of from 1×10⁺¹¹ to 5×10⁺¹² at 300° C., and a volume resistivity of from 1×10⁺⁹ to 5×10⁺⁹ at 500° C.

TABLE 6

| sample | Temp (° C.) | ρ (ohm-cm) |
|---|---|---|
| 112 | 23 | 4.27E+12 |
| 113 | 23 | 4.24E+12 |
| 114 | 23 | 9.92E+13 |
| 112 | 300 | 6.52E+11 |
| 113 | 300 | 1.11E+12 |
| 114 | 300 | 9.44E+12 |
| 114 | 500 | 8.30E+09 |

Rare earth oxide corrosion resistant materials such as the family of yttrium aluminum oxides, when applied as a film or coating by known aerosol or plasma spray techniques, typically exhibit high (on the order of from 3% to 50%) levels of porosity, and thereby low density. Further, these film or spray coatings may exhibit poor interfacial adhesion between the substrate material and the rare earth oxide coating. The monolithic ceramic sintered body comprising at least one of the yttrium aluminum oxide family, and in particular comprising >99 of the cubic YAG phase, having low levels of porosity may provide improved performance in plasma etch and deposition applications and facilitate extensive cleaning to levels required of semiconductor processing systems. This may result in extended component lifetimes, greater process stability and reduced chamber downtime for cleaning and maintenance. Disclosed herein is a nearly dense or fully dense solid body ceramic sintered body having minimal porosity. This minimal porosity may enable reductions in particle generation by preventing entrapment of contaminants in the surface of the ceramic sintered body during etch and deposition processes. Correspondingly, it may be advantageous for the ceramic sintered body to have a small percentage of a surface area comprising porosity, in combination with porosity of small diameters and controlled pore size distribution. The corrosion resistant ceramic sintered body as disclosed herein may have a very high density, for example greater than 97%, greater than 98%, preferably greater than 99%, preferably greater than 99.5%, and correspondingly low porosity below 3%, below 2%, preferably below 1%, preferably below 0.5% in the ceramic sintered body, providing improved etch resistance by way of controlled area of porosity of the surface, frequency of pores, and fine dimensions of porosity.

The forms of yttrium aluminum oxides may be among the most etch resistant materials known, and the use of high purity starting materials to fabricate a ceramic sintered body of very high purity, low volumetric porosity and density as a starting material provides etch resistant properties in a ceramic sintered component. However, highly pure yttrium aluminum oxides pose challenges to sinter to the high densities required for application to semiconductor etch chambers. The material properties of the forms of yttrium aluminum oxides of a high sintering temperature and plasma etch resistance present challenges in sintering to high density/low porosity while maintaining the necessary high purity as sintering aids are often required to achieve high (greater than 98%, 99% or 99.5%) density. This high purity may prevent roughening of the surface of the ceramic sintered body by halogen based gaseous species which may otherwise chemically attack, surface-roughen and etch those components made from powders lower in purity.

For improved corrosion and erosion resistance and chemical inertness, the starting compound oxide powders preferably have very high purity which may be preserved by the disclosed method herein, and thereby provided in the sintered yttrium aluminum oxide body and related components formed therefrom.

The yttrium oxide starting powder may, for example, have a total purity of greater than 99.99%, preferably greater than 99.999%, preferably greater than 99.9995%, and preferably greater than 99.9999%.

Total purity of the aluminum oxide starting powder may, for example, be higher than 99.99%, preferably higher than 99.995%, preferably higher than 99.999%, and preferably higher than 99.9995%.

Total purity of the powder mixture and/or the calcined powder mixture as disclosed herein may, for example, be higher than 99.99%, preferably higher than 99.995%, preferably higher than 99.999%, preferably higher than 99.9995%, and preferably about 99.9999%.

Total purity of the polycrystalline ceramic sintered body comprising YAG as disclosed herein may, for example, be higher than 99.99%, preferably higher than 99.995%, and preferably higher than 99.9995%. In embodiments where zirconia media is used for mixing, zirconia may be present in trace amounts in the ceramic sintered body.

The surface of the ceramic sintered body as disclosed herein, both before and after an etching process, may be correlated to particulate generation in processing chambers. Thus, it is beneficial generally to have a reduced surface roughness. The parameters of Sa (arithmetical mean height), Sz (maximum height) and Sdr (developed interfacial area) were measured on the ceramic sintered body. Generally, surface roughness after a plasma etch process may affect chamber particle generation in that low surface roughness, provided by corrosion resistant materials, reduces the release of contaminate particles into the chamber and correspondingly higher surface roughness after the etch may contribute to particle generation and release onto the wafer. Additionally, smoother surfaces as indicated by the lower surface roughness values of Sa, Sz and Sdr enable the chamber components as disclosed herein to be more easily cleaned to semiconductor grade levels.

### Apparatus/Spark Plasma Sintering Tool

The apparatus for preparing the ceramic sintered bodies disclosed herein is preferably a spark plasma sintering (SPS) tool comprising: a die comprising a sidewall comprising an inner wall and an outer wall, wherein the inner wall has a diameter that defines an inner volume capable of receiving at least one ceramic powder; and an upper punch and a lower punch operably coupled with the die, wherein each of the upper punch and the lower punch have an outer wall defining a diameter that is less than the diameter of the inner wall of the die thereby creating a gap between each of the upper punch and the lower punch and the inner wall of the die when at least one of the upper punch and the lower punch are moved within the inner volume of the die, wherein the gap is from 10 μm to 70 μm wide and the yttrium oxide powder has a specific surface area (SSA) of from 1 to 10 m²/g as measured according to ASTM C1274.

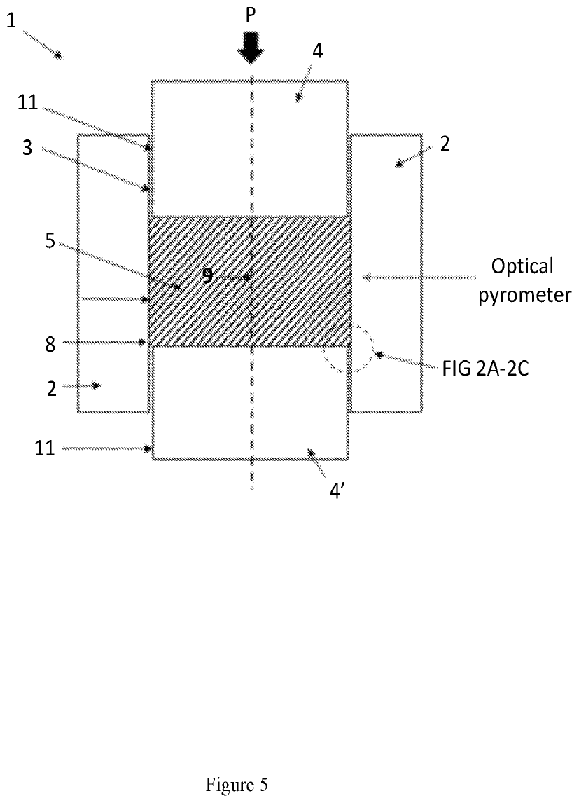

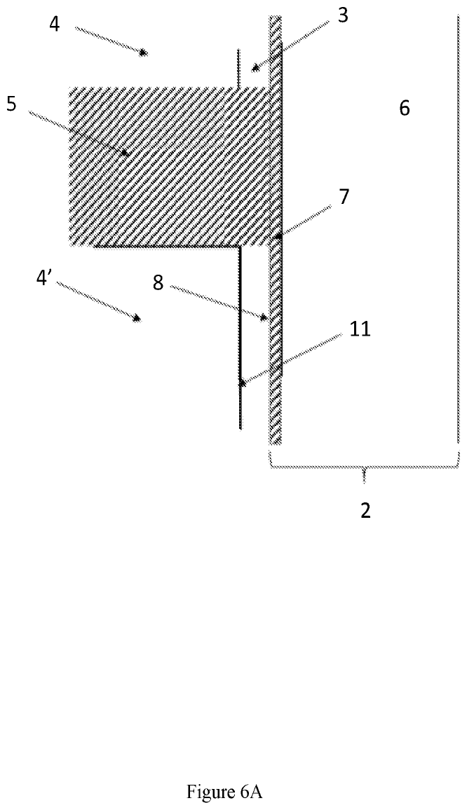

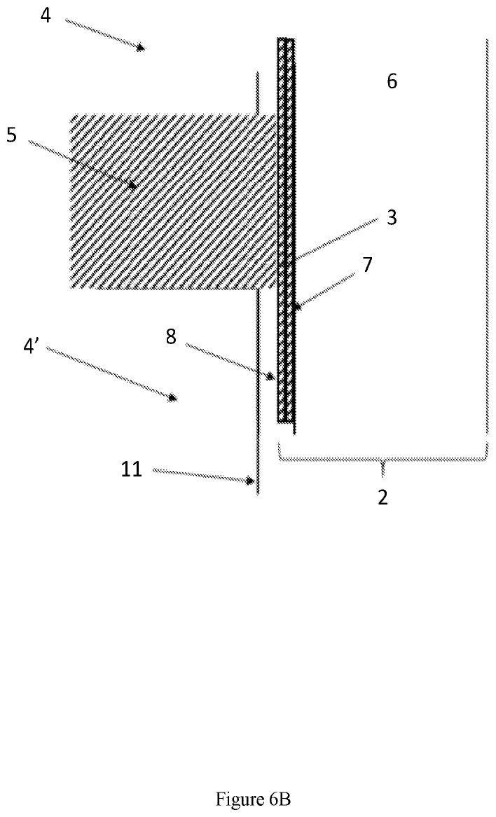

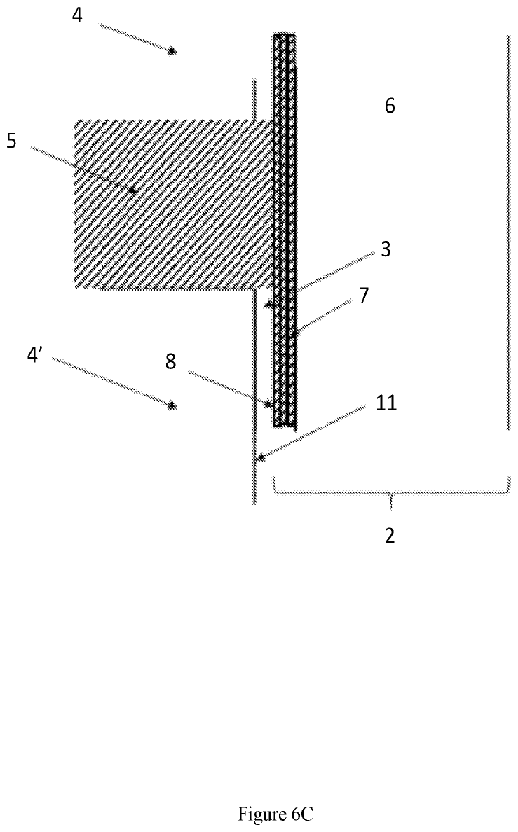

FIG. 5 depicts an SPS tool 1 with a simplified die/punch arrangement used for sintering ceramic powders. Typically, the die/punch arrangement is within a vacuum chamber (not shown) as will be recognized by one of ordinary skill in the art. Referring to FIG. 5, the spark plasma sintering tool 1 comprises a die system 2 comprising a sidewall comprising an inner wall 8 having a diameter that defines an inner volume capable of receiving a yttrium oxide powder 5.

Still referring to FIG. 5, the spark plasma sintering tool 1 comprises an upper punch 4 and a lower punch 4′ operably coupled with the die system 2, wherein each of the upper punch 4 and the lower punch 4′ have an outer wall 11 defining a diameter that is less than the diameter of the inner wall 8 of the die system 2 thereby creating a gap 3 between each of the upper punch 4 and the lower punch 4′ and the inner wall 8 of the die system 2 when at least one of the upper punch 4 and the lower punch 4′ are moved within the inner volume of the die system 2.

The die system 2 and upper 4 and lower 4′ punches may comprise at least one graphite material. In certain embodiments, the graphite material/s disclosed herein may comprise at least one isotropic graphite material. In other embodiments, the graphite material/s disclosed herein may comprise at least one reinforced graphite material such as for example a carbon-carbon composite, and graphite materials comprising fibers, particles or sheets or mesh or laminates of other electrically conductive materials such as carbon in a matrix of an isotropic graphite material. In other embodiments, the die and upper and lower punches may comprise combinations of these isotropic and reinforced graphite materials.

The graphite materials used for some or all of the parts of the tool such as, for example, die 6 and punches 4 and 4′ may comprise porous graphite materials which exhibit a porosity of from about 5% to about 20%, from about 5% to about 17%, from about 5% to about 13%, from about 5% to about 10%, from 5% to about 8%, from about 8% to about 20%, from about 12% to 20%, from about 15% to about 20%, from about 11% to about 20%, from about 5% to 15%, from 6% to about 13%, and preferably from about 7% to about 12%.

Preferably, the graphite material has an average pore size (pore diameter) of from 0.4 to 5.0 μm, preferably from 1.0 to 4.0 μm and comprises pores with a surface pore diameter of up to 30 μm, preferably up to 20 μm, preferably up to 10 μm. More preferably, pores with a surface pore diameter of from 10 to 30 μm may be present.

The graphite materials used for the tool as disclosed herein may have an average grain size of <0.05 mm, preferably <0.04 mm, preferably <0.03 mm, preferably <0.028 mm, preferably <0.025 mm, preferably <0.02 mm, preferably <0.018 mm, preferably <0.015 mm, and preferably <0.010 mm.

The graphite materials used for the tool as disclosed herein may have an average grain size of >0.001 mm, preferably >0.003 mm, preferably >0.006 mm, preferably >0.008 mm, preferably >0.010 mm, preferably >0.012 mm, preferably >0.014 mm, preferably >0.020 mm preferably >0.025 mm and preferably >0.030 mm.

The graphite materials used for the tool as disclosed herein may have a density of ≥1.45 g/cm³, preferably ≥1.50 g/cm³, preferably ≥1.55 g/cm³, preferably ≥1.60 g/cm³, preferably ≥1.65 g/cm³, preferably ≥1.70 g/cm³, and preferably ≥1.75 g/cm³.

The graphite materials used for the tool as disclosed herein may have a density of ≤2.0 g/cm³, preferably 1.90 g/cm³, preferably ≤1.85 g/cm³ and preferably ≤1.80 g/cm³.

In embodiments, the graphite materials have a coefficient of thermal expansion (CTE) across a temperature range from about 400 to about 1400° C. of ≥3.3×10⁻⁶/° C., ≥3.5×10⁻⁶/° C., ≥3.7×10⁻⁶/° C., ≥4.0×10⁻⁶/° C., ≥4.2×10⁻⁶/° C., ≥4.4×10⁻⁶/° C., ≥4.6×10⁻⁶/° C., ≥4.8×10⁻⁶/° C.

In embodiments, the graphite materials may have a coefficient of thermal expansion (CTE) across a temperature range from about 400 to 1400° C. of ≤7.2×10⁻⁶/° C., preferably ≤7.0×10⁻⁶/° C., preferably ≤6.0×10⁻⁶/° C., preferably ≤5.0×10⁻⁶/° C., preferably ≤4.8×10⁻⁶/° C., and preferably ≤4.6×10⁻⁶/° C.

Table 1A lists properties of exemplary graphite materials as disclosed herein.

TABLE 1A

| Property | Range |
|---|---|
| Density (g/cc) | 1.45 to 2.0 |
| Average Grain Size (um) | 1 to < 50 |
| Resistivity (Ohm-cm) | 0.001 to 0.003 |
| Flexural Strength (MPa) | 40-160 |
| Compressive Strength (MPa) | 80-260 |
| CTE (×10⁻⁶/C) at 400° C. to 1400° C. | 3.3 to 7 |
| Porosity % | 5 to 20 |
| Average Pore Diameter (um) | 0.4 to 5 |
| Thermal K (W/m K) | 40-130 |
| Shore Hardness (HSD) | 55 to 59 |
| Tensile Strength (MPa) | 25 to 30 |
| Elastic Modulus (GPa) | 9 to 11 |
| Impurities/Ash (ppm) | 3 to 500 |

The die system 2 comprises a die 6 and optionally but preferably at least one conductive foil 7 located on the inner wall of the die as depicted in the embodiments of FIGS. 3A to 3C. The number of conductive foils on the inner wall of the die is not limited and 1, 2, 3, 4, 5, 6, 7, 8, 9, or 10 conductive foils may be provided as a circumferential liner between die 6 and each of upper 4 and lower 4′ punches whereby the inner wall 8 of the die system 2 (including the at least one conductive foil, if present) and the outer wall 11 of each of the upper and lower punches defines the gap 3. The at least one conductive foil 7 may comprise graphite, niobium, nickel, molybdenum, platinum and other ductile, conductive materials and combinations thereof which are stable within the temperature range according to the method as disclosed herein.

In certain embodiments, the conductive foil may comprise a flexible and compressible graphite foil as disclosed herein having one or more of the following characteristics:
carbon content of more than 99 wt %, preferably more than 99.2 wt %, more preferably more than 99.4 wt %, more preferably more than 99.6 wt %, more preferably more than 99.8 wt %, more preferably more than 99.9 wt %, more preferably more than 99.99 wt %, and more preferably more than 99.999 wt %;
impurities of less than 500 ppm, preferably less than 400 ppm, more preferably less than 300 ppm, more preferably less than 200 ppm, more preferably less than 100 ppm, more preferably less than 50 ppm, more preferably less than 10 ppm, more preferably less than 5 ppm, and more preferably less than 3 ppm;
tensile strength of the graphite foil in a range of from 4.0 to 6.0 MPa, preferably from 4.2 to 5.8 MPa, and more preferably from 4.4 or 5.6 MPa; and/or bulk density of the graphite foil preferably in a range of from 1.0 to 1.2 g/cc, preferably 1.02 to 1.18 g/cc, more preferably 1.04 to 1.16 g/cc, and more preferably 1.06 to 1.16 g/cc.

In embodiments, the at least one foil typically comprises graphite. In certain embodiments, the at least one foil as part of the die system may comprise a circumferential liner between a surface of the die and each of the upper and lower punches.

The graphite foils may improve the temperature distribution across the powder during sintering. Table 2A lists properties of exemplary graphite foils according to embodiments as disclosed herein such as Neograf Grafoil®, Sigraflex® graphite foils, and Toyo Tanso Perma-Foil®.

TABLE 2A

| Thickness (mm) | 0.030 to 0.260 |
|---|---|
| Density (Mg/m3) | 0.5 to 2 |
| Tensile Strength (MPa) | 4.9-6.3 |
| Resistivity (μOhm-m; 25° C.) (parallel to surface) | 5 to 10 |
| Resistivity (μOhm-m; 25° C.) | 900 to 1100 |
| (perpendicular to surface) | |
| CTE (×10⁻⁶/C; parallel to surface) at 350° C. | 5 to 5.5 |
| to 500° C. | |
| CTE (perpendicular to surface) at 350° C. to 500° C. | 2 × 10⁻⁴ |
| Compressibility (%) | 40-50 |
| Recovery (%) | 10 to 20 |
| thermal conductivity (W/mK at 25° C.; | 175 to 225 |
| parallel to surface) | |
| thermal conductivity (W/mK at 25° C.; | ~5 |
| perpendicular to surface) | |
| Impurities/Ash (wt %) | <0.5 |

Referring now to FIGS. 3A, 3B and 3C, an SPS tool set with embodiments of the graphite foil arrangement is shown. A ceramic powder or mixture of powders 5 is disposed between at least one of upper and lower punches 4 and 4′ and gap 3 is shown between the outer wall 11 of each of the upper and lower punches and the inner wall 8 of the die system 2. FIGS. 3A, 3B and 3C depict 1 to 3 layers of conductive foil 7 respectively and die 6 as part of the die system 2. Accordingly, the gap extends from the inner wall 8 of the die system 2 to the outer wall 11 of each of the upper and lower punches. The gap distance is arranged such that the powder may degas before and/or during heating and sintering, while also maintaining ohmic contact between punch and die to improve the temperature distribution across the ceramic powder during heating and sintering.

The graphite foils 7 may have a thickness of, for example, from 0.025 to 0.260 mm, preferably from 0.025 to 0.200 mm, preferably from 0.025 to 0.175 mm, preferably from 0.025 to 0.150 mm, preferably from 0.025 to 0.125 mm, preferably from 0.035 to 0.200 mm, preferably from 0.045 to 0.200 mm, and preferably from 0.055 to 0.200 mm.

The distance of gap 3 is measured from an inwardly facing surface of the foil 7 closest to the upper and lower punches 4 and 4′ to the outer wall 11 of each of the upper and lower punches. Preferred ranges for the distance of gap 3 are preferably from 10 to 70 μm, preferably from 10 to 60 μm, preferably from 10 to 50 μm, preferably from 30 to 70 μm, preferably from 20 to 60 um, and preferably from 30 to 60 μm.

Moreover, the width of gap 3 between the inner wall 8 of the die system 2 and the outer wall 11 of each of the upper 4 and lower 4′ punches may be determined by the person skilled in the art so that the powder degassing during the preheating, heating and sintering processes are sufficiently facilitated on one hand and that a sufficient electrical contact for Joule or resistive heating and, thereby, sintering is achieved on the other hand. If the distance of gap 3 is less than 10 μm, the force required to move at least one of the upper and lower punches within the inner volume of the die system, and thereby assemble the tool set, may cause damage to the tool set. Further, a gap 3 of less than 10 um may not allow for escape of adsorbed gases, organics, humidity and the like within the powder 5 which would extend processing time during manufacturing and may result in residual porosity, and thereby lowered density, in the resulting sintered ceramic body. If the width of gap 3 is greater than 70 μm when sintering ceramic powders, localized overheating may occur, resulting in thermal gradients within the tool set during sintering. As a result, in order to form a sintered ceramic body (such as that disclosed herein) of a large dimension, a gap of from 10 to 70 um is preferable. Thus, in some embodiments, the distance of the gap 3 between the inner wall 8 of the die system 2 and the outer wall 11 of each of the upper and lower punches when sintering yttrium oxide powders is preferably from 10 to 70 μm, preferably from 10 to 60 μm, preferably from 10 to 50 μm, preferably from 10 to 40 μm, preferably from 20 to 70 μm, preferably from 30 to 70 μm, preferably from 40 to 70 μm, preferably from 50 to 70 um, preferably from 30 to 60 μm.

These thermal gradients may result in low overall or bulk density and high-density variations and a sintered ceramic body which is fragile and prone to breakage. As a result, the distance of gap 3 between the inner wall 8 of the die system 2 and the outer wall 11 of each of the upper and lower punches when sintering ceramic powders as disclosed herein is from 10 to 70 μm, preferably from 10 to 60 μm, preferably from 10 to 40 μm, preferably from 20 to 70 μm, preferably from 40 to 70 μm, preferably from 50 to 70 um, preferably from 30 to 70 μm, preferably from 40 to 60 μm. Without intending to be bound by a particular theory, it is believed that the gap distance between the inner wall 8 of the die system 2 and the outer wall 11 of each of the upper and lower punches during sintering functions to facilitate powder degassing of organics, moisture, adsorbed molecules, etc. during the sintering process. This leads to a sintered ceramic body of a large size having high density and low volumetric porosity, low density variation and improved mechanical properties such that the body may be easily handled without breakage. Sintered ceramic bodies made as disclosed herein may have dimensions of from 100 mm to 610 mm with regard to the greatest dimension of the sintered ceramic body.

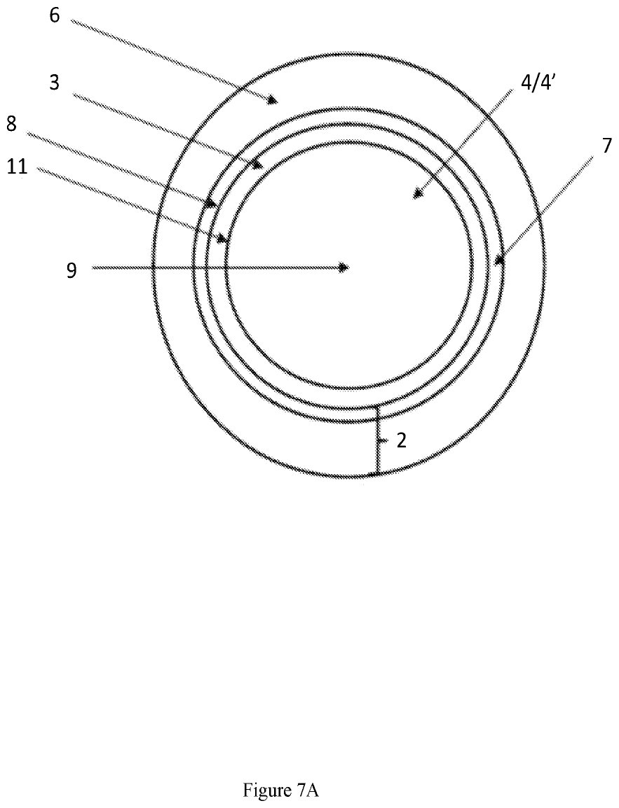

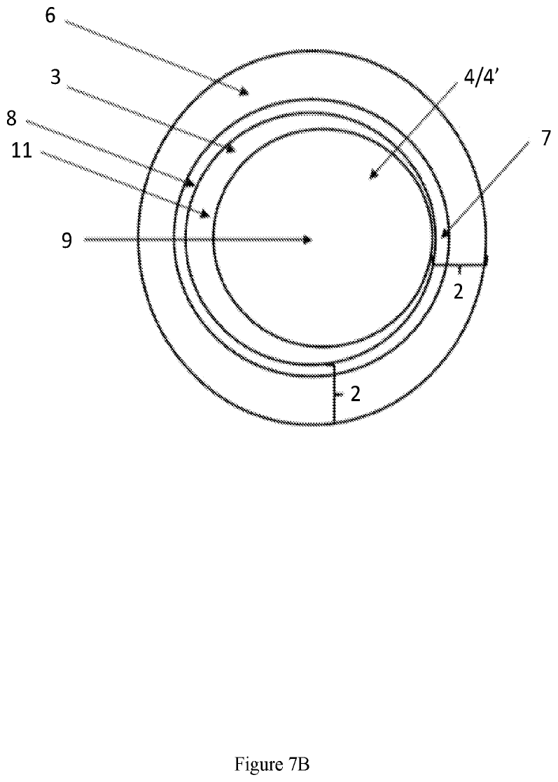

In practice, the upper and lower punches 4 and 4′ are not always perfectly aligned about a central axis. FIG. 7A and FIG. 7B are plan views of the tool set 1, illustrating alignments of upper and lower punches 4 and 4′, gap 3, any number of conductive foils 7, and die system 2 about central axis 9. In embodiments as depicted in FIG. 7A, the gap may be axisymmetric about central axis 9. In other embodiments as depicted in FIG. 7B, the gap may be asymmetric about central axis, 9. The gap 3 may extend between from 10 um to 70 um when sintering the ceramic powder to form a sintered ceramic body as disclosed herein, in both axisymmetric and asymmetric embodiments as depicted.

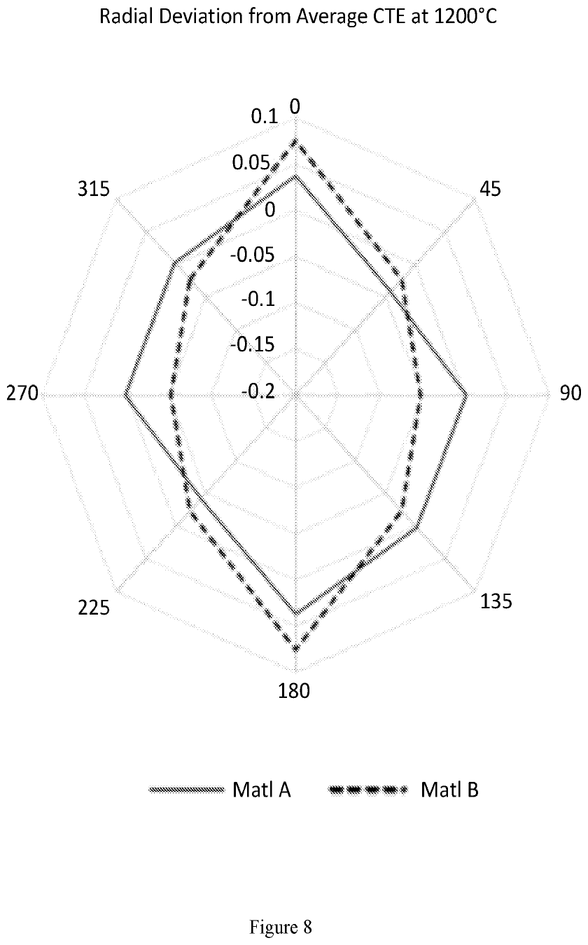

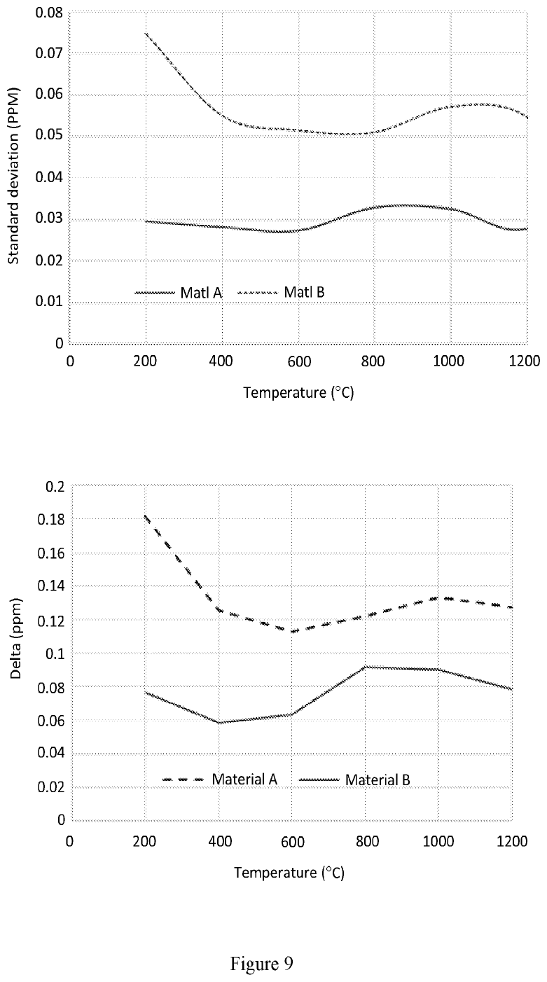

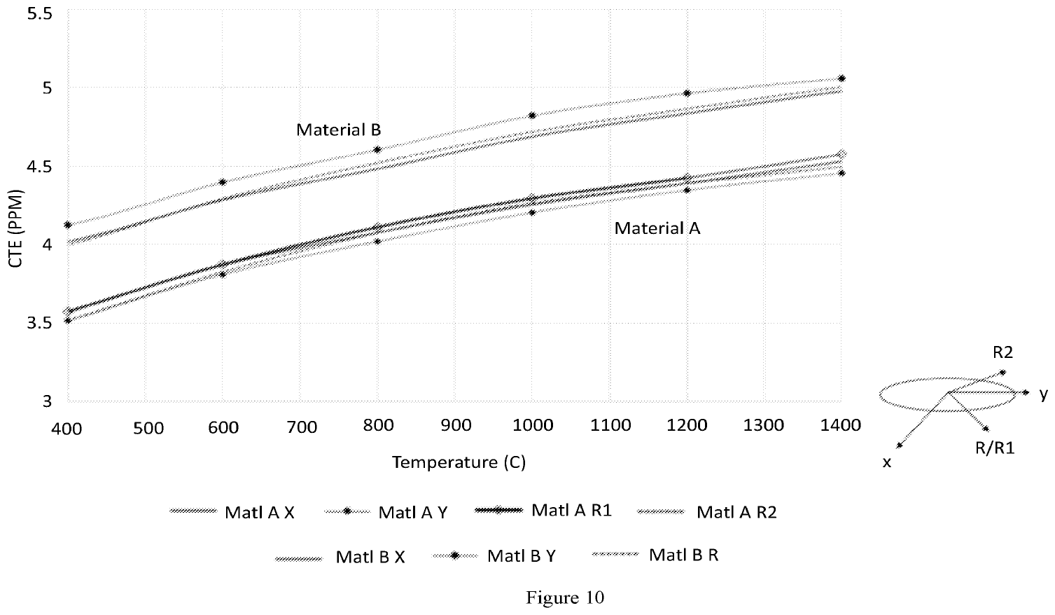

Gap asymmetry performance can be measured by performing an absolute radial CTE deviation analysis over a range of temperatures. For example, FIG. 8 shows the radial deviation from average CTE of two isotropic graphite materials (A and B) used as the punches and die of the apparatus disclosed herein at 1200° C. FIG. 8 shows that for a material to be successful at maintaining the desired gap over a large temperature range, the radial deviation cannot vary in the x-y plane by >0.3×10-6 at the maximum from, e.g., room temperature to 2000° C. Material B displays an unacceptable CTE expansion in the x-y plane whereas Material A exhibited an acceptable CTE expansion throughout the temperature range. FIG. 9 a) shows the standard deviation in ppm of the graphite material CTE and b) the absolute variation (delta) in CTE (from lowest to highest) across the x-y plane of both materials of FIG. 8 across the range of temperatures. FIG. 10 depicts variance in coefficient of thermal expansion of graphite materials A and B from 400 to 1400° C.

The advantages of the specific tool set design used according to an embodiment may lead to the overall technical effect to provide a large ceramic body of very high purity and having a high and uniform density and low volumetric porosity and thereby a reduced tendency towards breakage in the sintering process, in particular in the SPS process, according to the present disclosure. Therefore, all features disclosed with respect to the tool set also apply to the product of a sintered ceramic body of dimension greater than 100 mm.

By using the tool set as disclosed herein it becomes possible to achieve a more homogeneous temperature distribution in the ceramic powder 5 to be sintered, and make a sintered ceramic body, in particular one of large dimension, exceeding for example 100 mm and/or 200 mm in greatest dimension, having very high (>98% of theoretical density of yttrium oxide) and uniform density (<4% variation across a greatest dimension) and thereby a reduced tendency towards breakage. The word “homogeneous” means that a material or system has substantially the same property at every point; it is uniform without irregularities. Thus, by “homogeneous temperature distribution” is meant that the temperature distribution is spatially uniform and does not have considerable gradients, i.e., a substantially uniform temperature exists regardless of position in a horizontal x-y plane along the ceramic powder 5.

The tool set as disclosed may further comprise spacer elements, shims, liners and other tool set components. Typically, such components are fabricated from at least one of the graphite materials having the properties as disclosed herein.

### Method of Preparing

Preparation of the ceramic sintered body may be achieved by use of pressure assisted sintering combined with direct current sintering and related techniques, which employ a direct current to heat up an electrically conductive die configuration or tool set, and thereby a material to be sintered. This manner of heating allows the application of very high heating and cooling rates, enhancing densification mechanisms over grain growth promoting diffusion mechanisms, which may facilitate preparation of ceramic sintered bodies of very fine grain size, and transferring the intrinsic properties of the original powders into their near or fully dense products.

Single Layer Embodiment

A ceramic sintered body is prepared by a method comprising the steps of: a) combining powders comprising yttrium oxide and aluminum oxide to make a powder mixture; b) calcining the powder mixture by applying heat to a calcination temperature and maintaining the calcination temperature to perform calcination and form a calcined powder mixture; c) disposing the calcined powder mixture inside a volume defined by a tool set of a sintering apparatus and creating vacuum conditions inside the volume; d) applying pressure to the calcined powder mixture while heating to a sintering temperature and performing sintering to form the ceramic sintered body; and e) lowering the temperature of the ceramic sintered body. The following additional steps are optional; f) annealing the ceramic sintered body by applying heat to raise the temperature of the ceramic sintered body to reach an annealing temperature to form an annealed ceramic sintered body; g) lowering the temperature of the annealed ceramic sintered body; and h) machining the ceramic sintered body or the annealed ceramic sintered body to create a ceramic sintered component such as a dielectric window or RF window, a focus ring, a nozzle or a gas injector, a shower head, a gas distribution plate, an etch chamber liner, a plasma source adapter, a gas inlet adapter, a diffuser, an electronic wafer chuck, a chuck, a puck, a mixing manifold, an ion suppressor element, a faceplate, an isolator, a spacer, and/or a protective ring in etch chambers.

The above-mentioned characteristics of the corrosion resistant component formed from the ceramic sintered body are achieved by adapting the purity of the powders of yttrium oxide and aluminum oxide, the combining of the powders, the calcination of the powders, the pressure to the powders of yttrium oxide and aluminium oxide, the temperature of the powders of yttrium oxide and aluminium oxide, the duration of sintering the powders, the temperature of the ceramic sintered body/ceramic sintered component during the optional annealing step, and the duration of the optional annealing step. The method as disclosed herein is suitable for the production of ceramic sintered bodies, in particular those of large dimension, using a scalable manufacturing process.

The method disclosed herein provides for the preparation of ceramic sintered bodies and components to include yttrium oxide (Y₂O₃), aluminium oxide (Al₂O₃), yttrium aluminum garnet of composition Y₃Al₅O₁₂ (YAG), yttrium aluminum perovskite of composition YAlO₃ (YAP) and yttrium aluminum monoclinic of composition Y₄Al₂O₉ (YAM), and combinations thereof in a layer to be exposed to a corrosive plasma environment.

In embodiments, the method disclosed herein provides for the preparation of a ceramic sintered body comprising YAG of garnet cubic crystallographic structure or a layer YAG of garnet cubic crystallographic structure in amounts of from 90 to 99.5% by volume of a cubic crystallographic structure, preferably from 90 to 99% by volume of a cubic crystallographic structure, preferably from 95 to 99.5% by volume of a cubic crystallographic structure, preferably from 95 to 99% by volume of a cubic crystallographic structure. In alternate embodiments, a phase of Al₂O₃ in an amount of from 0.1 to 5%, from 0.1 to 3%, from 0.1 to 2%, from 0.1 to 1%, preferably less than 1% by volume may be present in the ceramic sintered body comprising YAG.

In embodiments, the aforementioned ceramic sintered bodies may be made with optional dopants of, for example, a rare earth oxide selected from the group consisting of Sc, La, Er, Ce, Cr, Pr, Nd, Pm, Sm, Eu, Gd, Tb, Dy, Ho, Tm, Yb, and Lu and oxides and combinations thereof in amounts of ≥0.002% by weight, preferably ≥0.0035% by weight, preferably ≥0.005% by weight, and preferably ≥0.0075% by weight, which may be added into the starting powders or powder mixture at step a).

In embodiments, the aforementioned ceramic sintered bodies may be made with optional dopants such as, for example, a rare earth oxide selected from the group consisting of Sc, La, Er, Ce, Cr, Pr, Nd, Pm, Sm, Eu, Gd, Tb, Dy, Ho, Tm, Yb, and Lu and oxides and combinations thereof in amounts of ≤0.05% by weight, preferably ≤0.03% by weight, preferably ≤0.01% by weight, and preferably from 0.002 to 0.02% by weight, which may be added into the starting powders or powder mixture at step a.

In some embodiments, a starting powder comprising yttrium aluminium garnet (YAG) may be used in step a in combination with the optional dopants and/or sintering aids in the ranges as disclosed.

In alternate embodiments as disclosed herein, the aforementioned ceramic sintered bodies may be made without the aforementioned dopants. In particular, for semiconductor chamber applications requiring chemical inertness and resistance to corrosion and erosion, it may be preferable that the ceramic sintered body is free of dopants. Thus, in certain embodiments, the ceramic sintered body is substantially free of, or free of, at least one of, or all of the aforementioned dopants.

Sintering aids may be used as needed in the preparation of the ceramic sintered bodies as disclosed herein, however they are not required and are optional. In specific embodiments, the aforementioned YAG ceramic sintered body may comprise a sintering aid selected from the group consisting of silica, zirconia, calcia, magnesia and combinations thereof. In the case of silica, it may be added in the form of tetraethyl orthosilicate (TEOS). The sintering aids may be added in amounts ≥0.002% by weight, preferably ≥0.0035% by weight, preferably ≥0.005% by weight, and preferably ≥0.0075% by weight.

In specific embodiments, the aforementioned YAG ceramic sintered body may comprise a sintering aid selected from the group consisting of silica, zirconia, calcia, magnesia and combinations thereof. In the case of silica, it may be added in the form of tetraethyl orthosilicate (TEOS). The sintering aids may be added in amounts of ≤0.05% by weight, preferably ≤0.03% by weight, and preferably ≤0.02% by weight.

Using the materials and methods as disclosed herein, high densities, for example 96% and greater of theoretical density for phase pure YAG may be achieved for the ceramic sintered body as disclosed without the use of sintering aids. For certain applications requiring chemical inertness and resistance to corrosion and erosion, it may be preferable that the ceramic sintered body is free of sintering aids. Thus, in embodiments, the ceramic sintered body comprising YAG is substantially free of, or free of, at least one of, or all of the aforementioned sintering aids.

In embodiments, the ceramic sintered body comprising from 90% to 99.8% by volume of polycrystalline YAG may comprise excess yttria and/or alumina beyond that of stoichiometric YAG, which may remain from the process or may be intentionally added during powder batching and preparation. The excess yttria and/or alumina are therefore not considered dopants or sintering aids to the extent they may remain in the ceramic sintered body.

The characteristics of the ceramic sintered body and ceramic sintered components according to an embodiment are achieved in particular by adapting step a) combining powders and b) calcining the powder mixture before sintering, the purity, the particle size and surface area of the starting powders of yttrium oxide, aluminium oxide and where applicable the yttrium aluminium garnet (YAG) powder used in step a), the surface area and uniformity of the starting materials used in step a), the pressure to the powder mixture in step d), the sintering temperature of the powder mixture in step d), the duration of sintering of the powder mixture in step d), the temperature of the ceramic sintered body or component during the optional annealing step in step f), and the duration of the optional annealing step f). In embodiments, the process as disclosed provides for preparation of highly phase pure YAG of greater than 99% by volume cubic crystallographic structure having high (>98%) density, high purity and low porosity. In alternate embodiments, the process as disclosed provides for preparation of highly phase pure YAG of 95% and greater by volume cubic crystallographic structure with a second crystallographic phase of alumina of 5% and less by volume, the sintered body also having high density, high purity and low porosity. In further embodiments, the process as disclosed provides for preparation of mixed phase and/or phase-pure ceramic sintered bodies of yttrium aluminium garnet, Y₃Al₅O₁₂ (YAG), yttrium aluminum perovskite YAlO₃ (YAP) and/or yttrium aluminum monoclinic Y₄Al₂O₉ (YAM) and combinations thereof, having high purity, high density and low porosity. The ceramic sintered body as disclosed is particularly suitable for use in a plasma processing apparatus such as a semiconductor manufacturing apparatus. Such parts or members may include windows, nozzles, gas injectors, shower heads, (etch) chamber liners, mixing manifolds, wafer supports, electronic wafer chucks, and various rings such as focus rings and protective rings, among other components.

Step a) of the method disclosed herein comprises combining powders comprising yttrium oxide and aluminum oxide to make a powder mixture. The starting powder materials of aluminium oxide and yttrium oxide (or in certain embodiments yttrium aluminum garnet (YAG) powder) for forming a corrosion resistant ceramic sintered body and subsequent component are preferably high purity commercially available powders. However, other oxide powders may be used, for example those produced from chemical synthesis processes and related methods. The d50 is defined as the median and represents the value where half of the population resides above this point, and half resides below this point. Similarly, 90 percent of the distribution lies below the d90, and 10 percent of the population lies below the d10.

The d10 particle size of the yttrium oxide powder used as a starting material according to one embodiment of the present invention is preferably from 1 to 7 μm, preferably from 1 to 6 μm, preferably from 1 to 5 μm, preferably from 2 to 7 μm, preferably from 3 to 7 μm, preferably from 4 to 7 μm, and preferably from 5 to 7 μm.

The d50 particle size of the yttrium oxide powder used as a starting material according to one embodiment of the present invention is preferably 3 to 11 μm, preferably from 3 to 9.5 μm, preferably from 3 to 8.5 μm, preferably from 3 to 7.5 μm, preferably from 4 to 11 μm, preferably from 5 to 11 μm, preferably from 6 to 11 μm, and preferably from 7 to 11 μm.

The d90 particle size of the yttrium oxide powder used as a starting material according to one embodiment of the present invention is preferably from 6 to 20 μm, preferably from 6 to 18 μm, preferably from 6 to 16 μm, preferably from 8 to 20 μm, preferably from 10 to 20 μm, preferably from 15 to 20 μm, preferably from 8 to 18 μm, and preferably from 10 to 18 μm.

The yttrium oxide powder usually has a specific surface area (SSA) of from 0.75 to 12 m²/g, preferably from 0.75 to 10 m²/g, preferably from 0.75 to 8 m²/g, preferably from 0.75 to 6 m²/g, preferably from 0.75 to 4 m²/g, preferably from 0.75 to 2 m²/g, preferably from 1 to 6 m²/g, preferably from 1 to 4 m²/g, preferably from 2 to 10 m²/g, preferably from 4 to 10 m²/g, preferably from 6 to 10 m²/g, and preferably from 1 to 4 m²/g.

The purity of the yttrium oxide starting material is preferably higher than 99.99%, preferably higher than 99.995%, preferably higher than 99.999%, more preferably higher than 99.9995%, and more preferably higher than 99.9999%. This corresponds to impurity levels of 100 ppm and less, preferably 50 ppm and less, preferably 25 ppm and less, preferably 10 ppm and less, more preferably about 1 ppm, preferably from 1 to 100 ppm, preferably from 1 to 50 ppm, preferably from 1 to 25 ppm, preferably from 1 to 10 ppm, and preferably from 1 to 5 ppm.

The d10 particle size of the aluminum oxide powder used as a starting material according to one embodiment of the present invention is preferably from 0.05 to 4 μm, preferably from 0.05 to 3 μm, preferably from 0.05 to 2 μm, preferably from 0.05 to 1 μm, preferably from 0.05 to 0.75 μm, preferably from 0.05 to 0.5 μm, preferably from 0.2 to 4 μm, preferably from 0.2 to 3 μm, preferably from 0.2 to 2 μm, preferably from 0.2 to 1 μm, preferably from 0.4 to 4 μm, preferably from 0.4 to 3 μm, preferably from 0.4 to 2 μm, preferably from 0.4 to 1 μm, preferably from 0.75 to 2 μm, preferably from 0.75 to 3 μm, preferably from 1 to 3 μm, and preferably from 2 to 3 μm.

The d50 particle size of the aluminum oxide powder used as a starting material according to one embodiment is usually from 0.15 to 8 μm, preferably from 0.15 to 5 μm, preferably from 0.15 to 3 μm, preferably from 0.15 to 1 μm, preferably from 0.15 to 0.5 μm, preferably from 1 to 8 μm, preferably from 1 to 6 μm, preferably from 1 to 4 μm, preferably from 2 to 6 μm, preferably from 3 to 8 μm, preferably from 4 to 8 μm, preferably from 5 to 8 μm, and preferably from 3.5 to 6.5 μm.

The d90 particle size of the aluminum oxide powder used as a starting material according to one embodiment of the present invention is from 0.35 to 60 um, preferably from 0.35 to 10 um, preferably from 0.35 to 5 μm, preferably from 0.35 to 3 μm, preferably from 0.35 to 1 μm, preferably from 0.35 to 0.75 μm, preferably from 3 to 80 um, preferably from 3 to 60 μm, preferably from 3 to 40 μm, preferably from 3 to 20 μm, preferably from 10 to 60 μm, preferably from 10 to 40 μm, preferably from 10 to 30 μm, preferably from 10 to 20 μm, preferably from 30 to 60 μm, preferably from 15 to 60 μm, preferably from 40 to 60 μm, and preferably from 6 to 15 μm.

The aluminum oxide powder usually has a specific surface area of from 3 to 18 m²/g, preferably from 3 to 16 m²/g, preferably from 3 to 14 m²/g, preferably from 3 to 12 m²/g, preferably from 3 to 10 m²/g, preferably from 3 to 6 m²/g, preferably from 6 to 18 m²/g, preferably from 6 to 14 m²/g, preferably from 8 to 18 m²/g, preferably from 10 to 18 m²/g, preferably from 8 to 10 m²/g, preferably from 4 to 9 m²/g, preferably from 5 to 10 m²/g, and preferably from 6 to 8 m²/g.

The purity of the aluminum oxide starting material is typically higher than 99.99%, preferably higher than 99.995%, preferably higher than 99.999%, and preferably higher than 99.9995%, as measured using ICPMS methods. Correspondingly, the impurity content of the alumina powder may be 100 ppm and less, preferably 50 ppm and less, preferably 25 ppm and less preferably 10 ppm and less, and more preferably 5 ppm and less.

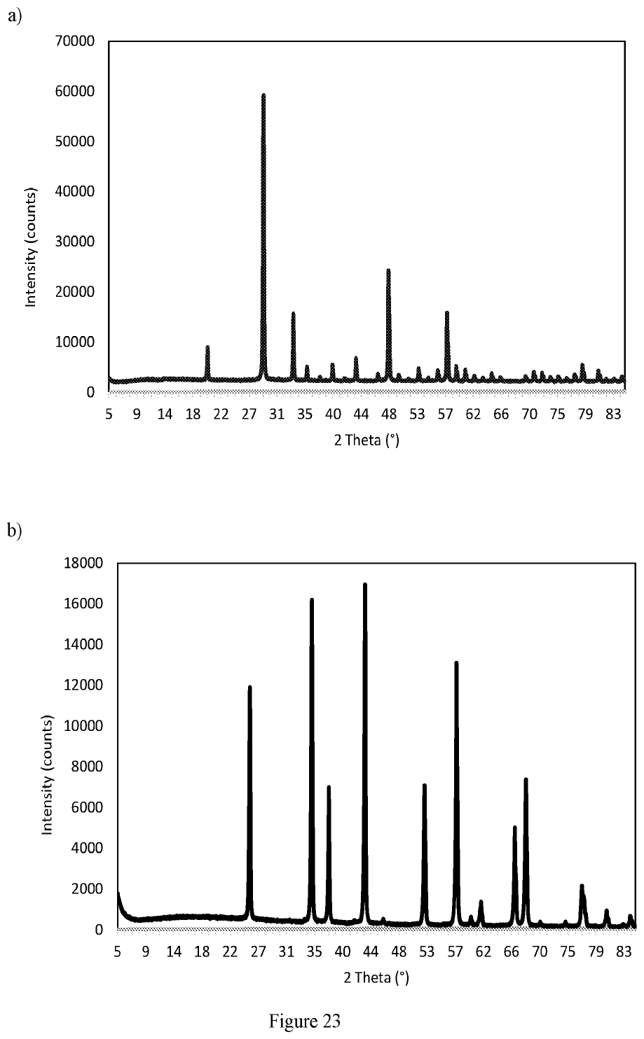

The starting powders as disclosed herein of yttria and alumina are crystalline, and thereby have a long-range crystallographic order. X ray diffraction patterns for exemplary crystalline yttrium oxide and aluminum oxide starting powders as disclosed herein are depicted in FIG. 23 a) and b) respectively. In embodiments, the aluminum oxide powder depicted in b) may comprise from 80 to 100% by volume of the alpha alumina crystallographic phase, preferably from 90 to 100% by volume of the alpha alumina crystallographic phase, and preferably from 95 to 100% by volume of the alpha alumina crystallographic phase.

Starting powders having high surface areas such as those exceeding 20 m²/g pose issues in handleability when loading the tool set with powder and achieving uniform dispersion and intimate mixing during the powder combination/mixing step. The starting powders in accordance with the method as disclosed herein comprise yttria and alumina and preferably may have d50 or median particles sizes as disclosed which may exceed those of nanopowders as defined herein. In embodiments, the starting powders, the powder mixture and calcined powder mixture according to the method as disclosed herein comprise a d50 particle size greater than that of nanopowders and as such, the starting powders, the powder mixture and calcined powder mixture are substantially free of, or free of, nanopowders as defined herein.

Starting powders having specific surface area of less than about 0.5 m²/g may suffer from agglomeration and require higher energy for mixing and longer mixing times and may reduce the sintering activation energy of the yttria/alumina calcined powder mixture during step d). The particle size distributions and specific surface areas disclosed herein for the yttrium oxide and aluminium oxide starting powders provide sufficient handleability and thorough mixing during step a) powder combining of the method as disclosed herein.

In embodiments, the d50 particle size of the commercially available yttrium aluminium garnet (YAG) powder used as a starting material/powder is typically from 3 to 10 μm, preferably from 4 to 9 μm, and more preferably from 5 to 8 μm. The yttrium aluminium garnet (YAG) powder typically has a specific surface area of from 3 to 10 m²/g, preferably from 3 to 8 m²/g, and more preferably from 4 to 6 m²/g. The purity of the yttrium aluminium garnet (YAG) powder starting material is typically higher than 99.99%, preferably higher than 99.999%.

In certain embodiments, formation of greater than 99.5 volume % phase pure YAG sintered bodies may be affected by the yttria and alumina particle size distribution, purity, surface area of the starting powders, mixing and calcination steps.

Table 7 lists characteristics of the starting materials as disclosed to form a sintered body comprising YAG. Particle sizes for the starting powders, powder mixtures and calcined powder mixtures were measured using a Horiba model LA-960 Laser Scattering Particle Size Distribution Analyzer capable of measuring particle size from 10 nm to 5 mm. Specific surface area for the starting powders, powder mixtures and calcined powder mixtures was measured using a Horiba BET Surface Area Analyzer model SA-9601 capable of measuring across a specific surface area of 0.01 to 2000 m²/g with an accuracy of 10% and less for most samples.

TABLE 7

| | d10 (um) | d50 (um) | d90 (um) | SSA (m2/g) |
|---|---|---|---|---|
| yttrium oxide | 1 to 7 | 3 to 11 | 6 to 20 | 0.75 to 12 |
| aluminum oxide | 0.05 to 4 | 0.15 to 8 | 0.35 to 60 | 3 to 18 |

In embodiments, the ceramic sintered body comprising from 90% to 99.8% by volume of polycrystalline yttrium aluminium garnet (YAG) garnet cubic phase (Y₃Al₅O₁₂) may be formed from a stoichiometric powder mixture of 37.5 mol % yttrium oxide and 62.5 mol % aluminum oxide. Studies reported in “Mechanisms of nonstoichiometry in Y₃Al₅O₁₂” Patel et al, 2008, Appl. Phys. Lett. 93, 191902 (2008) indicated that the width of the phase domain may have a variance of 0.1 mol % and less. Thus, deviations of 0.1 mol % and less from that of stoichiometric YAG (37.5% alumina/62.5% yttria) may result in formation of phase pure yttrium aluminum oxide garnet. Accordingly, in embodiments a ceramic sintered body comprising yttrium aluminium garnet (YAG) garnet cubic phase (Y₃Al₅O₁₂) in an amount of greater than 99% by volume may be formed from starting powders combined into a powder mixture in a ratio of from 37.4 to 37.6 mol % yttrium oxide and 62.6 and 62.4% mol aluminum oxide. By weight, a powder mixture may be formed from about 42.9 to 43.4% alumina and 57.1 to 56.6% yttria.

Combining the aforementioned starting powders comprising yttrium oxide and aluminium oxide to make a powder mixture may be performed using the powder preparation techniques of wet or dry ball (axially rotating) milling, wet or dry tumble (end over end or vertical) mixing and combinations of these.

Ball milling or end over end tumble mixing under dry conditions may be accomplished using high purity (>99.99%) alumina media in order to preserve the purity of the starting powders during mixing. The high purity alumina media used herein was tested using ICPMS methods and found to have a purity of 99.997%. In other instances where agglomeration may be of concern, a harder media such as zirconium oxide may be used. Use of zirconia media may result in trace amounts, such as less than 100 ppm, of zirconia in the ceramic sintered body. Thus, in certain embodiments disclosed herein is a ceramic sintered body comprising phase pure YAG having zirconia in amounts of less than 100 ppm, preferably less than 50 ppm, preferably from 10 to 100 ppm, preferably from 10 to 50 ppm, more preferably from 20 to 40 ppm. Media loading for dry ball or tumble mixing may vary between a large dimension (about 30 mm) media element to a media loading of about 50% by powder weight. Dry milling or mixing may be performed for durations of from 12 to 48 hours, preferably from 16 to 48 hours, preferably from 24 to 48 hours, using an RPM of from 50 to 200 RPM, preferably from 75 to 150 RPM, preferably from 100 to 125 RPM.

Wet ball milling or tumble mixing may be performed by suspending the starting powders in various solvents such as ethanol, methanol, and other alcohols, and/or water to form a slurry. The slurry may be formed having a powder loading during milling or mixing of from 5 to 50% by powder weight, preferably from 10 to 40% by powder weight, preferably from 20 to 40% by powder weight. Wet mixing or milling provides for improved dispersion of the powders through increased mobility, resulting in fine scale, uniform mixing before heat treatment or calcination. In specific embodiments, a dispersant may optionally be added to the slurry using any number of commercially available dispersants such as for example poly methyl methacrylate (PMMA) and polyvinyl pyrrolidone (PVP). The dispersant may optionally be added in amounts from zero (no dispersant) to 0.2% by powder weight, preferably from 0 to 0.1% by powder weight. Media loadings may be varied from having no media used during milling, to media at a loading of 50% and greater by powder weight, preferably from 40 to 100% by powder weight, preferably 60 to 100% by powder weight, preferably from 50 to 80% by powder weight. Wet ball milling or tumble mixing may be performed for durations of from 8 to 48 hours, preferably from 12 to 48 hours, preferably from 16 to 48 hours, preferably from 8 to 36 hours, preferably from 8 to 24 hours, preferably from 8 to 12 hours. Ball milling may use an RPM of from 50 to 200 RPM, preferably from 75 to 150 RPM, preferably between 100 and 125 RPM for containers having up to about 200 mm diameter. End over end tumble mixing may be performed at an RPM of from 10 to 30 rpm, preferably about 20.

Jet milling processes as known to those skilled in the art may also be used to thoroughly mix the powders to form a powder, powder mixture or calcined powder mixture having a narrow particle size distribution. Jet milling uses high velocity jets of either inert gases or air to collide particles of the starting powders and/or powder mixtures and/or calcined powder mixtures without the use of milling or mixing media, thus preserving initial purity of the powder to be milled. The chamber may be designed such that larger particles may be preferentially reduced in size, which may provide a narrow particle size distribution in the final powders, powder mixture or calcined powder mixture. Powders exit the jet milling chamber upon reaching a desired particle size as determined at setup of the machine prior to processing. Starting powders, powder mixtures and/or calcined powder mixtures as disclosed herein may be subjected to jet milling at pressures of about 100 psi, whether separately, or in combination with any, or all of, the as disclosed powder milling/mixing processes as disclosed herein. After jet milling, the powders or powder mixtures may be optionally sieved using any number of meshes which may have openings of for example from 45 to 400 um, and blended, without limitation as to repetition or order.

Use of wet ball milling, tumble mixing and/or jet milling are high energy processes which break down particulates and agglomerates, improves dispersion through increased particle mobility and may provide for fine scale mixing, providing a homogeneous powder mixture prior to calcination. The additional powder preparation procedures of attrition milling, high shear mixing, planetary milling, and other procedures as known to those skilled in the art may also be applied. The slurry may be dried by rotary evaporation methods. In other embodiments, the slurry may be dried using spray drying techniques as known in the art. Before or after drying, the powder mixture may be sieved using a mesh having openings of for example from 35 to 75 um. The aforementioned powder preparation techniques may be used alone or in any combination thereof.

After drying, the surface area of the powder mixture of step a. may be from 2 to 17 m²/g, from 2 to 14 m²/g, from 2 to 12 m²/g, from 2 to 10 m²/g, from 4 to 17 m²/g, from 6 to 17 m²/g, from 8 to 17 m²/g, from 10 to 17 m²/g, from 4 to 12 m²/g, from 4 to 10 m²/g, and from 5 to 8 m²/g.

The purity of the powder mixture may be maintained after mixing/milling from that of the starting materials through the use of milling media of high purity, for example aluminum oxide media of purity 99.99% and greater. In embodiments, use of zirconium oxide milling media may be preferable and may introduce zirconium oxide present in the final ceramic sintered body in amounts of from 20 to 100 ppm, from 20 to 75 ppm, preferably from 20 to 50 ppm, and preferably from 20 to 30 ppm.

Step b) of the method disclosed herein comprises heating the powder mixture to a calcination temperature and maintaining the calcination temperature for a duration to form a calcined powder mixture. Calcination as disclosed herein may be performed under ambient pressure in an oxygen containing environment, although other pressures and calcination environments may be used.

Calcination may be performed to remove moisture and ensure the surface condition of the powder mixture is uniform prior to sintering. In certain embodiments, calcination may be performed to reduce surface area. In other embodiments, calcination does not cause a reduction in surface area of the starting powders.

Calcination in accordance with the heat treatment step may be performed at temperatures of from 600° C. to 1100° C., preferably from 600 to 1000° C., preferably from 600 to 900° C., preferably from 700 to 1100° C., preferably from 800 to 1100° C., preferably from 800 to 1000° C., and preferably from 850 to 950° C. Calcination may be performed for durations of from 4 to 12 hours, preferably from 4 to 10 hours, preferably from 4 to 8 hours, preferably from 6 to 12 hours, preferably from 4 to 6 hours in an oxygen containing environment. After calcination, the powder mixtures may be sieved through for example a mesh screen having openings of from 45 to 400 μm, and/or tumbled and/or blended according to known methods to form the calcined powder mixture.

The calcined powder mixture to form the YAG phase may have a d10 particle size of preferably from 0.06 to 4 μm, preferably from 0.08 to 4 μm, preferably from 0.1 to 4 μm, preferably from 0.2 to 4 μm, preferably from 0.3 to 4 μm, preferably from 0.4 to 4 μm, preferably from 0.08 to 3 μm, preferably from 0.08 to 2 μm, preferably from 0.08 to 1 μm, preferably from 0.5 to 3 μm, preferably from 1 to 2 μm, and preferably from 1 to 3 μm.

The d50 particle size of the calcined powder mixture may vary from 0.7 to 50 μm, preferably from 1 to 40 μm, preferably from 1 to 30 μm, preferably from 1 to 20 μm, preferably from 1 to 10 μm, preferably from 1 to 5 μm, preferably from 5 to 50 μm, preferably from 10 to 50 μm, preferably from 20 to 50 μm, preferably from 30 to 50 μm, preferably from 3 to 8 μm, preferably from 5 to 10 μm, and preferably from 6 to 15 μm.

The d90 particle size of the calcined powder mixture may be preferably from 10 to 350 μm, preferably from 10 to 300 μm, preferably from 10 to 250 μm, preferably from 10 to 200 μm, preferably from 10 to 175 μm, preferably from 10 to 150 μm, preferably from 10 to 100 μm, preferably from 10 to 75 μm, preferably from 10 to 50 μm, preferably from 10 to 40 μm, preferably from 10 to 30 μm, preferably from 15 to 45 μm, preferably from 20 to 40 μm, preferably from 20 to 350 μm, preferably from 40 to 350 μm, preferably from 60 to 350 μm, preferably from 100 to 350 μm, preferably from 150 to 350 μm, preferably from 200 to 350 μm, preferably from 12 to 330 μm, preferably from 100 to 330 μm, and preferably from 100 to 250 μm.

In certain embodiments, the calcination conditions as disclosed herein may result in formation of one or more of the crystalline phases of YAP, YAM and YAG and combinations thereof, and/or agglomeration of the powder mixture and thus a broad range of particle or agglomerate sizes may result. Thus, in embodiments, the particle size as referred to herein may include a single particle and in other embodiments, the particle size as referred to herein may include an agglomerate comprising more than one particle or an agglomeration of multiple particles which may be measured, using the laser particle size detection methods as disclosed herein, as a single, large particle. Particles comprising either or both of a single particle or an agglomerate of multiple particles may comprise at least one crystalline phase selected from the group consisting of yttrium oxide, aluminum oxide, yttrium aluminium perovskite (YAP), yttrium aluminium monoclinic (YAM), and YAG (garnet) phase, and combinations thereof. In other embodiments, lower temperature calcination conditions as disclosed herein may not affect particle size distributions relative to the starting materials and particle size distributions are in the same range, or similar to, the starting powder materials. Lot to lot variation and management of heat transfer during calcination may also contribute to broadened particle size distributions. The starting powders, powder mixtures and/or the calcined powder mixtures as disclosed herein may be subjected to any one or a combination of the mixing/milling processes as disclosed herein. Thus, a broad range of particle size distributions may result from calcination conditions and processes as disclosed herein.

The calcined powder mixture may have a specific surface area of from 2 to 12 m²/g, preferably from 2 to 10 m²/g, preferably from 2 to 8 m²/g, preferably from 2 to 6 m²/g, preferably from 4 to 12 m²/g, preferably from 6 to 12 m²/g, preferably from 8 to 12 m²/g, preferably from 4 to 10 m²/g, preferably from 6 to 10 m²/g, preferably from 8 to 10 m²/g, preferably from 3 to 9 m²/g, preferably from 2 to 8 m²/g, and preferably from 4 to 8 m²/g, preferably from 4 to 6 m²/g.

Table 8 lists ranges of measured particle sizes and specific surface area (SSA) characteristics as measured by laser particle size and BET methods and equipment as disclosed herein for calcined powder mixtures used to form a ceramic sintered body comprising YAG as disclosed herein.

TABLE 8

| Powder | d10 (um) | d50 (um) | d90 (um) | SSA (m2/g) |
|---|---|---|---|---|
| 247 | 0.12 to 0.18 | 3.2 to 4.3 | 12 to 16 | 4 to 5 |
| 359-05 | 0.36 to 0.51 | 7.3 to 9.8 | 25 to 36 | 3 to 4 |
| 286 | 0.29 to 0.41 | 4.8 to 6.6 | 17 to 24 | 3 to 4 |
| (19 ppm Zr) | | | | |
| 299 | 0.16 to 0.22 | 6.4 to 8.7 | 30 to 42 | 3 to 4 |
| 300 | 0.18 to 0.25 | 6.7 to 9.1 | 23 to 33 | 3 to 4 |
| 247-1 | 0.21 to 0.3 | 5.1 to 6.8 | 126 to 178 | 3.5 to 4.5 |
| 12 | 0.52 to 0.73 | 4.9 to 6.6 | 93 to 132 | 3.5 to 4.5 |
| 8 | N/A | N/A | N/A | 2.5 to 3.5 |
| 279 | N/A | N/A | N/A | 4.5 to 5.5 |
| (25 ppm SiO2) | | | | |
| 280 | N/A | N/A | N/A | 9 to 10 |
| (160 ppm | | | | |
| CeO2) | | | | |
| 347 | 0.4 to 0.57 | 6.4 to 8.6 | 54 to 77 | 3 to 4 |
| (300 ppm | | | | |
| Yb2O3) | | | | |
| 092-3 | 0.18 to 0.26 | 6.6 to 8.9 | 107 to 151 | 7 to 8 |
| 194-2 | 0.86 to 1.22 | 25 to 33 | 201 to 283 | 4 to 5 |
| 092-1 | 2.03 to 2.87 | 9.6 to 13 | 168 to 238 | 2.5 to 3 |
| 615 | 0.54 to 0.77 | 34 to 47 | 235 to 332 | 3.5 to 4.5 |
| 359-09 | 0.14 to 0.2 | 4.9 to 6.7 | 17 to 24 | 4 to 5 |
| 359-06 | 0.37 to 0.52 | 7.6 to 10.2 | 19 to 27 | 3.5 to 4.5 |
| 359-11 | 0.14 to 0.2 | 4.9 to 6.7 | 17 to 24 | 4 to 5 |
| 381 | 0.1 to 0.15 | 4.6 to 6.3 | 20 to 28 | 4 to 5 |
| 398 | 0.09 to 0.13 | 4.9 to 6.7 | 63 to 89 | 7.5 to 8.5 |

Phase identification of the calcined powder mixtures and ceramic sintered bodies as disclosed herein was performed using a PANanlytical Aeris model XRD capable of crystalline phase identification to about +/−5%. Dependent upon the calcination conditions of temperature and duration, in embodiments, calcination may result in a calcined powder mixture comprising yttrium oxide and aluminium oxide. In other embodiments, the calcination conditions may result in a calcined powder mixture comprising at least one crystalline phase selected from the group consisting of yttrium oxide, aluminium oxide and the YAM (monoclinic) phase. In other embodiments, the calcination conditions may result in a calcined powder mixture comprising yttrium oxide, aluminium oxide, the YAM (monoclinic) phase and the YAP phase. In alternate embodiments, the calcination conditions may result in a calcined powder mixture comprising the YAM (monoclinic) phase and the YAP (perovskite) phase; in further embodiments, the calcination conditions may result in a calcined powder mixture comprising the YAP (perovskite) phase and the YAG (garnet) phase which may be present in amounts of less than 10% by volume, preferably less than 8% by volume, preferably less than 5% by volume. In embodiments, the calcined powder mixture comprises at least one crystalline phase selected from the group consisting of yttrium oxide, aluminum oxide, yttrium aluminium perovskite (YAP), yttrium aluminium monoclinic (YAM) and combinations thereof. In embodiments, the calcined powder mixture comprises at least one crystalline phase selected from the group consisting of yttrium oxide, aluminum oxide, yttrium aluminium perovskite (YAP), yttrium aluminium monoclinic (YAM), and YAG (garnet) phase wherein the YAG phase is present in an amount of less than 10% by volume, preferably less than 8% by volume, preferably less than 5% by volume, and combinations thereof. In alternate embodiments, the calcination conditions may result in a calcined powder mixture comprising the YAG (garnet) phase in amounts of less than 10% by volume, preferably less than 8% by volume, preferably less than 5% by volume. Calcination of the powder mixture will result in a calcined powder mixture which is crystalline, comprising one or more crystalline phases as disclosed herein, and combinations thereof.

Table 9 lists calcination conditions, crystalline phases and purity of the calcined powder mixtures according to preferred embodiments disclosed herein. All purity measurements disclosed herein are those reported above the reporting limit for a specific element and were completed using an ICP-MS from Agilent 7900 ICP-MS model G8403.

TABLE 9

| Powder | Temp (° C.) | Time (hr) | Phase/s | % Purity |
|---|---|---|---|---|
| 247 | 600 | 8 | Y2O3, Al2O3 | 99.9996 |
| 359-05 | 850 | 4 | Y2O3, Al2O3 | 99.9983 |
| 286 (19 ppm Zr) | 850 | 12 | N/A | 99.9969 |
| 299 | 850 | 4 | Y2O3, Al2O3 | 99.9989 |
| 300 | 850 | 4 | Y2O3, Al2O3 | 99.9991 |
| 247-1 | 900 | 4 | Y2O3, Al2O3 | 99.9996 |
| 012 | 950 | 4 | Y2O3, Al2O3 | 99.9996 |
| 008 | 950 | 8 | Y2O3, Al2O3 | 99.9996 |
| 279 (25 ppm | 950 | 4 | N/A | 99.9969 |
| SiO2) | | | | |
| 280 (160 ppm | 950 | 4 | N/A | 99.9840 |
| CeO2) | | | | |
| 347 (300 ppm | 950 | 4 | N/A | 99.9700 |
| Yb2O3) | | | | |
| 092-3 | 1000 | 8 | Y2O3, Al2O3 | 99.9985 |
| 194-2 | 1000 | 10 | Y2O3, Al2O3 | 99.9998 |
| | | | YAM | |
| 092-1 | 1100 | 8 | YAP, YAG (<10 | 99.9985 |
| | | | vol %) | |
| 516 (ex 1) | 1000 | 8 | N/A | 99.9996 |
| 518 (ex 2) | 1000 | 4 | N/A | 99.9956 |
| 525 (ex 3) | 1000 | 8 | N/A | 99.9968 |
| 615 (54 ppm Zr) | 1100 | 8 | N/A | 99.9927 |
| 359-09 | 850 | 6 | Y2O3, Al2O3 | 99.9983 |
| 359-06 | 850 | 6 | Y2O3, Al2O3 | 99.9983 |
| 359-11 | 850 | 6 | Y2O3, Al2O3 | 99.9983 |
| 381 | 850 | 6 | Y2O3, Al2O3 | N/A |
| 398 | 850 | 6 | Y2O3, Al2O3 | N/A |

In accordance with the disclosure herein, a ceramic sintered body comprising yttrium aluminum garnet (YAG) phase may be formed by in situ, reactive sintering during the sintering step by way of specific properties of particle size distribution, purity and/or surface area of the calcined powder mixture as disclosed. In specific embodiments, it may be preferred that the calcined powder mixture comprises less than 10% by volume of YAG, preferably less than 8% by volume of YAG, preferably less than 5% by volume of YAG; in other embodiments disclosed herein is a calcined powder mixture which is free of YAG. In other embodiments, it may be preferred that the calcined powder mixture has a specific surface area of greater than 2 m²/g, preferably greater than 2.5 m²/g. In other embodiments, it is preferable that the calcined powder mixture is free of a YAG phase and having a specific surface area of 2 m²/g and greater in order to form a ceramic sintered body comprising YAG through the in situ, reactive phase sintering process as disclosed herein. Table 10 lists properties of the calcined powder mixtures which are not preferable according to the disclosure.

TABLE 10

| | d10 | d50 | | SSA | Temp | Time | |
|---|---|---|---|---|---|---|---|
| Powder | (um) | (um) | d90(um) | (m2/g) | (° C.) | (hr) | Phase/s |
| 127-1 | 30 | 68 | 243 | 0.01 | 1100 | 8 | YAG |
| 125-1 | 6 | 22 | 326 | 1 | 1100 | 8 | YAP/YAG |
| 092-2 | N/A | N/A | N/A | 0.25 | 1200 | 8 | YAG |

Step c) of the method disclosed herein is disposing the calcined powder mixture inside a volume defined by a tool set of a sintering apparatus and creating vacuum conditions inside the volume. A sintering apparatus used in the process according to an embodiment comprises at least a graphite die which is typically a cylindrical graphite die. In the graphite die the powder mixture is disposed between at least two graphite punches. At least one calcined powder mixture may be loaded into the die of the sintering apparatus. Vacuum conditions as known to those skilled in the art are established within the powder between the punches surrounded by the die. Typical vacuum conditions include pressures of 10⁻² to 10⁻³ torr. The vacuum is applied primarily to remove air to protect the graphite from burning and to remove a majority of the air from the powder. The method as disclosed herein provides a process for production of ceramic sintered bodies and/or ceramic sintered components which is scalable and compatible with commercial manufacturing methods. The method utilizes powders having micron-sized particle distributions which are commercially available powders and/or prepared from chemical synthesis techniques, without the need for sintering aids, cold pressing, forming or machining a green body prior to sintering.

In another embodiment, a multilayer sintered body can be formed by separately disposing in a layered manner the alumina and yttria powder mixture as described above and at least one other ceramic powder of a different composition or a different ceramic powder mixture depending on the desired composition of the layers. For example, a second layer may comprise at least one crystalline phase comprising alumina and zirconia, wherein the zirconia is present in an amount of from 5 to 25%, preferably from 10 to 25%, preferably from 15 to 25%, preferably from 15 to 17%, preferably from 20 to 25%, preferably from 5 to 20%, preferably from 5 to 15%, preferably from 5 to 10%, preferably from 15 to 20% each by volume of the sintered ceramic body. The mixtures of alumina and zirconia can be prepared and calcined as detailed above. In such embodiments, the zirconia is preferably evenly dispersed throughout the alumina.

In such mixtures comprising zirconia, the zirconia powder may have a particle size distribution having a d10 of between 0.08 and 0.20 um, a d50 of between 0.3 and 0.7 um and a d90 of between 0.9 and 5 μm. The average particle size of the zirconia powder used as a starting material for the mixture according to one embodiment of the present invention may be from 0.3 to 1 um.

The zirconia powder preferably has a specific surface area of from 1 to 16 m²/g, preferably between 2 to 12 m²/g, and more preferably between 5 to 9 m²/g, and the purity of the zirconia powder starting material is typically higher than 99.5%, preferably higher than 99.8%, preferably higher than 99.9%, preferably higher than 99.99%. This corresponds to a total impurity content of 5000 μm and less, preferably 2000 ppm and less, preferably 1000 ppm and less, preferably 100 ppm and less.

In preferred multilayer embodiments wherein the process component comprises a substrate layer and a surface layer, the substrate layer comprises at least one crystalline phase comprising alumina and zirconia, wherein the zirconia is present in an amount of from 5 to 25%, preferably from 10 to 25%, preferably from 15 to 25%, preferably from 15 to 17%, preferably from 20 to 25%, preferably from 5 to 20%, preferably from 5 to 15%, preferably from 5 to 10%, and preferably from 15 to 20% each by volume of the sintered ceramic body; and the surface layer comprises at least one crystalline phase of yttrium aluminum oxide, wherein the at least one crystalline phase of yttrium aluminum oxide comprises pores having a pore size not exceeding 5 μm and having a maximum pore size of 1.5 μm for at least 95% of the pores.

In such embodiments, preferably the layer of YAG and the at least one other layer have closely matching coefficients of thermal expansion (CTE) across a temperature range of from about 200° C. to about 1700° C. Preferably, the differences in CTE are 0.5×10-6/° C. and less, preferably 0.4×10-6/° C. and less, preferably 0.3×10-6/° C. and less, preferably 0.2×10-6/° C. and less, preferably 0.1×10-6/° C. and less, preferably 0.09×10-6/° C., preferably 0.07×10-6/° C. and less, and preferably 0.05×10-6/° C. and less.

Step d) of the method disclosed includes applying pressure to the calcined powder mixture (or layers of powders and/or powder mixtures as may be the case) while heating to a sintering temperature and performing sintering to form the ceramic sintered body, and step e) may comprise lowering the temperature of the ceramic sintered body by, for example, removing the heat source to the sintering apparatus to cool the ceramic sintered body. Pressure may be applied to the calcined powder mixture disposed between the graphite punches and increased to a pressure of from 5 MPa to 100 MPa, preferably from 5 MPa to 60 MPa, preferably from 5 MPa to 40 MPa, preferably from 5 MPa to 20 MPa, preferably from 5 MPa to 15 MPa, preferably from 10 MPa to 60 MPa, preferably from 10 MPa to 40 MPa, preferably from 10 MPa to 30 MPa, preferably from 10 MPa to 20 MPa, preferably from 13 MPa to 18 MPa, preferably from 15 MPa to 60 MPa preferably from 15 MPa to 40 MPa, preferably from 15 MPa to 30 MPa, and preferably from 20 to 40 MPa. The pressure is applied axially on the powder mixture in the die.

In preferred embodiments, the powder mixture is heated directly by the punches and die of the sintering apparatus. The die may be comprised of an electrically conductive material such as graphite, which facilitates resistive/joule heating. The sintering apparatus and procedures are disclosed in US 2010/0156008 A1, which is incorporated herein by reference.

The temperature of the sintering apparatus according to the present disclosure is measured usually within the graphite die of the apparatus. Thereby, it is preferred that the temperature is measured as close as possible to the calcined powder mixture being processed so that the indicated temperatures are indeed realized within the calcined powder mixture to be sintered.

The application of heat to the powder mixture and/or layered powder mixtures provided in the die facilitates sintering temperatures of from 1000 to 1700° C., preferably from 1200 to 1700° C., preferably from 1400 to 1700° C., preferably from 1500 to 1700° C., more preferably from 1600 to 1700° C., preferably from 1200 to 1600° C., preferably from 1200 to 1400° C., preferably from 1400 to 1600° C., preferably from 1500 to 1600° C. Sintering may typically be achieved with an isothermal time of from 0.5 to 180 minutes, preferably from 0.5 to 120 minutes, preferably from 0.5 to 100 minutes, preferably from 0.5 to 80 minutes, preferably from 0.5 to 60 minutes, preferably from 0.5 to 40 minutes, preferably from 0.5 to 20 minutes, preferably from 0.5 to 10 minutes, preferably from 0.5 to 5 minutes, preferably from 5 to 120 minutes, preferably from 10 to 120 minutes preferably from 20 to 120 minutes preferably from 40 to 120 minutes preferably from 60 to 120 minutes, preferably from 80 to 100 minutes, preferably from 100 to 120 minutes preferably from 30 to 60 minutes, preferably from 15 to 45 minutes. In certain embodiments, sintering may be achieved with an isothermal time of zero and upon reaching the sintering temperature, a cooling rate as disclosed herein is initiated. In process step e), the ceramic sintered body is passively cooled by removal of the heat source. Natural convection may occur until a temperature is reached which may facilitate the optional annealing process.

During sintering, a volume reduction typically occurs such that the ceramic sintered body may comprise a volume that is about one third that of the volume of the starting powder mixture when disposed in the tool set of the sintering apparatus.

The order of application of pressure and temperature in one embodiment may vary according to the present disclosure, which means that it is possible to apply at first the indicated pressure and thereafter to apply heat to achieve the desired temperature. Moreover, in other embodiments it is also possible to apply at first the indicated heat to achieve the desired temperature and thereafter the indicated pressure. In a third embodiment according to the present disclosure, the temperature and the pressure may be applied simultaneously to the calcined powder mixture to be sintered and raised until the indicated values are reached.

Inductive or radiant heating methods may also be used for heating the sintering apparatus and indirectly heating the calcined powder mixture in the tool set.

In contrast to other sintering techniques, preparation of the sample prior to sintering, i.e., by cold pressing or forming a green body before sintering is not necessary, and the calcined powder mixture is disposed directly in the volume defined by the tool set of the sintering apparatus. This reduced powder mixture handling may provide for higher purity in the final, ceramic sintered body.

In further contrast to other sintering techniques, sintering aids are not required (although they may be used if desired). Additionally, a high purity starting powder is desirable for optimal etch performance. The lack of sintering aids and the use of high purity starting materials, from 99.99% to about 99.9999% purity as disclosed herein, enables the fabrication of a high purity, high density/low porosity ceramic sintered body which provides improved etch resistance for use as a ceramic sintered component in semiconductor etch chambers.

In one embodiment of the present invention, process step d) may further comprise a pre-sintering step with a specific heating ramp of from 0.1° C./min to 100° C./min, from 0.1° C./min to 50° C./min, from 0.1° C./min to 25° C./min, preferably 0.5° C./min to 50° C./min, preferably 0.5 to 25° C./min, preferably 0.5 to 10° C./min, preferably from 0.5° C./min to 5° C./min, preferably 0.75 to 25° C./min, preferably 1 to 10° C./min, preferably 1 to 5° C./min until a specific pre-sintering time is reached.

In a further embodiment of the present invention, process step d may further comprise a pre-sintering step with a specific pressure ramp of from 0.50 MPa/min to 30 MPa/min, preferably 0.75 MPa/min to 20 MPa/min, more preferably 1 to 10 MPa/min until a specific pre-sintering time is reached.

In another embodiment, process step d) may further comprise a pre-sintering step with the above-mentioned specific heating ramp and with the above-mentioned specific pressure ramp.

At the end of process step d), in an embodiment, the method may further comprise step e, cooling of the ceramic sintered body in accordance with a natural cooling of the process chamber (unforced cooling) under vacuum conditions as known to those skilled in the art. In a further embodiment in accordance with process step e), the ceramic sintered body may be cooled under convection with inert gas, for example, at 1 bar of argon or nitrogen. Other gas pressures of greater than or less than 1 bar may also be used. In a further embodiment, the ceramic sintered body is cooled under forced convective conditions in an oxygen environment. To initiate the cooling step, the power applied to the sintering apparatus is removed and the pressure applied to the ceramic sintered body is removed at the end of the sintering step d and thereafter cooling occurs in accordance with step e). Cooling rates for the ceramic sintered body as disclosed herein may be from 0.5 to 20° C./minute from 1 to 10° C./minute, preferably from 1 to 8° C./minute, preferably from 1 to 5° C./minute, preferably from 2 to 10° C./minute, preferably from 2 to 8° C./minute, preferably from 2 to 5° C./minute.

Step f) of the method disclosed herein is optionally annealing the ceramic sintered body (or in embodiments optionally annealing the ceramic sintered component) by applying heat to raise the temperature of the ceramic sintered body to reach an annealing temperature, performing annealing and step g) is lowering the temperature of the annealed ceramic sintered body. In optional step f), the resulting ceramic sintered body or ceramic sintered component of steps d) or h) respectively may be subjected to an annealing procedure. In other instances, annealing may not be performed on the ceramic sintered body or ceramic sintered component. Under other circumstances, annealing may be performed in a furnace external to the sintering apparatus, or within the sintering apparatus itself, without removal from the apparatus.

For the purpose of annealing in accordance with this disclosure, the ceramic sintered body may be removed from the sintering apparatus after cooling in accordance with process step e), and the process step of annealing may be conducted in a separate apparatus such as a furnace.

This annealing leads to a refinement of the chemical and physical properties of the sintered body. The step of annealing can be performed by conventional methods used for the annealing of glass, ceramics and metals, and the degree of refinement can be selected by the choice of annealing temperature and the duration of time that annealing is allowed to continue.

In embodiments, the optional step f) of annealing the ceramic sintered body is carried out at a heating rate of from 0.5° C./min to 50° C./min, preferably from 0.5° C./min to 25° C./min, preferably from 0.5° C./min to 10° C./min, preferably from 0.5° C./min to 5° C./min, preferably from 1° C./min to 50° C./min, preferably from 3° C./min to 50° C./min, preferably from 5° C./min to 50° C./min, preferably from 25° C./min to 50° C./min, preferably from 1° C./min to 10° C./min, preferably from 2° C./min to 10° C./min, and preferably from 2° C./min to 5° C./min.

In embodiments, the optional step f) of annealing the ceramic sintered body is carried out at a temperature of from about 900 to about 1800° C., preferably from about 1250 to about 1700° C., more preferably from about 1300 to about 1650° C., and more preferably from about 1400 to about 1600° C.

In embodiments, the optional step f) of annealing the ceramic sintered body is carried out at a cooling rate of from 0.5° C./min to 50° C./min, preferably from 0.5° C./min to 25° C./min, more preferably from 0.5° C./min to 10° C./min, and more preferably from 0.5° C./min to 5° C./min, more preferably from 1° C./min to 50° C./min, more preferably from 3° C./min to 50° C./min, more preferably from 5° C./min to 50° C./min, more preferably from 25° C./min to 50° C./min, preferably from 1° C./min to 10° C./min, preferably from 2° C./min to 10° C./min, and preferably from 2° C./min to 5° C./min.

The optional step f) of performing annealing of the ceramic sintered body is intended to correct oxygen vacancies in the crystal structure back to stochiometric ratio. The optional annealing step may be carried out at the annealing temperature for a duration of from 1 to 24 hours, preferably from 1 to 18 hours, preferably from 1 to 16 hours, preferably from 1 to 8 hours, preferably from 4 to 24 hours, preferably from 8 to 24 hours, preferably from 12 to 24 hours, preferably from 4 to 12 hours, and preferably from 6 to 10 hours.

The optional process step f) of annealing the ceramic sintered body may be carried out in an oxidizing atmosphere, whereby the annealing process may provide increased albedo, lowered stress which may provide improved mechanical handling and reduced porosity. The optional annealing step may be carried out in air.

The pressure and current assisted process according to one embodiment and described above is suitable for use in the preparation of large sintered YAG bodies. The process as disclosed provides for rapid powder consolidation and densification, retaining a maximum grain size of less than about 10 um in the ceramic sintered body, and achieving high, uniform densities in excess of 96% of theoretical and volumetric porosities of less than 4%, with minimal (<5%) density variation across a greatest dimension. Reducing the variation in density may improve handleability and reduce overall stress in the ceramic sintered body. This combination of fine grain size, uniform and high density provides for a high strength sintered YAG body of large dimension suitable for machining, handling and use as a component in a semiconductor processing chamber.

After the optional process step f) of annealing the ceramic sintered body is performed, the temperature of the sintered, and in some instances, annealed ceramic sintered body is decreased to an ambient temperature in accordance with process step g) and the sintered and optionally annealed ceramic body is taken out of either the furnace in the instance that the annealing step is performed external to the sintering apparatus, or removed from the sintering apparatus in case the annealing step f) is carried out in the sintering apparatus. Table 11 lists a range of process conditions and sample sizes of exemplary ceramic sintered bodies comprising solid YAG (unless otherwise specified) as disclosed herein.

TABLE 11

| | | | | Sintering | Anneal | Anneal |
|---|---|---|---|---|---|---|
| Size | | Sintering | Sintering | Time | Temp | Time |
| (mm) | Sample | T (° C.) | P (MPa) | (min) | (° C. ) | (hr) |
| 100 | 519 | 1450 | 30 | 30 | none | none |
| 100 | 529 | 1450 | 30 | 30 | none | none |
| 100 | 531 | 1450 | 30 | 30 | none | none |
| 100 | 514 | 1450 | 30 | 30 | none | none |
| 150 | 196 | 1450 | 30 | 30 | none | none |
| 100 | 535 | 1400 | 30 | 30 | none | none |
| 150 | 162 | 1500 | 20 | 30 | none | none |
| 150 | 162-1 | 1500 | 20 | 30 | 1400 | 8 |
| 150 | 158 | 1500 | 30 | 30 | none | none |
| 150 | 158-1 | 1500 | 30 | 30 | 1400 | 8 |
| 150 | 153 | 1500 | 30 | 30 | none | none |
| 150 | 153-1 | 1500 | 30 | 30 | 1400 | 8 |
| 150 | 165 | 1450 | 30 | 30 | 1400 | 8 |
| 150 | 166 | 1450 | 30 | 30 | 1400 | 8 |
| 150 | 167 | 1450 | 30 | 30 | none | none |
| 150 | 17 | 1500 | 30 | 30 | none | none |
| 150 | 19 | 1500 | 30 | 30 | 1400 | 8 |
| 150 | 6 | 1500 | 30 | 30 | 1400 | 8 |
| 150 | 134 | 1500 | 30 | 30 | 1400 | 8 |
| 150 | 135 | 1550 | 30 | 30 | 1400 | 8 |
| 150 | 112 | 1550 | 30 | 30 | 1400 | 8 |
| 150 | 113 | 1550 | 30 | 30 | 1400 | 8 |
| 150 | 114 | 1550 | 30 | 30 | 1400 | 8 |
| 150 | 402 | 1500 | 15 | 60 | none | none |
| 150 | 402-1 | 1500 | 15 | 60 | 1400 | 8 |
| 150 | 401 | 1500 | 20 | 45 | none | none |
| 150 | 401-1 | 1500 | 20 | 45 | 1550 | 8 |
| 150 | 401-2 | 1500 | 20 | 45 | none | none |
| 150 | 377 | 1475 | 15 | 45 | none | none |
| 150 | 423 | 1450 | 20 | 30 | none | none |
| 406 | 191 | 1575 | 20 | 60 | none | none |
| 406 | 258 | 1550 | 20 | 60 | none | none |
| 572 | 355 | 1550 | 20 | 90 | none | none |
| 572 | 408 | 1600 | 15 | 90 | 1400 | 8 |
| 572 | 395 | 1600 | 20 | 90 | 1400 | 8 |
| 572 | 399 | 1600 | 20 | 120 | 1400 | 8 |
| 150 | 195 | 1500 | 20 | 30 | 1500 | 8 |
| 150 | 93 | 1500 | 30 | 30 | none | none |
| 572 | 418 | 1650 | 15 | 60 | none | none |
| 150 | 416 | 1450 | 15 | 30 | none | none |
| 150 | 322 | 1450 | 20 | 45 | none | none |
| 150 | 322-1 | 1450 | 20 | 45 | 1400 | 8 |
| 150 | 272-5 | 1450 | 20 | 45 | 1550 | 8 |
| 150 | 298 | 1450 | 20 | 30 | none | none |
| 622 | 506 | 1650 | 15 | 60 | none | none |
| 622 | 487 | 1600 | 15 | 60 | none | none |
| 622 | 495 | 1600 | 15 | 60 | none | none |
| 622 | 521 | 1650 | 15 | 60 | none | none |
| 572 (layered) | 421 | 1600 | 15 | 60 | none | none |
| 622 (layered) | 597 | 1625 | 15 | 60 | none | none |

The ceramic sintered bodies prepared in accordance with the materials and methods as disclosed have very high purity. Purity of the ceramic sintered body may be on the order of that for the calcined powder mixtures. Table 12 lists impurities in ppm and purities in percent of the calcined powder mixtures and corresponding ceramic sintered bodies formed therefrom as disclosed herein as measured by ICPMS methods.

TABLE 12

| | Calcined | Calcined | | | |
|---|---|---|---|---|---|
| | Powder | Powder | Ceramic | | Si in |
| Ceramic | Impurity | Purity | Impurity | Ceramic | Ceramic |
| Sample | (ppm) | (%) | (ppm) | Purity (%) | (ppm) |
| 519 | 4 | 99.9996 | 28.3 | 99.9972 | 0 |
| 385 | 16.8 | 99.9983 | 23 | 99.9977 | 0 |
| 387-2 | 16.8 | 99.9983 | 36.2 | 99.9964 | 0 |
| 388 | 16.8 | 99.9983 | 15 | 99.9985 | 6.6 |
| 388-1 | 16.8 | 99.9983 | 16.6 | 99.9983 | 0 |
| 164-9 | 12 | 99.9988 | 23.6 | 99.9976 | 0 |
| 605 | 48 | 99.9952 | 50 | 99.995 | 0 |
| 199 | 4.2 | 99.9996 | 2.8 | 99.9997 | 0 |
| 206 | 4.2 | 99.9996 | 3.6 | 99.9996 | 0 |
| 218 | 4.1 | 99.9996 | 2.8 | 99.9997 | 0 |
| 195 | 2.2 | 99.9998 | 3.8 | 99.9996 | 0 |
| 601 | 32 (22 zr) | 99.9968 | 27 (19 zr) | 99.9973 | 0 |

In certain embodiments, the ceramic sintered bodies as disclosed herein may have a low silica content of, for example, less than 10 ppm, preferably less than 7 ppm, and preferably less than 5 ppm. In other embodiments, as listed in Table 12, silica was not detected in the ceramic sintered bodies using ICPMS measurements. Thus, in specific embodiments, the ceramic sintered bodies are substantially free of, or free of, silica.

A number of process parameters may be adjusted to form a ceramic sintered body having a visually apparent color which may be grey, white, red and combinations thereof. In embodiments, the ceramic sintered body before or after the annealing process as disclosed may be uniform throughout in color and comprise one of the aforementioned colors. In other embodiments, the ceramic sintered body may vary throughout in color and comprise more than one of the aforementioned colors. Sintered bodies in the as-sintered condition prior to the optional annealing step may have a surface and bulk which may be grey throughout in appearance and may have densities exceeding 99% of the theoretical density for YAG. For example, upon visual inspection, ceramic sintered body sample 322 as disclosed herein displays a grey color within the bulk and on a surface of the sample. In order to produce a white ceramic sintered body, the annealing conditions of heating rate, annealing temperature and time may be varied to alter the appearance of the ceramic sintered body such that it appears white on a surface and throughout. For example, in certain embodiments to form a white ceramic sintered body, annealing at times and durations of between 8 to 24 hours at temperatures of about 1500° C. may be required, resulting in densities of between 97 and 99% of theoretical density of YAG. Ceramic sintered body sample 272-5, annealed at 1550° C. for 8 hours as disclosed in Table 11, displays a white color within the bulk and on a surface of the sample and has a density of 4.433 g/cc, or about 97.3% of theoretical for YAG. In alternate embodiments, a white ceramic sintered body may be produced by the presence of excess alumina (in amounts of between about 0.1 and 3% by volume, preferably between 0.1 and 1% by volume) in the ceramic sintered body which after annealing at temperatures of between 1100 to 1400° C. for durations of 6 to 10 hours produce a white sintered body in accordance with ceramic sintered body sample 322-1 as disclosed herein, having a density of 4.531 g/cc, or 99.451% of theoretical for YAG. In other embodiments, the presence of zirconia added to the starting powders and/or resulting from use of zirconia milling media in amounts of between 20 and 100 ppm may produce a ceramic sintered body having a red color in an as-sintered condition, and a density of between 98 and 99.5% of theoretical. For example, ceramic sintered body sample 298 was prepared with about 100 ppm zirconia and displayed a red color on a surface and within the bulk, having a density of 4.540 g/cc or 99.649% of theoretical for YAG. Excess alumina (in amounts of between about 0.1 and 3% by volume, preferably between 0.1 and 1% by volume) to the extent it may be present in the ceramic sintered body may provide a ceramic sintered body having the same color on a surface and within the bulk of the body, whether in an as-sintered condition or after an annealing process as disclosed herein, and a density of between 98.5 and 99.5% of theoretical for YAG. Densities and sample preparation for these and similar embodiments are listed in Tables 1 and 11 respectively.

Step h) of the method disclosed herein is optionally machining of the ceramic sintered body or according to step i) the annealed ceramic sintered body to create a ceramic sintered component and may be carried out according to known methods for machining of corrosion resistant components from the ceramic sintered body as disclosed herein. In embodiments, the ceramic sintered component formed from the ceramic sintered body may comprise aluminium oxide (Al₂O₃), yttrium aluminum garnet of composition Y₃Al₅O₁₂ (YAG), yttrium aluminum perovskite of composition YAlO₃ (YAP) and yttrium aluminum monoclinic of composition Y₄Al₂O₉ (YAM), and combinations thereof (also referred to herein as “at least one crystalline phase of yttrium aluminum oxide”).

Multilayer Embodiment

Preparation of the multilayer sintered ceramic body may be achieved by use of pressure assisted sintering, such as for example Spark Plasma Sintering (SPS), also known as Field Assisted Sintering Technology (FAST), or Direct Current Sintering (DCS). These direct current sintering and related techniques employ a direct current to heat up an electrically conductive die configuration or tool set, and thereby a material to be sintered. This manner of heating allows the application of very high heating and cooling rates, enhancing densification mechanisms over grain growth promoting diffusion mechanisms, which may facilitate preparation of ceramic sintered bodies of very fine grain size, and transferring the intrinsic properties of the original powders into their near or fully dense products. The direct current, pressure assisted methods as disclosed herein utilize a preferably unpulsed, continuous direct current to heat the tool set as disclosed.

Preparation of the multilayer sintered ceramic bodies as disclosed herein may also be achieved through use of pressure assisted sintering methods such as uniaxial hot pressing whereby the die configuration or tool set is heated by way of an externally applied heat source such as induction heating.

The multilayer sintered ceramic body is prepared according to the general process steps as follows: a) combining yttria and alumina powders to make a first powder mixture; b) combining alumina powder and at least one of partially stabilized and stabilized zirconia powder to make a second powder mixture; c) combining yttria powder, alumina powder, and at least one of unstabilized, partially stabilized, and stabilized zirconia powder to make a third powder mixture; d) calcining at least one of the first, second, and third powder mixtures by applying heat to raise the temperature of at least one of the powder mixtures to a calcination temperature and maintaining the calcination temperature to perform calcination to form at least one of first, second, and third calcined powder mixtures; e) separately disposing the at least one first, second, and third powder mixtures inside a volume defined by a tool set of a sintering apparatus to form at least one layer of the first powder mixture, at least one layer of the second powder mixture, and at least one layer of the third powder mixture, and creating vacuum conditions inside the volume, wherein at least one of the first, second and third powder mixtures is calcined; f) applying pressure to the layers of the first, second, and third powder mixtures while heating to a sintering temperature and performing sintering to form the multilayer sintered ceramic body, wherein the at least one layer of the first powder mixture forms at least one first layer, the at least one layer of the second powder mixture forms at least one second layer, and the at least one layer of the third powder mixture forms at least one third layer; and g) lowering the temperature of the multilayer sintered ceramic body, wherein the at least one first layer comprises YAG, and the at least one second layer comprises alumina and zirconia wherein the zirconia comprises at least one of stabilized and partially stabilized zirconia, and the at least one third layer comprises at least one selected from the group consisting of yttria, alumina, and zirconia wherein the zirconia comprises at least one of unstabilized zirconia, stabilized zirconia and partially stabilized zirconia, wherein the at least one second layer is disposed between the at least one first layer and the at least one third layer, wherein an absolute value of the difference in coefficient of thermal expansion (CTE) between any of the at least one first, second, and third layers is from 0 to 0.75×10-6/° C. as measured in accordance with ASTM E228-17, wherein the at least one first, second and third layers form a unitary sintered ceramic body. In preferred embodiments, the powders selected from the group consisting of yttria and alumina in accordance with steps a), b) and c) each have a specific surface area of about 18 m²/g and less, preferably from about 1 to about 18 m²/g, as measured according to ASTM C1274. Preferably, the first, second and third powder mixtures have a total impurity content of 200 ppm and less as measured relative to a mass of the first, second and third powder mixtures.

The at least one second powder mixture comprises alumina and zirconia wherein the zirconia comprises at least one of stabilized zirconia and partially stabilized zirconia. The at least one second powder mixture comprises alumina in amounts by weight of from 60% to 92.5%, preferably from 75% to 85%, preferably about 77%, relative to the weight of the at least one second powder mixture. The at least one second powder mixture comprises zirconia (to include stabilizers to form at least one of stabilized and partially stabilized zirconia) in amounts by weight of from 7.5% to 40%, preferably from 15% to 25%, preferably about 23%, relative to the weight of the at least one second powder mixture. Upon sintering, these compositional ranges of the at least one second powder mixture correspond to at least one second layer 102 which comprises zirconia (upon sintering) in an amount of from 5 to 30% by volume, preferably from 10 to 30% by volume, preferably from 15 to 30% by volume, preferably from 20 to 30% by volume, preferably from 12 to 25% by volume, preferably from 15 to 25% by volume, preferably from 17 to 25% by volume, preferably from 10 to 22% by volume, preferably from 10 to 20% by volume, preferably from 10 to 17% by volume, preferably from 15 to 21%, preferably from 16 to 20%, and preferably about 16% by volume (and the balance comprising alumina), each relative to a volume of the at least one second layer 102. These volumetric amounts of zirconia may be measured using the combination of SEM imaging and ImageJ analysis software according to the methods as disclosed herein.

The at least one third powder mixture comprises at least one selected from the group consisting of yttria, alumina, and zirconia wherein the zirconia comprises at least one of unstabilized, partially stabilized and stabilized zirconia. The at least one third powder mixture comprises yttria in amounts by weight of from 1 to 57%, preferably from 3 to 57%, preferably from 5 to 57%, preferably from 1 to 40%, preferably from 1 to 30%, preferably from 3 to 30%, preferably from 5 to 30%, preferably from 5 to 15%, and preferably about 6% relative to the weight of the at least one third powder mixture. The at least one third powder mixture comprises alumina in amounts by weight of from 43% to 92.5%, preferably from 65% to 75%, preferably about 73%, relative to the weight of the at least one third powder mixture. The at least one third powder mixture comprises zirconia (including stabilizers, where applicable to form stabilized and/or unstabilized) in amounts by weight of from about 0.4% to 40%, preferably from 4% to 40%, preferably from 15% to 40%, preferably from 15% to 25%, preferably about 21%, relative to the weight of the at least one third powder mixture. In a preferred embodiment, the at least one third powder mixture comprises zirconia in amounts for the at least one third layer (upon sintering) to comprise ZrO₂ in an amount of from about 5 to about 30% by volume, preferably from 5 to 25% by volume, preferably from 5 to 20% by volume, preferably from 5 to 16% by volume, preferably from 10 to 30% by volume, preferably from 15 to 30% by volume, preferably from 20 to 30% by volume, and preferably from 15 to 20% by volume (and the balance comprising Y₂O₃ and Al₂O₃, each relative to a volume of the at least one third layer 103.

The following additional steps are optional; h) annealing the multilayer sintered ceramic body by applying heat to raise the temperature of the multilayer sintered ceramic body to reach an annealing temperature, performing annealing; i) lowering the temperature of the annealed multilayer sintered ceramic body; and j) machining the multilayer sintered ceramic body or the annealed multilayer sintered ceramic body to create a multilayer sintered ceramic component in the shape of a window, a lid, a dielectric window, an RF window, a ring, a focus ring, a process ring, a deposition ring, a nozzle, an injector, a gas injector, a shower head, a gas distribution plate, a diffuser, an ion suppressor element, a chuck, an electrostatic wafer chuck (ESC), and a puck.

In some embodiments, an optional annealing step may be performed. Optionally, annealing is performed by applying heat to raise the temperature of the multilayer sintered ceramic body to reach an annealing temperature, performing annealing, and lowering the temperature of the sintered and annealed multilayer sintered ceramic body to an ambient temperature by removing the heat source applied to the body and removing the multilayer sintered ceramic body.

The above-mentioned characteristics of the corrosion resistant multilayer sintered ceramic body according to an embodiment are achieved in part by adapting the purity and specific surface area (SSA) of the first, second and third powder mixtures, the pressure to the first, second and third mixtures, the temperature of the first, second and third powder mixtures, the duration of sintering of the first, second and third powder mixtures, the temperature of the multilayer sintered ceramic body during the optional annealing step, and the duration of the optional annealing step.

Disclosed is a method for preparing a multilayer sintered ceramic body, the method comprising the steps of: a) combining yttria and alumina powders to make a first powder mixture; b) combining alumina powder and at least one of partially stabilized and stabilized zirconia powder to make a second powder mixture; c) combining yttria powder, alumina powder, and at least one of unstabilized, partially stabilized, and stabilized zirconia powder to make a third powder mixture; d) calcining at least one of the first, second, and third powder mixtures by applying heat to raise the temperature of the powder mixtures to a calcination temperature and maintaining the calcination temperature to perform calcination to form at least one of first, second, and third calcined powder mixtures; e) separately disposing the first, second, and third powder mixtures inside a volume defined by a tool set of a sintering apparatus to form at least one layer of the first powder mixture, at least one layer of the second powder mixture, and at least one layer of the third powder mixture and creating vacuum conditions inside the volume, wherein at least one of the first, second and third powder mixtures is calcined; f) applying pressure to the layers of the at least one first, second, and third powder mixtures while heating to a sintering temperature and performing sintering to form the multilayer sintered ceramic body, wherein the at least one layer of the first powder mixture upon sintering forms at least one first layer, the at least one layer of the second powder mixture forms at least one second layer, and the at least one layer of the third powder mixture forms at least one third layer; and g) lowering the temperature of the multilayer sintered ceramic body, wherein the first layer comprises at least one crystalline phase of a ceramic material comprising YAG. The at least one second layer comprises alumina and zirconia wherein the zirconia comprises at least one of unstabilized, stabilized and partially stabilized zirconia, wherein the at least one second layer is disposed between the at least one first layer and the at least one third layer, wherein an absolute value of the difference in coefficient of thermal expansion (CTE) between any of the at least one first, second, and third layers is from 0 to 0.75×10-6/° C. as measured in accordance with ASTM E228-17, wherein the at least one first, second and third layers form a unitary sintered ceramic body. In preferred embodiments, the powders selected from the group consisting of yttria, alumina, and at least one selected from the group consisting of unstabilized, partially stabilized and stabilized zirconia each have a specific surface area of about 18 m²/g and less, preferably from about 1 to about 18 m²/g as measured according to ASTM C1274. In additional preferred embodiments, the at least one first, second and third powder mixtures (or calcined powder mixtures as the case may be) each have a specific surface area of about 18 m²/g and less, preferably from 1 to 18 m²/g as measured according to ASTM C1274. Preferably, the first, second and third powder mixtures have a total impurity content of 200 ppm and less as measured relative to a mass of the first, second and third powder mixtures.

The following additional steps are optional; h) annealing the multilayer sintered ceramic body by applying heat to raise the temperature of the multilayer sintered ceramic body to reach an annealing temperature, performing annealing; i) lowering the temperature of the annealed multilayer sintered ceramic body; and j) machining the multilayer sintered ceramic body or the annealed multilayer sintered ceramic body to create a multilayer sintered ceramic component in the shape of a window, a lid, a dielectric window, an RF window, a ring, a focus ring, a process ring, a deposition ring, a nozzle, an injector, a gas injector, a shower head, a gas distribution plate, a diffuser, an ion suppressor element, a chuck, an electrostatic wafer chuck (ESC), and a puck for use in plasma processing chambers.

Step a) of the method as disclosed herein comprises combining yttria and alumina powders to make a first powder mixture; the starting powder materials comprising the first powder mixture are combined and mixed in proportions such that the at least one first powder mixture upon sintering forms an at least one first layer comprising at least one crystalline phase of a ceramic material comprising YAG. The powders selected to form the at least one first powder mixture are preferably high purity (>99.99%) commercially available powders. However, other oxide powders may be used, for example those produced from chemical synthesis processes and related methods as long as the high purity requirement is satisfied.

Particle sizes for the starting powders, powder mixtures and calcined powder mixtures can be measured using a Horiba model LA-960 Laser Scattering Particle Size Distribution Analyzer capable of measuring particle size from 10 nm to 5 mm. Specific surface area (SSA) for the starting powders, powder mixtures and calcined powder mixtures can be measured using a Horiba BET Surface Area Analyzer model SA-9601 capable of measuring across a specific surface area of 0.01 to 2000 m²/g with an accuracy of 10% and less for most samples. Purity of the starting powders, powder mixtures and calcined powder mixtures can be measured using ICP-MS measurements using an Agilent 7900 ICP-MS model G8403 capable of analysis of lighter elements (such as from Sc and smaller atomic numbers) to about 1.4 ppm, and heavier elements (such as higher atomic numbers than Sc) to about 0.14 ppm. Purity is reported herein as a percent relative to 100% purity, which represents a material comprising the intended constituents only, without impurities, dopants, sintering aids and the like. Impurity contents are reported herein in ppm relative to a total mass of the material under assessment. Silica is not disclosed in the purity and impurity reporting and may be measured in amounts of about 14 ppm using the ICP-MS methods as disclosed herein.

The d50 as used herein is defined as the median and represents the value where half of the particle size distribution resides above this point, and half resides below this point. Similarly, 90 percent of the distribution lies below the d90, and 10 percent of the distribution lies below the d10.

The starting powders as disclosed herein of yttria and alumina are preferably crystalline, and thereby have a long-range crystallographic order. Any one or all of the starting powders of yttria and alumina may be sieved, tumbled, blended, milled, etc. according to methods known to those skilled in the art. In some embodiments, the starting powders of yttria and alumina may be optionally calcined according to methods as known to those skilled in the art. Starting powders, powder mixtures and calcined powder mixtures having high specific surface areas (SSAs) such as those nanopowders exceeding 20 m²/g pose issues in handleability when loading the tool set with powder, achieving uniform particle dispersion and mixing during the powder combination/mixing step, and formation of the first layer comprising the YAG phase during the in-situ, reactive sintering method to form YAG as disclosed in International Application No. PCT/US20/60918, which is herein incorporated by reference. The starting powders in accordance with the method as disclosed herein comprise yttria and alumina and preferably have specific surface areas of 18 m²/g and less. Thus, it is preferable that the powder mixtures as disclosed herein are free of, or substantially free of nanopowders as disclosed herein, and have a specific surface area (SSA) of about 18 m2/g and less.

Starting powders, powder mixtures and/or calcined powder mixtures having specific surface areas of less than about 0.75 m²/g may suffer from agglomeration, require higher energy for mixing and extended mixing times to combine to form the powder mixtures as disclosed herein. Further, powders having surface areas in this range may reduce the driving force necessary for sintering to the high densities as disclosed herein, producing sintered ceramic bodies having lower densities and higher porosity. Preferable for use in the method as disclosed are starting powders as disclosed herein having a SSA of from 1 to 18 m²/g, preferably from 2 to 15 m²/g, and preferably from 3 to 12 m²/g as measured according to ASTM C1274.

The d10 particle size of the yttrium oxide powder used as a starting material according to embodiments as disclosed herein is preferably from 1 to 6 μm, preferably from 1 to 5 μm, preferably from 1 to 4 μm, preferably from 2 to 6 μm, preferably from 3 to 6 μm, preferably from 4 to 6 μm, preferably from 2 to 4 μm.

The d50 particle size of the yttrium oxide powder used as a starting material according to embodiments as disclosed herein is preferably from 3 to 9 μm, preferably from 3 to 8.5 μm, preferably from 3 to 8 μm, preferably from 3 to 7 μm, preferably from 4 to 9 μm, preferably from 5 to 9 μm, preferably from 6 to 9 μm, preferably from 4 to 8 μm. The yttria powder as disclosed herein may have an average particle size of from about 5 to 9 μm.

The d90 particle size of the yttrium oxide powder used as a starting material according to embodiments as disclosed herein is preferably from 6 to 16 μm, preferably from 6 to 15 μm, preferably from 6 to 14 μm, preferably from 6.5 to 16 μm, preferably from 7 to 16 μm, preferably from 7.5 to 16 μm, preferably from 7.5 to 14 μm.

The yttrium oxide powder typically has a specific surface area (SSA) of from 2 to 10 m²/g, preferably from 2 to 8 m²/g, preferably from 2 to 6 m²/g, preferably from 3 to 10 m²/g, preferably from 4 to 10 m²/g, preferably from 6 to 10 m²/g, preferably from 2 to 4 m²/g.

The purity of the yttrium oxide starting material is preferably higher than 99.99%, preferably higher than 99.995%, preferably higher than 99.999%, more preferably higher than 99.9995%, and more preferably about 99.9999%. This corresponds to impurity levels of 100 ppm and less, preferably 50 ppm and less, preferably 25 ppm and less, preferably 10 ppm and less, more preferably about 1 ppm, preferably from 1 to 100 ppm, preferably from 1 to 50 ppm, preferably from 1 to 25 ppm, preferably from 1 to 10 ppm, preferably from 1 to 5 ppm.

The average or d50 particle size of the magnesium oxide powder used as a starting material according to embodiments as disclosed herein is typically from 1.5 to 5.5 μm, from 2 to 5.5 μm, from 2.5 to 5.5 μm, from 3 to 5.5 μm, from 1.5 to 5 μm, from 1.5 to 4.5 μm, more preferably from 2 to 4.5 μm.

Combining yttria and alumina powders to make at least first and second powder mixtures (in accordance with either or both of steps a) and b)) may be performed using the powder preparation techniques of wet or dry ball (axially rotating) milling, wet or dry tumble (end over end or vertical) mixing, jet milling, and combinations of these. Use of these powder combination methods provide a high energy process which breaks down particulates and agglomerates.

Using dry conditions, the starting powders may be ball milled or end-over-end/tumble mixed using high purity (>99.9%) alumina media in order to preserve the purity of the starting powders during mixing. In other embodiments, a harder media such as zirconia media may be used to break up hard agglomerates. The high purity alumina media was tested using ICPMS methods as disclosed herein and found to have a purity of from 99.9 to about 99.99%. Use of zirconia media may result in trace amounts, such as less than 100 ppm, of zirconia in the multilayer sintered ceramic body. Media used to perform dry ball milling may have a range of dimensions, from for example 5 mm to 15 mm in diameter, added at a loading of from about 50 to about 100% by powder weight. Media used to perform dry tumble mixing may comprise at least one media element of large dimension (from about 20 to 40 mm diameter) without limitation. Dry ball milling and/or dry tumble mixing may be performed for durations of from 12 to 48 hours, preferably from 16 to 48 hours, preferably from 16 to 24 hours, preferably from 18 to 22 hours. Dry ball milling or tumble milling processes (axially rotating) may use an RPM of from 50 to 250 RPM, preferably from 75 to 200 RPM, preferably from 75 to 150 RPM, preferably from 100 to 125 RPM, each for containers having about 200 mm diameter. RPMs may vary dependent upon the dimensions of containers selected for use, and as such, those containers greater than 200 mm in diameter may have correspondingly lower RPMs as known to those skilled in the art. Dry end-over-end/tumble mixing may be performed at an RPM of from 10 to 30 rpm, preferably about 20 RPM. After dry ball milling and/or end-over-end/tumble milling/mixing, the powder mixture may be optionally sieved using any number of meshes which may have openings of for example from 45 to 400 um, and blended, without limitation as to repetition or order as known to those skilled in the art.

Wet ball milling or wet end-over-end/tumble mixing may be performed by suspending the starting powders in various solvents such as ethanol, methanol, and other alcohols, to form a slurry. The slurries in either process (ball or tumble milling/mixing) may be formed having a powder loading during milling or mixing of from 25 to 75% by powder weight, preferably from 40 to 75% by powder weight, preferably from 50 to 75% by powder weight. Wet ball milling or wet end-over-end/tumble mixing may provide for improved dispersion of the powders through increased mobility, resulting in fine scale, uniform mixing before heat treatment or calcination. In embodiments, a dispersant may optionally be added to the slurry using any number of commercially available dispersants such as for example poly methyl methacrylate (PMMA) and polyvinyl pyrrolidone (PVP) and other dispersants as known to those skilled in the art. The dispersant may optionally be added in amounts from 0.05 to 0.2% by powder weight, preferably from 0.05 to 0.1% by powder weight. Media loadings for either wet ball or wet tumble/end-over-end mixing may be varied from a loading of 30 to 100% by powder weight, preferably from 30 to 75% by powder weight, preferably from 30 to 60% by powder weight. Wet ball milling or tumble mixing may be performed for durations of from 8 to 48 hours, preferably from 12 to 48 hours, preferably from 16 to 48 hours, preferably from 8 to 36 hours, preferably from 8 to 24 hours, preferably from 16 to 24 hours preferably from 12 to 24 hours. Ball milling may use an RPM of from 50 to 250 RPM, preferably from 75 to 200 RPM, preferably from 75 to 150 RPM, preferably between 100 and 125 RPM, each for containers having about 200 mm diameter. RPMs may vary dependent upon the dimensions of containers selected for use, and those greater than for example 200 mm in diameter may have correspondingly lower RPM as known to those skilled in the art. Wet end over end/tumble mixing may be performed at an RPM of from 10 to 30 rpm, preferably about 20. After wet ball milling and/or wet end-over-end/tumble mixing, the powder mixture may be optionally sieved using any number of meshes which may have openings of for example from 45 to 400 um, and blended, without limitation as to repetition or order as known to those skilled in the art.

Jet milling processes as known to those skilled in the art may also be used to thoroughly mix the powders to form a powder, powder mixture or calcined powder mixture having a narrow particle size distribution. Jet milling uses high velocity jets of either inert gases or air to collide particles of the starting powders and/or powder mixtures and/or calcined powder mixtures without the use of milling or mixing media, thus preserving initial purity of the powder to be milled. The chamber may be designed such that larger particles may be preferentially reduced in size, which may provide a narrow particle size distribution in the final powders, powder mixture or calcined powder mixture. Powders exit the jet milling chamber upon reaching a predetermined particle size as determined at setup of the machine prior to processing, thus ending the process. Starting powders, powder mixtures and/or calcined powder mixtures as disclosed herein may be subjected to jet milling at pressures of about 100 psi, whether separately, or in combination with any, or all of, the as disclosed powder milling/mixing processes as disclosed herein. After jet milling, the powders or powder mixtures may be optionally sieved using any number of meshes which may have openings of for example from 45 to 400 um, and blended, without limitation as to repetition or order as known to those skilled in the art.

The additional powder preparation procedures of attrition milling, high shear mixing, planetary milling, and other known procedures may also be applied. The aforementioned powder preparation techniques may be used alone or in any combination thereof, or upon more than one powder mixture which are thereafter sintered to form a unitary, multilayer sintered ceramic body.

Where wet mixing or milling processes are used, the slurry may be dried by rotary evaporation methods for example at a temperature of from about 40° C. to 90° C. for a duration of from 1 to 4 hours, dependent upon the volume of slurry to be dried, as known to those skilled in the art. In other embodiments, the slurry may be dried using spray drying techniques as known to those skilled in the art. After drying, the powder mixture may be optionally sieved using a mesh having openings of for example from 45 to 400 um, and blended, without limitation as to repetition or order. The aforementioned powder preparation techniques may be used alone or in any combination thereof.

After drying, the specific surface area of the powder mixture of step a) may be from 2 to 18 m²/g, preferably from 2 to 17 m²/g, preferably from 2 to 14 m²/g, preferably from 2 to 12 m²/g, preferably from 2 to 10 m²/g, preferably from 4 to 17 m²/g, preferably from 6 to 17 m²/g, preferably from 8 to 17 m²/g, preferably from 10 to 17 m²/g, preferably from 4 to 12 m²/g, preferably from 4 to 10 m²/g, and preferably from 5 to 8 m²/g as measured according to ASTM C1274.

The purity of the powder mixtures may be maintained after mixing/milling from that of the starting materials through the use of milling media of high purity, for example aluminum oxide media of purity 99.99% and greater. In embodiments, use of zirconium oxide milling media may be preferable and may introduce zirconium oxide to the extent it remains in the at least one first and/or second layers of the multilayer sintered ceramic body in amounts of from 15 to 100 ppm, from 15 to 75 ppm, preferably from 15 to 60 ppm, preferably from 20 to 30 ppm.

Step b) of the method as disclosed herein comprises combining alumina powder and zirconia powder wherein the zirconia powder comprises at least one of partially stabilized and stabilized zirconia powder to make a second powder mixture; the starting powder materials comprising the second powder mixture are combined and mixed in proportions such that the second powder mixture upon sintering forms the at least one second layer 102 wherein the at least one second layer 102 comprises at least one of partially stabilized and stabilized zirconia (and combinations thereof) in an amount of not less than 5 volume % ZrO₂ and not greater than 30 volume % ZrO₂, and the balance comprising Al₂O₃. The starting powder materials selected to form the at least one second layer 102 are preferably high purity commercially available powders. However, other oxide powders may be used, for example those produced from chemical synthesis processes and related methods as long as the high purity requirement is satisfied. In some embodiments, dependent upon required CTE matching properties, the toughness and mechanical strength requirements of the plasma processing chamber component, the at least one second layer 102 may comprise at least one of partially stabilized and stabilized zirconia (and combinations thereof) in an amount of not less than 10 volume % ZrO₂ and not greater than 25 volume % ZrO₂, (and the balance comprising Al₂O₃) relative to the volume of the at least one second layer 102.

The following properties for powders of zirconia and alumina also apply to step a) with the exception that the zirconia of step a) may comprise any one or combinations of unstabilized, partially stabilized and stabilized zirconia. The zirconia powders in accordance with step b) are preferably stabilized, partially stabilized and combinations thereof.

The zirconium oxide powder may have a particle size distribution having a d10 of from 0.08 to 0.20 um, a d50 of from 0.3 to 0.7 um and a d90 of from 0.9 to 5 μm. The average particle size of the zirconium oxide powder used as a starting material for the mixture according to one embodiment of the present invention may be from 0.3 to 1 um.

The zirconia powder typically has a specific surface area (SSA) of from 1 to 16 m²/g, preferably from 2 to 14 m²/g, preferably from 4 to 12 m²/g, and more preferably from 5 to 9 m²/g as measured according to ASTM C1274.

The purity of the zirconia powder starting material is typically higher than 99.8%, preferably higher than 99.9%, preferably higher than 99.95%, preferably higher than 99.975%, preferably higher than 99.99%, and preferably higher than 99.995%. This corresponds to a total impurity content of 2000 μm and less, preferably 1000 ppm and less, preferably 500 ppm and less, preferably 250 ppm and less, preferably 100 ppm and less, preferably 50 ppm and less and preferably from 25 to 150 ppm as measured using ICPMS methods as disclosed herein. Zirconia as used in embodiments disclosed herein comprises Hf in low amounts of about 2 to 5 wt % as is common in many commercially available zirconia powders. These purities of zirconia exclude Hf and any stabilizing compounds as disclosed according to Table 1.

In embodiments, the zirconia powder may comprise stabilizing compounds comprising at least one selected from the group consisting of yttria, lanthanum oxide (La₂O₃), ceria (CeO2), magnesia, samaria (Sm₂O₃), and calcia and combinations thereof. To form partially stabilized zirconia (PSZ), these stabilizing compounds may each be present in amounts of from 0.5 to 50 mol %, preferably from 0.5 to 30 mol %, preferably from 0.5 to 15 mol %, preferably from 0.5 to 10 mol %, preferably from 1 to 50 mol %, preferably from 1 to 30 mol %, preferably from 1 to 10 mol %, preferably from 1 to 5 mol %, and preferably about 3 mol %. To form stabilized zirconia (SZ), these stabilizing compounds may each be present in amounts of from greater than 6 to about 45 mol %, preferably from greater than 10 to about 45 mol %, preferably from greater than 25 to about 45 mol %, preferably from greater than 6 to 30 mol %, preferably from greater than 6 to about 15 mol %, preferably from greater than 8 to 15 mol %. Table 1 provides additional guidance for stabilizing or partially stabilizing zirconia.

In certain embodiments, the at least one second layer 102 is yttria stabilized and formed from a powder mixture comprising alumina and zirconia wherein the zirconia is selected from the group consisting of partially yttria stabilized zirconia (PYSZ) or fully yttria stabilized zirconia (YSZ). Partially yttria stabilized zirconia (PYSZ) may be formed from powder mixtures comprising from about 1 to 10 mol % yttria, preferably from 1 to 8 mol % yttria, preferably from 1 to 5 mol % yttria, preferably from 2 to 4 mol % yttria, and preferably about 3 mol % yttria. Yttria stabilized zirconia (YSZ) may be formed from powder mixtures comprising from about 8 to about 15 mol % yttria, preferably from 10 to 15 mol % yttria, and preferably from 12 to 15 mol % yttria.

The alumina powder comprising the first and second powder mixtures has powder characteristics as disclosed following.

The d10 particle size of the aluminum oxide powder used as a starting material according to embodiments of the present disclosure is preferably from 0.1 to 0.5 μm, preferably from 0.1 to 0.4 μm, preferably from 0.1 to 0.3 μm, preferably from 0.2 to 0.5 μm, preferably from 0.3 to 0.5 μm, preferably from 0.4 to 0.5 μm, preferably from 0.1 to 0.2 μm.

The d50 particle size of the aluminum oxide powder used as a starting material according to embodiments of the present disclosure is preferably from 2 to 8 μm, preferably from 2 to 7 μm, preferably from 2 to 6 μm, preferably from 3 to 8 μm, preferably from 4 to 8 μm, preferably from 5 to 8 μm and more preferably from 2.5 to 5 μm.

The d90 particle size of the aluminum oxide powder used as a starting material according to embodiments of the present disclosure is preferably from 15 to 40 μm, preferably from 15 to 30 μm, preferably from 15 to 25 μm, preferably from 20 to 40 μm, preferably from 30 to 40 μm, and preferably from 20 to 30 μm.

The aluminum oxide powder typically has a specific surface area of from 4 to 18 m²/g, preferably from 4 to 14 m²/g, preferably from 4 to 10 m²/g, preferably from 4 to 6 m²/g, preferably from 6 to 18 m²/g, preferably from 6 to 14 m²/g, preferably from 8 to 18 m²/g, preferably from 10 to 18 m²/g, preferably from 8 to 10 m²/g, and preferably from 6 to 10 m²/g.

The purity of the aluminum oxide starting material is typically higher than 99.99%, preferably higher than 99.995%, preferably higher than 99.999%, and preferably higher than 99.9995%, as measured using ICPMS methods. Correspondingly, the impurity content of the alumina powder may be 100 ppm and less, preferably 50 ppm and less, preferably 25 ppm and less preferably 10 ppm and less, and more preferably 5 ppm and less.

The alumina and zirconia powders are mixed in proportions such that the zirconia is present in an amount of from 10 to 30%, preferably from 10 to 25%, preferably from 10 to 20%, preferably from 15 to 25%, preferably from 20 to 25%, and preferably from 15 to 20% each by volume of the at least one second layer 102 (upon sintering) of the multilayer sintered ceramic body.

Combining the alumina and at least one of partially stabilized and stabilized zirconia powders to make the second powder mixture may be performed in accordance with the materials and methods as disclosed in step a) of the method.

Step c) of the method disclosed herein comprises combining alumina, yttria, and at least one of unstabilized, partially stabilized, and stabilized zirconia to make at least one third powder mixture. The at least one third powder mixture may comprise alumina in an amount of from greater than 43 to 92.5% and less, yttria in an amount of from 1 to 56% and less, and at least one of unstabilized, partially stabilized, and stabilized zirconia in an amount of from 0.4 and greater to 40%, each by weight of the at least one third powder mixture. Preferably, the at least one third powder mixture has an SSA of from about 1 to 18 m²/g, preferably from about 1 m²/g to about 14 m²/g, preferably from about 1 m²/g to about 10 m²/g, preferably from about 1 m²/g to about 8 m²/g, preferably from about 2 m²/g to about 18 m²/g, preferably from about 2 m²/g to about 14 m²/g, preferably from about 2 m²/g to about 10 m²/g, preferably from about 3 m²/g to about 9 m²/g, preferably from about 3 m²/g to about 6 m²/g as measured according to ASTM C1274. In preferred embodiments, the at least one third powder mixture may comprise about 73% alumina, about 6% yttria and about 21% of at least one of unstabilized, partially stabilized and stabilized zirconia, each by weight of the at least one third powder mixture. In further preferred embodiments, the at least one third powder mixture comprises about 73% alumina, about 6% yttria and about 21% of 3 mol % yttria partially stabilized zirconia, each by weight of the at least one third powder mixture. The at least one third powder mixture, upon sintering, forms at least one third layer 103 having multiple phases comprising YAG, alumina, and at least one of unstabilized, partially stabilized, and stabilized zirconia. In other embodiments, the at least one third powder mixture may be batched to form the YAG phase upon sintering, and as such comprises about 43 wt % alumina and 57% yttria. The at least one third layer comprising YAG would be CTE matched to at least one first layer comprising YAG within the ranges as disclosed.

Combining the yttria, alumina and zirconia powders to make the third powder mixture may be performed in accordance with the powder materials and methods as disclosed in Steps a) and b) of the method. The third powder mixture may be dry ball milled, roller blended, wet milled, wet tumble mixed, and other similar mixing methods as known to those skilled in the art.

As previously disclosed, combining at least two of alumina, yttria, magnesia and at least one of unstabilized, partially stabilized and stabilized zirconia powders to make at least first, second and third powder mixtures (in accordance with either or both of steps a), b) and c) may be performed using the powder preparation techniques of wet or dry ball (axially rotating) milling, wet or dry tumble (end over end or vertical) mixing, jet milling, and combinations of these. Use of these powder combination methods provides a high energy process which breaks down particulates and agglomerates.

Step d) of the method disclosed herein comprises calcining at least one of the first, second and third powder mixtures by applying heat to raise the temperature of at least one of the powder mixtures to a calcination temperature, and maintaining the calcination temperature to perform calcination to form at least one of first, second and third calcined powder mixtures. This step may be conducted such that moisture may be removed and surface condition of the powder mixture is uniform prior to sintering. Calcination may be performed at temperatures of from 600° C. to 1200° C., preferably from 600 to 1100° C., preferably from 600 to 1000° C., preferably from 600 to 900° C., preferably from 700 to 1100° C., preferably from 800 to 1100° C., preferably from 800 to 1000° C., and preferably from 850 to 950° C. Calcination may be performed for durations of from 4 to 12 hours, preferably from 4 to 10 hours, preferably from 4 to 8 hours, preferably from 6 to 12 hours, preferably from 4 to 6 hours, in an oxygen containing environment. After calcination, at least one of the first, second and third powder mixtures may be sieved and/or tumbled and/or blended according to known methods to form at least one first, second and third calcined powder mixtures. The at least one first powder mixture is preferably calcined. Calcination may or may not result in a reduction in specific surface area.

The first powder mixture may have a d10 particle size of from 0.06 to 4 μm, preferably from 0.08 to 4 μm, preferably from 0.1 to 4 μm, preferably from 0.2 to 4 μm, preferably from 0.3 to 4 μm, preferably from 0.4 to 4 μm, preferably from 0.08 to 3 μm, preferably from 0.08 to 2 μm, preferably from 0.08 to 1 μm, preferably from 0.5 to 3 μm, preferably from 1 to 2 μm, preferably from 1 to 3 μm.

The second powder mixture may have a d10 particle size of from 0.075 to 0.4 um, preferably from 0.075 to 0.3 um, preferably from 0.075 to 0.2 um, preferably from 0.1 to 0.4 um, preferably from 0.1 to 0.3 um, preferably from 0.1 to 0.2 um, preferably about 0.2 um.

The first powder mixture may have a d50 particle size of from 0.7 to 50 μm, preferably from 1 to 40 μm, preferably from 1 to 30 μm, preferably from 1 to 20 μm, preferably from 1 to 10 μm, preferably from 1 to 5 μm, preferably from 5 to 50 μm, preferably from 10 to 50 μm, preferably from 20 to 50 μm, preferably from 30 to 50 μm, preferably from 3 to 8 μm, preferably from 5 to 10 μm, preferably from 6 to 15 μm.

The second calcined powder mixture may have a d50 particle size of from 1 to 100 μm, preferably from 1 to 80 μm, preferably from 1 to 60 μm, preferably from 1 to 40 μm, preferably from 10 to 100 μm, preferably from 20 to 100 μm, preferably from 30 to 100 μm, preferably from 20 to 80 μm, preferably from 20 to 60 μm, preferably from 20 to 40 μm.

The first calcined powder mixture may have a d90 particle size of from 10 to 350 μm, preferably from 10 to 300 μm, preferably from 10 to 250 μm, preferably from 10 to 200 μm, preferably from 10 to 175 μm, preferably from 10 to 150 μm, preferably from 10 to 100 μm, preferably from 10 to 75 μm, preferably from 10 to 50 μm, preferably from 10 to 40 μm preferably from 10 to 25 μm, preferably from 20 to 350 μm, preferably from 40 to 350 μm, preferably from 60 to 350 μm, preferably from 100 to 350 μm, preferably from 150 to 350 μm, preferably from 200 to 350 μm, preferably from 12 to 330 um, preferably from 100 to 330 μm, preferably from 100 to 250 um.

The second calcined powder mixture may have a d90 particle size of from 20 to 250 μm, preferably from 20 to 220 μm, preferably from 20 to 150 μm, preferably from 20 to 100 μm, preferably from 50 to 220 μm, preferably from 70 to 220 μm, preferably from 100 to 220 μm.

In certain embodiments, higher temperature calcination conditions as disclosed herein may result in formation of crystalline phases and agglomeration of the calcined powder mixtures and thus greater variability in particle size distributions overall and in particular larger variance and overall d50 and d90 particle sizes may result. In other embodiments, lower temperature calcination conditions as disclosed herein may not affect particle size distributions of the calcined powder mixtures relative to the starting materials and thereby particle size distributions are in the same range, or similar to, the starting powder materials. Lot to lot variation and management of heat transfer during calcination may also contribute to variations in particle size distributions. Thus, a broad range of particle size distributions, and in particular d50 and d90 particle sizes of the powder mixtures, may result from calcination conditions as disclosed herein.

The at least one first, second and third calcined powder mixtures may each have a specific surface area (SSA) of from about 1 m²/g to about 18 m²/g, preferably from about 1 m²/g to about 14 m²/g, preferably from about 1 m²/g to about 10 m²/g, preferably from about 1 m²/g to about 8 m²/g, preferably from about 2 m²/g to about 18 m²/g, preferably from about 2 m²/g to about 14 m²/g, preferably from 2 to 12 m²/g, preferably from about 2 m²/g to about 10 m²/g, preferably from about 3 m²/g to about 9 m²/g, and preferably from about 3 m²/g to about 6 m²/g as measured according to ASTM C1274.

The first calcined powder mixture may have a total impurity content of from 5 to 200 ppm, preferably from 5 to 150 ppm, preferably less than 100 ppm, preferably less than 75 ppm, preferably less than 50 ppm, preferably less than 25 ppm, preferably less than 15 ppm, preferably less than 10 ppm, preferably less than 8 ppm, preferably less than 5 ppm, preferably from 5 to 50 ppm, preferably from 5 to 30 ppm, preferably from 3 to 20 ppm relative to a mass of the first calcined powder mixture.

The second powder mixture may have a total impurity content of from 5 to 200 ppm, preferably from 5 to 150 ppm, preferably less than 100 ppm, preferably less than 50 ppm, preferably less than 25 ppm, preferably less than 15 ppm, preferably from 10 to 100 ppm, preferably from 10 to 80 ppm, preferably from 10 to 60 ppm, preferably from 10 to 40 ppm, preferably from 20 to 80 ppm, preferably from 30 to 60 ppm relative to a mass of the second powder mixture.

The starting powders comprising at least one first and second powder mixtures have varying properties of for example, particle size and purity. As such, features of the powder mixture, such as purity, may be higher than at least one of the starting powders alone due to combination with another starting powder which may be higher in purity.

Step e) of the method as disclosed herein comprises separately disposing the first, second and third calcined powder mixtures inside a volume defined by a tool set of a sintering apparatus to form at least one layer of the first powder mixture, at least one layer of the second powder mixture, and at least one layer of the third powder mixture, and creating vacuum conditions inside the volume wherein at least one of the first, second and third powder mixtures is calcined. A spark plasma sintering (SPS) apparatus used in the process as disclosed herein comprises at least a graphite die which is usually a cylindrical graphite die. In the graphite die, first, second and third powder mixtures are separately disposed between two graphite punches to form at least three separate layers.

In preferred embodiments, the SPS apparatus comprises a die comprising a sidewall comprising an inner wall and an outer wall, wherein the inner wall has a diameter that defines an inner volume capable of receiving at least one ceramic powder or powder mixtures; and an upper punch and a lower punch operably coupled with the die, wherein each of the upper punch and the lower punch have an outer wall defining a diameter that is less than the diameter of the inner wall of the die thereby defining a gap between each of the upper punch and the lower punch, and the inner wall of the die when at least one of the upper punch and the lower punch are moved within the inner volume of the die, wherein the gap is from 10 μm to 70 μm wide. Preferably, the die and punches are made of graphite. Such SPS tool is disclosed in U.S. provisional patent application Ser. No. 63/087,204, filed Oct. 3, 2020, and U.S. provisional patent application Ser. No. 63/124,547, filed Dec. 11, 2020 both of which are herein incorporated by reference.

In embodiments, three or more powder mixtures may be disposed within the graphite die. Vacuum conditions as known to those skilled in the art are established within the ceramic powder or powder mixtures disposed inside the inner volume. Typical vacuum conditions include pressures of 10⁻² to 10⁻³ torr. The vacuum is applied primarily to remove air to protect the graphite from burning and to remove a majority of the air from the powder. The order of powder mixture disposition may be reversed or repeated as necessary to achieve the desired structure of the multilayer sintered ceramic body and component formed therefrom. In preferred embodiments, the second powder mixture is disposed between the first and third powders, and thus the second powder mixture is contiguous with each of the first and third powder mixtures as disposed within the graphite die during sintering. The at least one first, second and third powder layers are thereafter sintered to form first, second and third layers whereby first and second layers are contiguous, thereby forming a nonlinear interface, and second and third layers are contiguous, thereby forming second interface, of the multilayer sintered ceramic body. Disposing the at least one first and second powder mixtures inside the volume defined by the tool set typically results in intermixing of the first and second powder mixtures, thereby creating the tortuosity as described above of the nonlinear interface which is characteristic of the multilayer sintered bodies produced by the method as disclosed herein. This nonlinear interface may provide an interlocking effect, and enhanced adhesion, between at least one first and second layers. Intermixing also occurs between the at least one second and third powder mixtures, thereby creating the second interface. This second interface may provide an interlocking effect and enhanced toughness between at least one second and third layers. Nonlinear interface and second interface differ significantly from that of laminates and sintered bodies formed from at least one laminate or pre-sintered body, which have a substantially linear (or one dimensional) interface and as such, the multilayer sintered ceramic bodies as disclosed herein are not laminates or laminated bodies. The at least first, second and third powder mixtures may be directly loaded into the tool set of the sintering apparatus and sintered, without pre-sintering steps such as use of binders, dispersants and the like, which may contribute to contamination and reduced density.

As described above, the interfaces between the layers typically have a tortuosity and a non-linear interface so that the interface layer usually meanders between the layers. The tortuosity using the calculations as disclosed herein may be between 1.2 and 2.2, in particular between 1.4 and 2.0. The measurements for determining the tortuosity are described later below and are based on an increase in the interfacial length relative to the linear distance of the interface layer. Thus, disclosed herein is a multilayer sintered ceramic body having an interface defined by the at least one second layer and the at least one first layer and between the at least one second layer and the at least one third layer wherein the interfacial length is increased by from 20 to 70%, preferably from 20 to 60%, preferably from 20 to 40%, preferably from 30 to 80%, preferably from 40 to 80%, preferably from 50 to 70%.

Correspondingly, the at least one second layer and the at least one first layer and the at least one third layer and the at least one second layer may contact one another at an interface commensurate in interfacial area to the greatest dimension of the multilayer sintered ceramic body along the interface layer.

For unitary, multilayer sintered bodies (and components made therefrom) having greatest dimensions of from 100 to about 625 mm considering the above-mentioned tortuosity of at least 1.2, the at least one second layer and the at least one first layer contact one another at a nonlinear interface having an area of at least 113 cm², preferably of at least 452 cm², preferably at least 1,018 cm², and preferably at least 1,810 cm².

For unitary, multilayer sintered bodies (and components made therefrom) having greatest dimensions of from 100 to about 625 mm considering the above-mentioned tortuosity of at least 1.4, the at least one second layer and the at least one first layer contact one another at a nonlinear interface having an area of at least 153 cm², preferably of at least 616 cm², preferably at least 1,386 cm², and preferably at least 2,464 cm².

For unitary, multilayer sintered bodies (and components made therefrom) having greatest dimensions of from 100 to about 625 mm considering the above-mentioned tortuosity of at most 2.2, the at least one second layer and the at least one first layer contact one another at a nonlinear interface having an area of at most 15,085 cm², preferably of at most 14,850 cm², preferably at most 14,128 cm², preferably at most 9,802 cm², preferably at most 6,083 cm², preferably at most 3,421 cm², and preferably at most 1,520 cm².

For unitary, multilayer sintered bodies (and components made therefrom) having greatest dimensions of from 100 to about 625 mm considering the above-mentioned tortuosity of at most 2.0, the at least one second layer and the at least one first layer contact one another at a nonlinear interface having an area of at most 12,468 cm², preferably of at most 12,272 cm², preferably at most 11,676 cm², preferably at most 7,852 cm², preferably at most 5,028 cm², preferably at most 2,828 cm², and preferably at most 1,256 cm².

For unitary, multilayer sintered bodies (and components made therefrom) having greatest dimensions of from 100 to about 625 mm considering the above-mentioned tortuosity of at least 1.2, the at least one second layer and the at least one first layer contact one another at a nonlinear interface having an area of from 113 to about 4,488 cm², preferably from 113 to about 4,418 cm², preferably from 113 to 4,204 cm², preferably from 113 to 2,827 cm², preferably from 113 to 1,918 cm², preferably from 113 to 1,018 cm², preferably from 113 to 452 cm², preferably from 452 to about 4,488 cm², preferably from 452 to about 4,418 cm², preferably from 452 to 4,203 cm², preferably from 452 to 2,827 cm², preferably from 452 to 1,810 cm², preferably from 1,018 to about 4,418 cm², and preferably from 1,810 to 4,376 cm².

For unitary, multilayer sintered bodies (and components made therefrom) having greatest dimensions of from 100 to about 625 mm considering the above-mentioned tortuosity of at least 1.4, the at least one second layer and the at least one first layer contact one another at a nonlinear interface having an area of from 153 to about 6,110 cm², preferably from 153 to about 6,013 cm², preferably from 153 to 5,722 cm², preferably from 153 to 3,847 cm², preferably from 153 to 2,464 cm², preferably from 153 to 1,386 cm², preferably from 153 to 616 cm², preferably from 616 to about 6,110 cm², preferably from 616 to about 6,013 cm², preferably from 616 to 5,722 cm², preferably from 616 to 3,847 cm², preferably from 616 to 2,464 cm², preferably from 1,386 to about 6,013 cm², and preferably from 2,464 to 5,957 cm².

For unitary, multilayer sintered bodies (and components made therefrom) having greatest dimensions of from 100 to about 625 mm considering the above-mentioned tortuosity of at most 2.2, the at least one second layer and the at least one first layer contact one another at a nonlinear interface having an area of from 378 to about 15,085 cm², preferably from 378 to about 14,850 cm², preferably from 378 to 14,128 cm², preferably from 378 to 9,502 cm², preferably from 378 to 6,083 cm², preferably from 378 to 3,421 cm², preferably from 378 to 1,520 cm², preferably from 1,520 to about 15,085 cm², preferably from 1,520 to about 14,850 cm², preferably from 1,520 to 14,128 cm², preferably from 1,520 to 9,502 cm², preferably from 1,1520 to 6,083 cm², preferably from 3,421 to about 14,850 cm 2, and preferably from 6,083 to 14,710 cm².

For unitary, multilayer sintered bodies (and components made therefrom) having greatest dimensions of from 100 to about 625 mm considering the above-mentioned tortuosity of at most 2.0, the at least one second layer and the at least one first layer contact one another at a nonlinear interface having an area of from 312 to about 12,468 cm², preferably from 312 to about 12,272 cm², preferably from 312 to 11,676 cm², preferably from 312 to 7,852 cm², preferably from 312 to 5,028 cm², preferably from 312 to 2,828 cm², preferably from 312 to 1,256 cm², preferably from 1,256 to about 12,468 cm², preferably from 1,256 to about 12,272 cm², preferably from 1,256 to 11,676 cm², preferably from 1,256 to 7,652 cm², preferably from 1,256 to 5,028 cm², preferably from 2,828 to about 12,272 cm², and preferably from 5,028 to 7,294 cm².

The process as disclosed utilizes commercially available, starting powders having micron-sized average (or d50) particle size distributions or those prepared from chemical synthesis techniques without the requirement of forming green tapes or bodies or machining the same prior to sintering.

The high densities and low porosities associated with the multilayer sintered ceramic bodies resulting from the disclosed process and powder materials are achieved without the use of binders or sintering aids in the initial powders. Other sintering techniques require use of sintering aids to lower sintering temperatures, which may adversely impact halogen-based plasma resistance and densification. Polymeric binders are also often used to create the aforementioned green bodies, which may contribute to residual porosity and lower densities upon binder burn out. No binders or sintering aids are required in the making of the multilayer, sintered corrosion resistant ceramic bodies or multilayer components formed therefrom as disclosed herein. The combination of CTE matching of the respective layers and pressure assisted sintering is preferable to form the multilayer sintered ceramic bodies having the characteristics as disclosed herein, including high density and high adhesion strength between layers.

Step f) of the method as disclosed herein comprises applying pressure to the layers of the first, second and third powder mixtures while heating to a sintering temperature and performing sintering to form the multilayer sintered ceramic body, wherein the at least one layer of the first powder mixture forms a first layer, the at least one layer of the second powder mixture forms a second layer, and the at least one layer of the third powder mixture forms a third layer, and g) lowering the temperature of the multilayer sintered ceramic body.

After the at least one first, second and third powder mixtures are disposed inside the inner volume of the die, pressure is applied axially to the powder mixtures disposed between the graphite punches. The pressure is increased to reach a pressure of from 5 MPa to 100 MPa, preferably from 5 MPa to 60 MPa, preferably from 5 MPa to 40 MPa, preferably from 5 MPa to 20 MPa, preferably from 5 MPa to 15 MPa, preferably from 10 MPa to 60 MPa, preferably from 10 MPa to 40 MPa, preferably from 10 MPa to 30 MPa, preferably from 10 MPa to 20 MPa, preferably from 15 MPa to 60 MPa preferably from 15 MPa to 40 MPa, preferably from 15 MPa to 30 MPa, preferably from 20 to 40 MPa, preferably from 15 MPa to 20 MPa, and preferably from 13 MPa to 18 MPa.

The application of heat to the powder mixture provided in the inner volume of the die facilitates sintering temperatures of from 1000 to 1700° C., preferably from 1200 to 1700° C., preferably from 1400 to 1700° C., preferably from 1500 to 1700° C., more preferably from 1600 to 1700° C., preferably from 1200 to 1600° C., preferably from 1200 to 1400° C., preferably from 1400 to 1600° C., and preferably from 1500 to 1650° C. Sintering may typically be achieved with a time of from 0.5 to 180 minutes, preferably from 0.5 to 120 minutes, preferably from 0.5 to 100 minutes, preferably from 0.5 to 80 minutes, preferably from 0.5 to 60 minutes, preferably from 0.5 to 40 minutes, preferably from 0.5 to 20 minutes, preferably from 0.5 to 10 minutes, preferably from 0.5 to 5 minutes, preferably from 5 to 120 minutes, preferably from 10 to 120 minutes preferably from 20 to 120 minutes preferably from 40 to 120 minutes preferably from 60 to 120 minutes, preferably from 80 to 100 minutes, preferably from 100 to 120 minutes, and preferably from 30 to 90 minutes. In certain embodiments, sintering may be achieved with an isothermal time of zero and upon reaching the sintering temperature, a cooling rate as disclosed herein is initiated. According to process step g), the ceramic sintered body may be passively cooled by removal of the heat source. Natural or forced convection may be used until a temperature is reached which may facilitate the optional annealing process.

In preferred embodiments, the powder mixtures are heated directly by the punches and die of the sintering apparatus. The die and punches may be comprised of an electrically conductive material such as graphite, which facilitates resistive/joule heating. The sintering apparatus and procedures are disclosed in US 2010/0156008 A1, which is incorporated herein by reference.

Sintering the powder layers under pressure creates a co-compacted, unitary multilayer body. In accordance with the method as disclosed, the at least one layer of the first powder mixture, the at least one layer of the second powder mixture and the at least one layer of the third powder mixture are simultaneously formed in-situ into the first, second and third layers, respectively, of the multilayer sintered ceramic body during step f) of the method. This single step, concurrent sintering of the at least one first, second and third powder mixtures into the at least one first, second and third layers of the multilayer sintered ceramic body may provide enhanced interfacial adhesion, high mechanical strength and improved flatness of the multilayer sintered ceramic body. The CTE matching of the at least one first layer 100, the at least one second layer 102, and the at least one third layer 103, in particular across the range of sintering temperatures as disclosed herein, prevents the generation of stress due to CTE mismatching at the interface between the at least one second layer 102, the at least one first layer 100, and the at least one third layer 103 upon cooling after sintering, and during any thermal excursion in accordance with the method as disclosed, thus enabling the formation of multilayer sintered ceramic bodies (and components formed therefrom) of large dimension having high strength, plasma resistance, and high interfacial adhesion.

During sintering, a volume reduction typically occurs such that the ceramic sintered body may comprise a volume that is about one third that of the volume of the starting powder mixtures when disposed in the tool set of the sintering apparatus.

The temperature of the sintering apparatus according to the present disclosure is measured usually within the graphite die of the apparatus. Thereby, it is preferred that the temperature is measured as close as possible to the powder mixtures being processed so that the indicated temperatures are indeed realized within the powder mixtures to be sintered.

The order of application of pressure and temperature may vary as disclosed herein. In an embodiment, the indicated pressure may be applied and thereafter heat may be applied to achieve the desired temperature of sintering. In another embodiment, heat may be applied to achieve the desired temperature of sintering and thereafter the indicated pressure may be applied. In a further embodiment, the temperature and the pressure may be applied simultaneously to the powder mixtures to be sintered and raised until the indicated values are reached.

The method as disclosed may comprise a pre-sintering step with a specific heating ramp of from 1 to 100° C./min, preferably 2 to 50° C./min, preferably 3 to 25° C./min, preferably 3 to 10° C./min, more preferably 5 to 10° C./min until a specific pre-sintering time is reached.

The method as disclosed may comprise a pre-sintering step with a specific pressure ramp of from 0.50 MPa/min to 30 MPa/min, preferably 0.75 MPa/min to 10 MPa/min, more preferably 1 to 5 MPa/min until a specific pre-sintering time is reached.

The method as disclosed herein may comprise a pre-sintering step with the above-mentioned specific heating ramp and with the above-mentioned specific pressure ramp.

In the aforementioned pre-sintering steps, the temperature and pressure are maintained for a time period of 10 min to 360 minutes.

Inductive or radiant heating methods may also be used for heating the sintering apparatus and indirectly heating the powders in the tool set.

Step h) of the method as disclosed herein comprises optionally annealing the multilayer sintered ceramic body (or component formed therefrom) by applying heat to raise the temperature of the multilayer sintered ceramic body to reach an annealing temperature, performing annealing; and step i) lowering the temperature of the annealed multilayer sintered ceramic body (or component formed therefrom). In some embodiments, the method as disclosed herein may further include an optional annealing step. In the optional annealing step in accordance with embodiments as disclosed herein, the multilayer sintered ceramic body may be subjected to an annealing procedure by removal from the sintering apparatus and annealing in a furnace at temperatures of from about 900 to about 1800° C., preferably from about 1250 to about 1700° C., preferably from about 1300 to about 1650° C., and preferably from about 1400 to about 1600° C.

In embodiments, the optional annealing of the multilayer sintered ceramic body may be carried out at a heating and/or a cooling rate of from 0.5° C./min to 50° C./min, preferably from 0.5° C./min to 25° C./min, more preferably from 0.5° C./min to 10° C./min, and more preferably from 0.5° C./min to 5° C./min, more preferably from 1° C./min to 50° C./min, more preferably from 3° C./min to 50° C./min, more preferably from 5° C./min to 50° C./min, more preferably from 25° C./min to 50° C./min, preferably from 1° C./min to 10° C./min, preferably from 2° C./min to 10° C./min, and preferably from 2° C./min to 5° C./min.

Durations of the optional annealing step may be from 1 to 24 hours, preferably from 1 to 18 hours, preferably from 1 to 16 hours, preferably from 1 to 8 hours, preferably from 4 to 24 hours, preferably from 8 to 24 hours, preferably from 12 to 24 hours, preferably from 4 to 12 hours, and preferably from 6 to 10 hours.

In an embodiment, optional annealing in accordance with this disclosure may be performed after the sintering process and within the sintering apparatus. The optional process of annealing may preferably be performed under oxidizing conditions such as forced convection or in air. Annealing leads to a refinement of the chemical and physical properties of the multilayer sintered ceramic body or component fabricated therefrom through reduction of oxygen vacancies for stoichiometric correction and reduced stress in the sintered body or component. The optional process step of annealing the sintered multilayer corrosion resistant component is carried out in an oxidizing atmosphere, whereby the annealing process may provide increased albedo, improved mechanical handling and reduced porosity.

In some embodiments, the step of annealing may be performed by conventional methods used for the annealing of glass, ceramics and metals, and the degree of refinement may be selected by the annealing temperature and the duration of time that annealing is conducted. In other embodiments, annealing may not be performed on the sintered ceramic body.

After the optional process step of annealing the multilayer sintered ceramic body is performed, the temperature of the sintered, and in some instances annealed, multilayer sintered ceramic body is decreased to an ambient temperature by removal of the heat source to the multilayer sintered body (or component fabricated therefrom) in accordance with step i). The sintered and annealed multilayer sintered ceramic body or component fabricated therefrom is thereafter taken out of either the furnace in the instance that the annealing step is performed external to the sintering apparatus, or removed from the tool set in case annealing is carried out in the sintering apparatus.

Step j) of the method as disclosed herein comprises machining the multilayer sintered ceramic body (or the annealed multilayer sintered ceramic body) to create a sintered ceramic component in the shape of a window, a lid, a dielectric window, an RF window, a ring, a focus ring, a process ring, a deposition ring, a nozzle, an injector, a gas injector, a shower head, a gas distribution plate, a diffuser, an ion suppressor element, a chuck, an electrostatic wafer chuck (ESC), and a puck. Machining, drilling, boring, grinding, lapping, polishing, and the like as known to those skilled in the art may be performed as necessary to form the multilayer sintered ceramic body into a predetermined shape of a component for use in plasma processing chambers. Use of the powder mixtures in the compositional ranges as disclosed herein may provide a multilayer sintered ceramic body having improved machinability through use of CTE matched layers, thereby reducing stress during the machining step of the method as disclosed.

An improved multilayer sintered ceramic body and methods for fabrication of the same, in particular of large body size for use in plasma processing chambers, is disclosed herein. The multilayer sintered ceramic bodies as disclosed may have a size of from 100 mm to at least 622 mm, including about 625 mm, with regard to the longest extension of the sintered body.

If it is desired to make a two-layer sintered ceramic body, then either step b) or step c) is optional and can be skipped.

Components Made from Sintered Bodies

In one embodiment, the ceramic sintered body disclosed herein can be machined into a process ring. Examples of a process ring include an insert ring, a focus ring, an exhaust ring, a cover ring, a deposition ring, an etch ring, a shield ring, a carrier ring, or a substrate capture ring that are components of a plasma vacuum processing chamber. Each process ring comprises: an annular body comprising from 90% to 99.8% by volume of polycrystalline yttrium aluminum garnet (YAG), wherein the annular body has at least one surface having a surface area; and an opening surrounded by the annular body, wherein the polycrystalline yttrium aluminum garnet comprises pores on the at least one surface having a pore size not exceeding 5 μm and having a maximum pore size of 1.5 μm for at least 95% of the pores.

FIGS. 8A and 8B illustrate a single layer embodiment. Here, exhaust ring 100 is formed of an upper ring 100a, which is exposed to plasma, and a lower ring 100b, which is covered by the upper ring 100a and not exposed to plasma. Preferably, both rings are made of polycrystalline yttrium aluminum garnet (YAG) of the present invention and formed of an outer ring 30 of flange shape, which is exposed to plasma, and a projection part 32, beyond which the outer ring 30 extends to a predetermined length.

Preferably, the lower ring 100b is formed of an inner ring 34 and an inner flange 36, which are not exposed by plasma. The projection part 32 of the upper ring 100a is inserted into the lower ring 100b to be coupled to the inner flange 36. During the etching process, only the upper ring 100a is typically exposed to plasma. The lower ring 100b is covered by the upper ring 100a and is typically not exposed to plasma. Ring components as disclosed herein may comprise any number of embodiments without limitation. Embodiments of the sintered ceramic bodies and multilayer structures as disclosed herein may be machined to form at least one ring component selected from the group consisting of a cover ring, a substrate ring, a shield ring and/or top shield ring, an etch or deposition ring, an insulating ring and other equivalents as known to those skilled in the art.

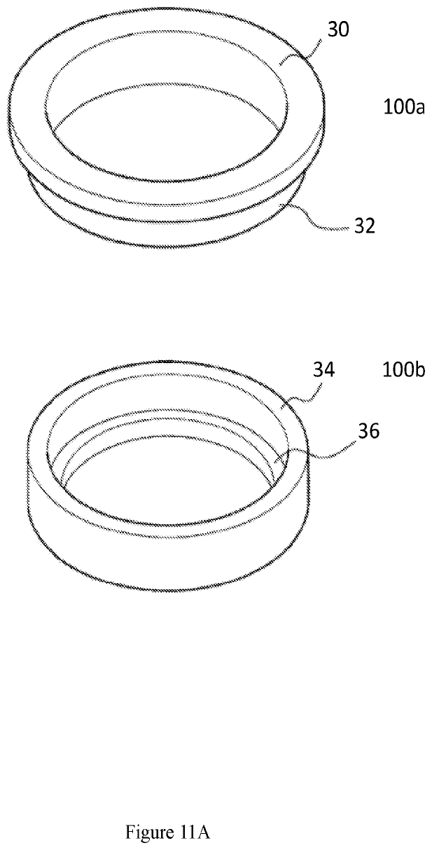

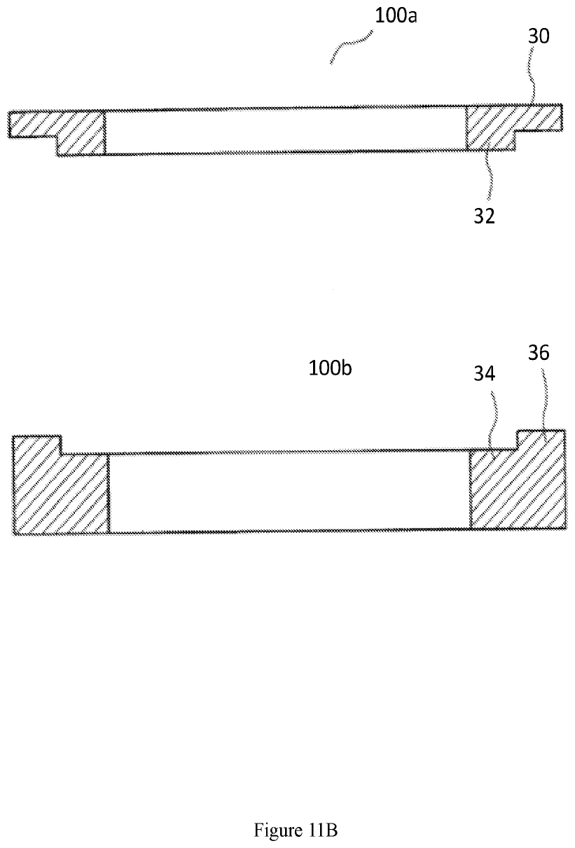

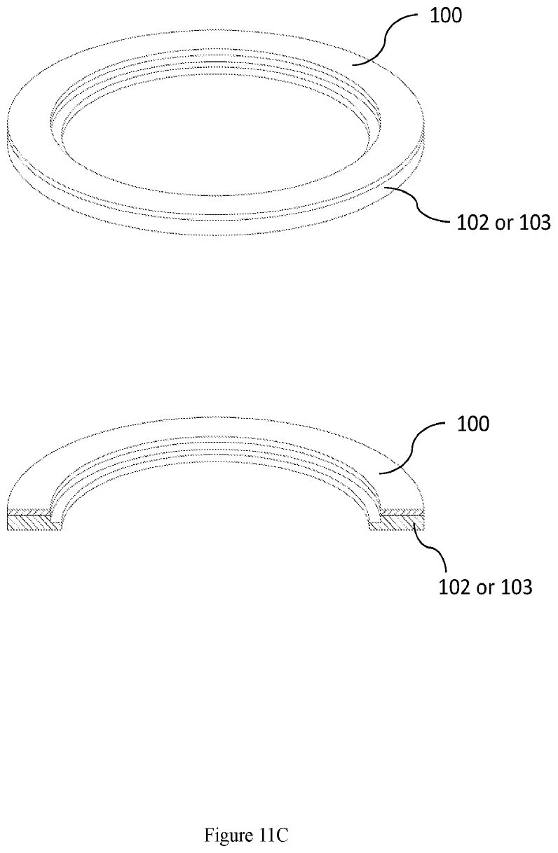

FIG. 11C illustrates a two-layer ring component wherein layer 100 is the layer exposed to plasma and corresponds to layer 100 of FIG. 2 and the second layer corresponds to either layer 102 or 103 of FIG. 2. In an embodiment not shown, the ring is a three-layer ring comprising layers 100, 102, and 103 as described above. Thus, in another embodiment, provided is a process ring for use in a plasma vacuum processing chamber, the process ring comprising: an annular body comprising at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, and wherein the at least one first, second and third layers form a unitary sintered ceramic body; and an opening surrounded by the annular body, wherein the surface comprises pores having a pore size not exceeding 5 μm and having a maximum pore size of 1.5 μm for at least 95% of the pores. In a two-layered embodiment, either of the at least one second layer or the at least one third layer is optional.

In another embodiment, the ceramic sintered body disclosed herein can be machined into a “showerhead” gas flow manifold, sometimes also referred to as a showerhead assembly or a gas distribution assembly. This device is typically used to distribute process gases across the surface of a wafer. Process gases may be flowed out of the showerhead and distributed across a wafer; the wafer may be supported by a pedestal assembly within a process chamber housing the showerhead. Distribution of the process gases across the wafer may be accomplished through a pattern of gas distribution holes which direct the flow of gas from inside the showerhead assembly to the wafer.

A showerhead assembly typically comprises: a backplate portion comprising at least one gas inlet; a frontplate portion opposite the backplate portion, wherein the frontplate portion comprises a plurality of gas distribution holes; and an inner volume in communication with the gas distribution holes and the gas inlet, wherein the backplate portion and the frontplate portion each comprise from 90% to 99.8% by volume of polycrystalline yttrium aluminum garnet (YAG) and have at least one surface having a surface area, wherein the polycrystalline yttrium aluminum garnet comprises pores on the at least one surface wherein the pores have a pore size not exceeding 5 μm and have a maximum pore size of 1.5 μm for at least 95% of the pores.

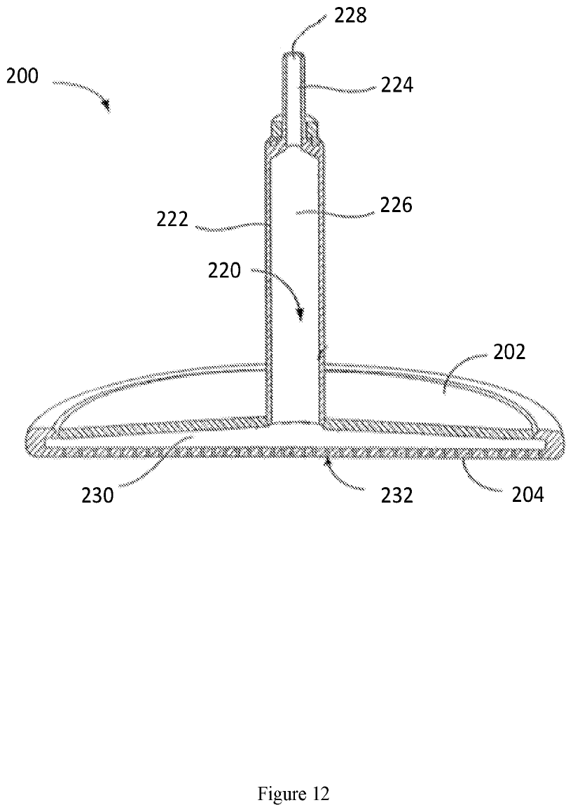

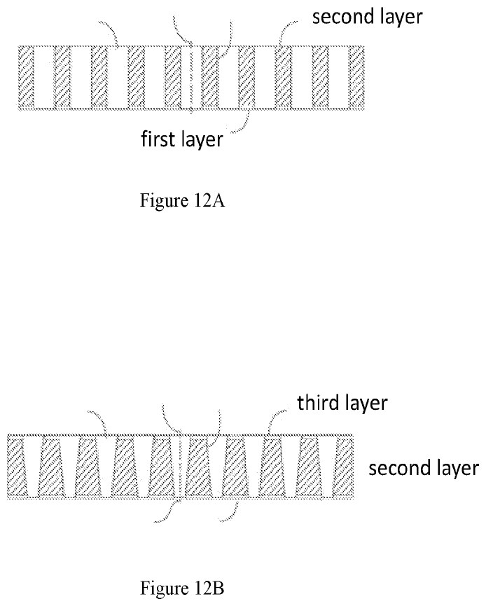

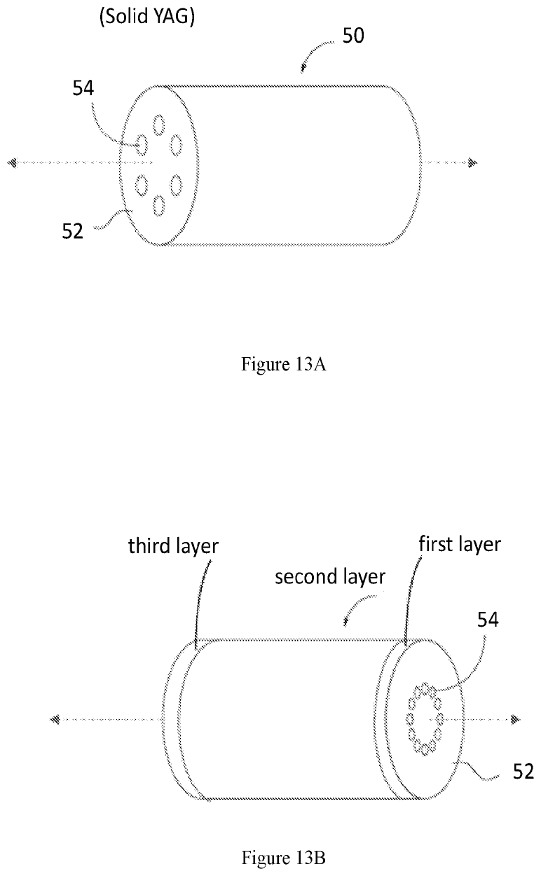

A showerhead assembly of a plasma vacuum processing chamber is shown in FIG. 12. FIG. 12 shows an isometric section view of an example of a single-layer showerhead assembly 215. As shown in FIG. 12, the showerhead assembly 215 includes a gas distribution plate or a backplate 202 and a faceplate 204 (also referred to herein as a frontplate), where the backplate 202 and the faceplate 204 may be separate mechanical components or integrated into a single body. In some embodiments, there may also be a blocker plate (not shown) disposed between the faceplate and the backplate to further control the gas distribution across the showerhead. The backplate 202 and the faceplate 204 may be positioned opposite one another. The backplate 202 comprises at least one gas inlet 220 for receiving process gas. The faceplate 204 may have a plurality of gas distribution holes or through-holes 232 to facilitate delivery of gas to a substrate. An inner volume 230 may be defined between the backplate 202 and the faceplate 204, where the inner volume 230 can have a first surface and a second surface opposite the first surface. In some implementations, the first surface and the second surface of the inner volume 230 can have circumferential surfaces. The first surface and the second surface can at least partially define the inner volume 230 of the showerhead assembly 215. A first side of the faceplate 204 can define the first surface of the inner volume 230. A second side of the backplate 202 can define the second surface of the inner volume 230. Generally, the first surface of the inner volume 230 can have a diameter that is similar or substantially similar to a diameter of a substrate for which the showerhead assembly 215 is configured for use. In some implementations, as illustrated in FIG. 12, the inner volume 230 can be substantially conical in shape along the second surface of the inner volume 230.

The inner volume 230 may be supplied with a gas, such as reactant gas or purge gas, via one or more gas inlets 220. The gas inlet 220 in FIG. 12 may be connected to a gas supply or supplies for delivery of the gas. The gas inlet 220 can include a stem 222, where the stem 222 can include an expanded tube 226 connected to a narrow tube 224. The expanded tube 226 can have a diameter greater than a diameter of the narrow tube 224 to provide a more spatially distributed flow upon reaching the inner volume 230.

FIGS. 9A and 9B show faceplate 204 as a two and three-layer embodiment, respectively, wherein FIG. 12A exemplifies straight through holes 232 and FIG. 12B exemplifies tapered through holes 232.

In one embodiment, the gas distribution holes 232 in faceplate 204 may be from about 0.050″ to about 0.100″ in diameter. Other gas distribution hole sizes may be used as well, e.g., sizes falling in the range of 0.02″ to 0.06″ in diameter.

The gas distribution holes 232 may be arranged in any of several different configurations, including grid arrays, polar arrays, spirals, offset spirals, hexagonal arrays, etc. The hole arrangements may result in varying hole density across the showerhead. Different diameters of gas distribution holes may be used in different locations depending on the gas flow desired.

The gas distribution holes 232 may also vary in their angle through the thickness of the faceplate 204. They may be angled or straight/perpendicular to a plane including the surface of the faceplate. They may be a combination of angled or straight/perpendicular to a plane.

In some embodiments, the showerhead may be a dual-zone showerhead such as that disclosed in U.S. patent application Publication No. 2018/0358244, which is incorporated herein by reference. Such showerheads may be aligned so that the holes are not in alignment with other plates to avoid co axial flow. Each zone may have a set of holes to facilitate addition of precursor gases and/or to control flow between zones. The zones may be arranged concentrically or encircling one another, etc.

Showerhead components as disclosed herein may comprise any number of embodiments without limitation. Embodiments of the sintered ceramic bodies and multilayer structures as disclosed herein may be machined to form at least one component selected from the group consisting of a gas distribution plate, a diffuser, an ion suppressor and other equivalents as known to those skilled in the art.

In another embodiment, provided is a showerhead assembly of a plasma vacuum processing chamber, the showerhead assembly comprising: a) a backplate portion comprising at least one gas inlet; b) a frontplate portion opposite the backplate portion, wherein the frontplate portion comprises a plurality of gas distribution holes; and c) an inner volume in communication with the gas distribution holes and the gas inlet, wherein the backplate portion and the frontplate portion each comprise at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores. In a two-layered embodiment, either of the at least one second layer or the at least one third layer is optional.

In yet another embodiment, the ceramic sintered body disclosed herein can be machined into a gas distribution nozzle comprising: a body having at least one gas injection passage and at least one surface having a surface area, wherein the body comprises from 90% to 99.8% by volume of polycrystalline yttrium aluminum garnet (YAG), wherein the polycrystalline yttrium aluminum garnet comprises pores on the at least one surface wherein the pores have a pore size not exceeding 5 μm and have a maximum pore size of 1.5 μm for at least 95% of the pores.

Referring to FIGS. 10A and 10B, gas distribution nozzle 50 comprises a body 52 body comprising from 90% to 99.8% by volume of polycrystalline yttrium aluminum garnet (YAG) as disclosed herein. Body 52 comprises multiple gas injection channels or passages 54. Such gas distribution nozzle is typically found in a plasma reactor over a workpiece.

FIGS. 10A and 10B show a comparison of a single YAG layer embodiment (10A) against a three-layer embodiment (10B), wherein the first layer is YAG.

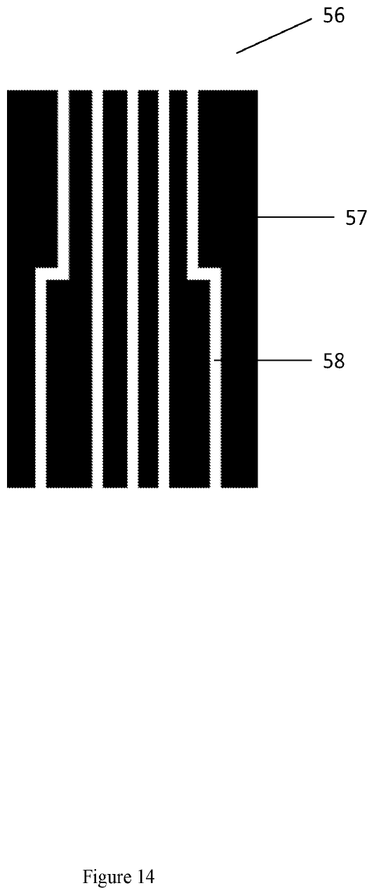

FIG. 14 is a cross section of a second gas distribution nozzle 56 embodiment wherein gas distribution nozzle comprises a body 57 body comprising from 90% to 99.8% by volume of polycrystalline yttrium aluminum garnet (YAG) as disclosed herein. Body 57 comprises multiple gas injection channels or passages 58, which could be non-linear. Such gas distribution nozzle is typically found in a plasma reactor over a workpiece. Gas distribution nozzles and gas distribution nozzle components as disclosed herein may comprise any number of embodiments without limitation. Embodiments of the sintered ceramic bodies and multilayer structures as disclosed herein may be machined to form at least one component selected from the group consisting of a gas distribution nozzle, an injector, a nozzle and other equivalents as known to those skilled in the art.

In another embodiment, provided herewith is a gas distribution nozzle for use in a plasma vacuum processing chamber, the gas distribution nozzle comprising: a body having at least one gas injection passage, wherein the body comprises at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores. In a two-layered embodiment, either of the at least one second layer or the at least one third layer is optional.

In still another embodiment, the ceramic sintered body disclosed herein can be machined into a dielectric window, through which RF or microwave energy passed when used in a plasma process chamber. The dielectric window comprises: a body having at least one surface having a surface area, wherein the body comprises from 90% to 99.8% by volume of polycrystalline yttrium aluminum garnet (YAG), wherein the polycrystalline yttrium aluminum garnet comprises pores on the at least one surface wherein the pores have a pore size not exceeding 5 μm and have a maximum pore size of 1.5 μm for at least 95% of the pores.

The dielectric window disclosed herein may be a single layer or it may have more than one layer (i.e., a multilayer dielectric window) as long as it allows for the transmission of radiation/energy. The dielectric window, if multilayer, may comprise at least one layer comprising a second ceramic material, which is not the yttrium aluminum oxide material made according to the present disclosure. Exemplary materials include alumina or quartz.

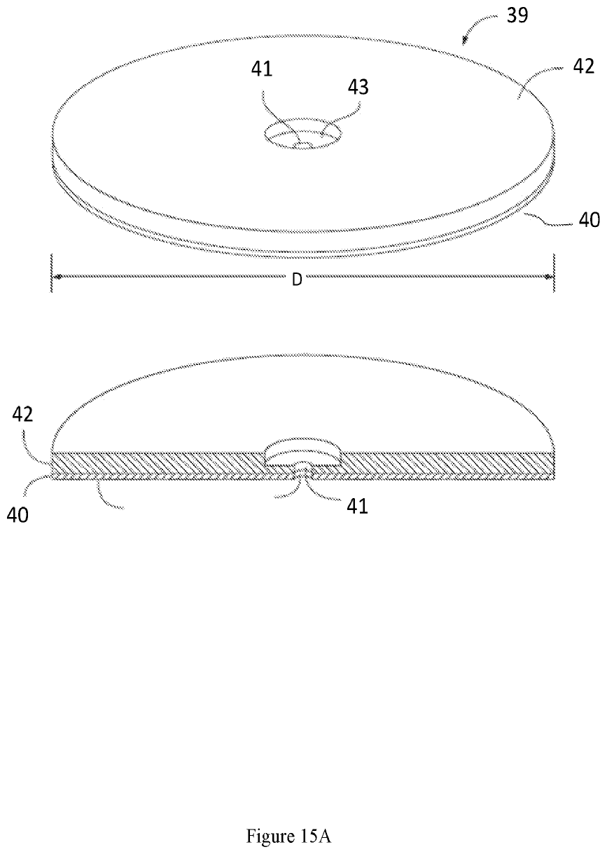

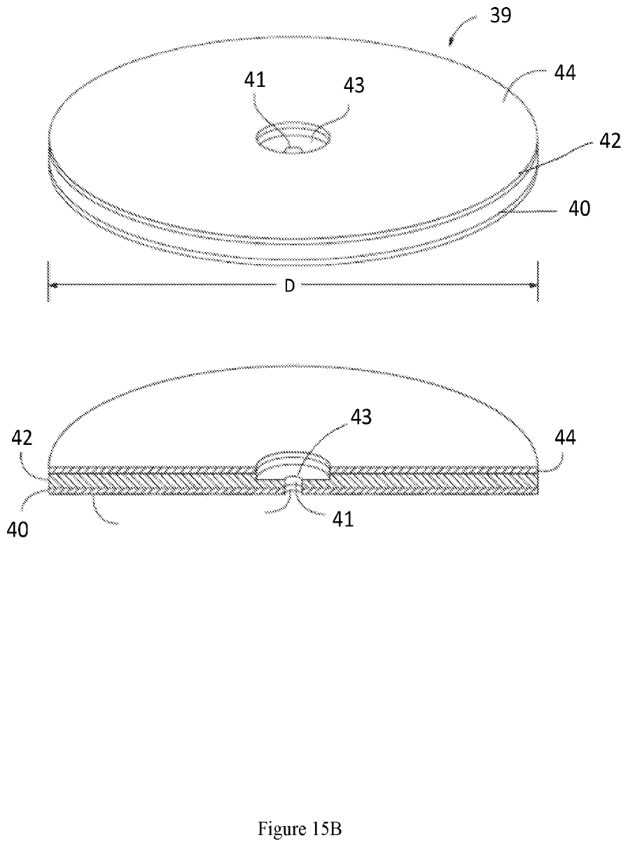

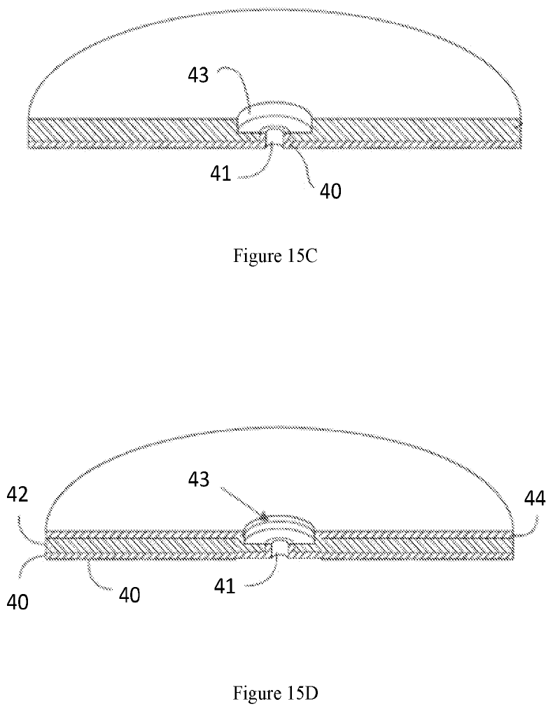

Referring to FIGS. 12A and 12C, a two-layer dielectric window is shown through which RF energy passes. Two-layer dielectric window includes at least one layer 40 comprising from 90% to 99.8% by volume of polycrystalline yttrium aluminum garnet (YAG) as disclosed herein. At least one surface of layer 40 comprises pores wherein the pores have a pore size not exceeding 5 μm and have a maximum pore size of 1.5 μm for at least 95% of the pores. Two-layer dielectric window comprises layer 42 comprising zirconia toughened alumina, wherein the zirconia is present in an amount of from 5 to 25%, preferably from 10 to 25%, preferably from 15 to 25%, preferably from 15 to 17%, preferably from 20 to 25%, preferably from 5 to 20%, preferably from 5 to 15%, preferably from 5 to 10%, preferably from 15 to 20% each by volume of layer 42. The specific composition of the layer 42 of zirconia toughened alumina may be selected to match the coefficient of thermal expansion of the YAG layer across temperatures of use in semiconductor plasma processing chambers. As such, in embodiments, it may be preferable that the layer of zirconia toughened alumina comprises about 16% by volume of zirconia and the balance alumina. The layers 40, 42 allow the transmission of RF energy. Also depicted in the embodiment shown in FIGS. 12A and 12C is through hole 41 and cut-away portion 43. In the embodiment shown in FIG. 15C, through hole 41 has walls comprising the material of layer 40 to provide corrosion resistant walls, formed by placement of material in the tool of an SPS apparatus as disclosed herein.

Referring now to FIGS. 12B and 12D, a three-layer dielectric window through which RF energy passes. Three-layer dielectric window includes at least one layer 40 comprising from 90% to 99.8% by volume of polycrystalline yttrium aluminum garnet (YAG) as disclosed herein. At least one surface of layer 40 comprises pores wherein the pores have a pore size not exceeding 5 μm and have a maximum pore size of 1.5 μm for at least 95% of the pores. Three-layer dielectric window comprises layer 42 comprising zirconia toughened alumina, wherein the zirconia is present in an amount of from 5 to 25%, preferably from 10 to 25%, preferably from 15 to 25%, preferably from 15 to 17%, preferably from 20 to 25%, preferably from 5 to 20%, preferably from 5 to 15%, preferably from 5 to 10%, preferably from 15 to 20% each by volume of layer 42. The specific composition of the layer 42 of zirconia toughened alumina may be selected to match the coefficient of thermal expansion of the YAG layer across temperatures of use in semiconductor plasma processing chambers. As such, in embodiments, it may be preferable that the layer of zirconia toughened alumina comprises about 16% by volume of zirconia and the balance alumina. Three-layer dielectric window comprises at least one third layer 44 comprising multiple phases comprising at least one of YAG, alumina, and zirconia. The at least one third layer 103 may comprise YAG in an amount by area of from greater than 50% to 90%, preferably from greater than 50% to 80%, preferably from greater than 50% to 60%, and more preferably about 51% to 55%, relative to the area of an exemplary, polished surface of the at least one third layer. The layers 40, 42, 44 allow the transmission of RF energy. Also shown in the embodiment shown in FIGS. 12B and 12D is through hole 41 through which a cooling liquid could flow such as, for example, a liquid that does not absorb microwave radiation, while removing heat from the window. Also shown in FIGS. 15B and 15D is cut-away portion 43. In the embodiment shown in FIG. 15D, through hole 41 has walls comprising the material of layer 40 to provide corrosion resistant walls, formed by placement of powder material in the center of the tool of an SPS apparatus as disclosed herein.

The dielectric window may have any shape such as, for example, a disk shape, or a circular shape and be sufficiently large enough to form the ceiling of the process chamber.

In another embodiment, provided herewith is a dielectric window for use in a plasma vacuum processing chamber, the dielectric window comprising: a body comprising at least one first layer comprising a surface having a surface area and at least one crystalline phase of from 90% to 99.8% by volume of polycrystalline yttrium aluminum garnet (YAG), at least one second layer comprising alumina and zirconia wherein the zirconia comprises at least one of stabilized and partially stabilized zirconia, and at least one third layer comprising at least one selected from the group consisting of YAG, alumina, and zirconia, wherein the at least one second layer is disposed between the at least one first layer and the at least one third layer, wherein an absolute value of the difference in coefficient of thermal expansion (CTE) between the at least one first, second and third layers is from 0 to 0.75×10⁻⁶/° C. as measured in accordance with ASTM E228-17, wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores. In a two-layered embodiment, either of the at least one second layer or the at least one third layer is optional.

Window components as disclosed herein may comprise any number of embodiments without limitation. Embodiments of the sintered ceramic bodies and multilayer structures as disclosed herein may be machined to form at least one window component selected from the group consisting of an RF window, a dielectric window, a multilayer window and other equivalents as known to those skilled in the art.

In embodiments, two or more of the components as disclosed herein may be provided in combination without limitation. For example, a gas injector or nozzle comprising solid YAG may be provided in combination with a multilayer sintered ceramic window comprising YAG and a modified alumina as disclosed herein.

In the present disclosure, surfaces of components of a plasma vacuum processing chamber such as those described above that are exposed to process gases exhibit a superior resistance to corrosion as a result of plasma and process gases under harsh temperature, pressure, and corrosive conditions typically experienced during, for example, a plasma etch process. In some embodiments, the at least one surface of the components disclosed herein has at least one surface having a surface area wherein the at least one surface comprises at least one crystalline phase of yttrium aluminum oxide, wherein the at least one crystalline phase of yttrium aluminum oxide comprises pores having a pore size not exceeding 5 μm. In other embodiments, the at least one surface of the components disclosed herein has at least one surface having a surface area wherein the at least one surface comprises at least one crystalline phase of yttrium aluminum oxide, wherein the at least one crystalline phase of yttrium aluminum oxide comprises pores having a pore size not exceeding 2 μm. In some embodiments, the at least one crystalline phase of yttrium aluminum oxide has a maximum pore size of 1.5 μm for at least 95% of the pores. In some embodiments, the pores occupy less than 0.2% of the surface area. In other embodiments, the pores occupy less than 0.1% of the surface area.

The at least one crystalline phase of yttrium aluminum oxide according to one embodiment of the present invention has few pores and a small distribution with pore size of preferably essentially less than 2.00 μm, more preferably essentially less than 1.75 μm, most preferably essentially less than 1.50 μm.

The yttrium aluminum oxide body (or finished process component) is further characterized by having a pore size distribution with a maximum pore size of 1.50 μm for 95% or more of all pores, preferably with a maximum pore size of 1.75 μm for 97% or more of all pores, more preferably with a maximum pore size of 2.00 μm for 99% or more of all pores.

The yttrium aluminum oxide body (or finished process component) is further characterized by having pores not exceeding a pore size of 7 μm, preferably having pores not exceeding a pore size of more than 6 μm, more preferably having pores not exceeding a pore size of more than 5 μm.

The yttrium aluminum oxide body (or finished process component) is further characterized by having a developed interfacial area ratio in an unetched area of less than 100×10⁻⁵, more preferably less than 75×10⁻⁵, most preferably less than 50×10⁻⁵, according to ISO standard 25178-2-2012, section 4.3.2.

The yttrium aluminum oxide body (or finished process component) is further characterized by having a developed interfacial area ratio in an etched area of less than less than 600×10⁻⁵, more preferably less than 500×10⁻⁵, more preferably less than 400×10⁻⁵, more preferably less than 300×10⁻⁵, most preferably less than 200×10⁻⁵, according to ISO standard 25178-2-2012, section 4.3.2. This developed interfacial ratio is realized in case a sample of the yttrium aluminum oxide body with a dimension of 6 mm×6 mm×2 mm is subjected to etching conditions at a pressure of 10 millitorr with a CF₄ flow rate of 90 standard cubic centimetres per minute (sccm), an oxygen flow of 30 standard cubic centimetres per minute (sccm), and argon flow of 20 standard cubic centimetres per minute (sccm), a bias of 600 volts and 2000 watt ICP power for a duration of 24 hours CF₄ etch time. The respective etch process is described in more detail further below.

The yttrium aluminum oxide body (or finished process component) is further characterized by having a developed interfacial area ratio in an unetched area of less than 100×10⁻⁵, more preferably less than 75×10⁻⁵, most preferably less than 50×10⁻⁵, according to ISO standard 25178-2-2012, section 4.3.2; and having a developed interfacial area ratio in an etched area of less than 600×10⁻⁵, more preferably less than 500×10⁻⁵, more preferably less than 400×10⁻⁵, more preferably less than 300×10⁻⁵, most preferably less than 200×10⁻⁵, according to ISO standard 25178-2-2012, section 4.3.2. This latter developed interfacial ratio is realized in case a sample of the yttrium aluminum oxide body with a dimension of 6 mm×6 mm×2 mm is subjected to etching conditions at a pressure of 10 millitorr with a CF₄ flow rate of 90 standard cubic centimetres per minute (sccm), an oxygen flow of 30 standard cubic centimetres per minute (sccm), and argon flow of 20 standard cubic centimetres per minute (sccm), a bias of 600 volts and 2000 watt ICP power for a duration of 24 hours CF₄ etch time. The respective etch process is described in more detail further below.

The yttrium aluminum oxide body (or finished process component) is further characterized by having an arithmetical mean height Sa of less than 30 nm, more preferably less than 28 nm, most preferably less than 25 nm, according to ISO standard 25178-2-2012, section 4.1.7.

The yttrium aluminum oxide body (or finished process component) is further characterized by having an arithmetical mean height Sa of less than 40 nm, more preferably loss than 35 nm, most preferably less than 30 nm, according to ISO standard 25178-2-2012, section 4.1.7. This arithmetical mean height Sa is realized in case a sample of the yttrium aluminum oxide body with a dimension of after a sample of the dimension of 6 mm×6 mm×2 mm is subjected to etching conditions at a pressure of 10 millitorr with a CF₄ flow rate of 90 standard cubic centimetres per minute (sccm), an oxygen flow of 30 standard cubic centimetres per minute (sccm), and argon flow of 20 standard cubic centimetres per minute (sccm), a bias of 600 volts and 2000 watt ICP power. This process is carried out for a total CF₄ etch time of 24 hours. The respective etch process is described in more detail further below.

The yttrium aluminum oxide body (or finished process component) is further characterized by having an arithmetical mean height Sa of less than 30 nm, more preferably less than 28 nm, most preferably less than 25 nm, according to ISO standard 25178-2-2012, section 4.1.7; and with an arithmetical mean height Sa of less than 40 nm, more preferably loss than 35 nm, most preferably less than 30 nm, according to ISO standard 25178-2-2012, section 4.1.7. The latter arithmetical mean height Sa is realized in case a sample of the yttrium aluminum oxide body with a dimension of 6 mm×6 mm×2 mm is subjected to etching conditions at a pressure of 10 millitorr with a CF₄ flow rate of 90 standard cubic centimetres per minute (sccm), an oxygen flow of 30 standard cubic centimetres per minute (sccm), and argon flow of 20 standard cubic centimetres per minute (sccm), a bias of 600 volts and 2000 watt ICP power. This process is carried out for a total CF₄ etch time of 24 hours. The respective etch process is described in more detail further below.

The yttrium aluminum oxide body (or finished process component) is further characterized by having a porous structure, whereby less than 0.2%, more preferably less than 0.15%, most preferably less than 0.1%, of the surface area of the sintered yttrium aluminum oxide body are taken up by pores. This porous structure measured on a surface may be representative of porosity levels within the bulk yttrium aluminum oxide body.

In certain embodiments, the ceramic sintered component formed from the ceramic sintered body may comprise YAG having a phase purity of about 99.6% and less by volume and a chemical purity of greater than 99.99%. In alternate embodiments, the ceramic sintered component may comprise YAG having a phase purity of from 97 to 99.9% by volume, further comprising an aluminum oxide phase of from 0.1 and 3% by volume. The corrosion resistant ceramic sintered components may be formed from any of the aforementioned embodiments of the ceramic sintered bodies as disclosed herein.

Corrosion resistant ceramic sintered components as required for semiconductor etch chambers may be made from embodiments of the ceramic sintered body as disclosed herein and may include RF or dielectric windows, nozzles or injectors, shower heads, (etch) chamber liners, mixing manifolds, wafer supports, electronic wafer chucks, and various process rings such as focus rings and protective rings, among other shapes. Accordingly, properties such as density, volumetric porosity, hardness, purity, grain size, strength, etc. are transferred to the ceramic sintered component formed therefrom.

The ceramic sintered body/component may have mechanical properties sufficient to allow fabrication of a large body size for use in plasma etching chambers. The components as disclosed herein may have a size of from 200 mm to 610 mm, preferably from 300 to 610 mm, preferably from 350 to 610 mm, preferably from 400 to 610 mm, more preferably from 450 to 610 mm, more preferably from 500 to 610 mm, preferably from 100 to 605 mm, preferably from 200 to 605 mm, preferably from 550 to 610 mm, each with regard to the greatest dimension of the sintered body. To assess mechanical strength, Sample 6 was polished in accordance with known techniques to prepare type B bars for 4-point strength testing. Sample 6 was prepared using a sintering temperature of 1500° C. at a pressure of 30 MPa for a duration of 30 minutes, followed by annealing in air at 1400° C. for a duration of 8 hours. A density using the methods disclosed herein was measured of 4.545 or 99.77% of theoretical, corresponding to porosity of 0.23%. High strength values are reported in Table 4 indicating the ceramic sintered bodies as disclosed herein will have mechanical strengths sufficient for preparation of chamber components as disclosed herein.

The method as disclosed herein provides for an improved control over the crystalline phase purity, chemical purity, density and density variation, mechanical strength and thereby handleability of the corrosion resistant ceramic sintered component in particular for those ceramic bodies of dimensions greater than, for example, 200 mm across a maximum feature size, and the reduction of oxygen vacancies in the lattice of the corrosion resistant ceramic sintered component. Table 13 lists dimensions, average density, percent of theoretical for YAG, density variation and volumetric porosity for exemplary ceramic sintered bodies as disclosed herein.

TABLE 13

| | | Ave D | | % density | % vol. |
|---|---|---|---|---|---|
| Sample | Size (mm) | (g/cc) | % TD | variation | porosity |
| 519 | 100 | 4.534 | 99.517 | <1% | 0.483 |
| 531 | 100 | 4.552 | 99.912 | <1% | 0.088 |
| 514 | 100 | 4.549 | 99.846 | <1% | 0.154 |
| 172 | 150 | 4.553 | 99.930 | <1% | 0.070 |
| 6 | 150 | 4.545 | 99.766 | <1% | 0.234 |
| 191 | 406 | 4.464 | 97.971 | 0.120 | 2.029 |
| 258 | 406 | 4.542 | 99.687 | 0.430 | 0.313 |
| 164 | 406 | 4.467 | 98.050 | 2.061 | 1.950 |
| 355 | 572 | 4.429 | 97.220 | 4.164 | 2.652 |
| 395 | 572 | 4.389 | 96.335 | 1.712 | 3.656 |
| 506 | 622 | 4.546 | 99.783 | <0.208 | 0.217 |

### Performance

Etching was carried out on a corrosion resistant ceramic sintered body prepared according to the method disclosed herein, as described following.

Etch Procedure:

To assess etch performance, a sample comprising the ceramic sintered body of sample 519 of example 1 having dimension 6 mm×6 mm×2 mm was mounted onto a c plane sapphire wafer using a heat sink compound. The surface quality was assessed by measuring Sa, Sz and Sdr before and after an etching process.

The dry etch process was performed using a Plasma-Therm Versaline DESC PDC Deep Silicon Etch which is standard equipment for the industry. Etching was completed using a 2-step process for a total duration of 6 hours. The etch method was performed having a pressure of 10 millitorr, a bias of 600 volts and ICP power of 2000 watts. The etch method was conducted with a first etch step having a CF₄ flow rate of 90 standard cubic centimetres per minute (sccm), an oxygen flow rate of 30 standard cubic centimetres per minute (sccm), an argon flow rate of 20 standard cubic centimetres per minute (sccm), and a second etch step having an oxygen flow rate of 100 standard cubic centimetres per minute (sccm) and an argon flow rate of 20 standard cubic centimetres per minute (sccm), wherein first and second etch steps are performed for 300 seconds each and repeated for a combined duration of 6 hours.

The etch conditions as used here to assess sample performance were selected to subject the disclosed materials to extreme etch conditions in order to differentiate performance. Upon completion of the etch procedure, surface roughness parameters of Sa, Sz and Sdr were measured.

Surface Roughness Measurement

Surface roughness measurements were performed using a Keyence 3D laser scanning confocal digital microscope model VK-X250X under ambient conditions in a class 1 cleanroom. The microscope rests on a TMC tabletop CSP passive benchtop isolator with 2.8 Hz Natural Frequency. This non-contact system uses laser beam light and optical sensors to analyse the surface through reflected light intensity. The microscope acquires 1,024 data points in the x direction and 786 data points in the y direction for a total of 786,432 data points. Upon completion of a given scan, the objective moves by the pitch set in the z direction and the intensity is compared between scans to determine the focus. The ISO 25178 Surface Texture (Areal Roughness Measurement) is a collection of international standards relating to the analysis of surface roughness with which this microscope is compliant.

The surface of the sample was laser scanned using the confocal microscope at 50× magnification to capture a detailed image of the sample. Line roughness was obtained on a profile of 7 partitioned blocks. The lambda chi(λ), which represents the measurement sampling lengths, was adjusted so that the line reading was limited to measurements from the 5 middle blocks of the 7 according to ISO specification 4288: Geometrical Product Specifications (GPS)-Surface texture: Profile method-Rules and procedures for the assessment of surface texture.

Areas were selected within etched and unetched regions of the ceramic sintered body for measurement. Areas were selected to be most representative of the typical sample surface, and used to calculate Sa, Sz and Sdr.

Sa represents an average roughness value calculated across a user-defined area of a surface of the ceramic sintered body. Sz represents the maximum peak-to-valley distance across a user-defined area of a surface of the ceramic sintered body. Sdr is a calculated numerical value defined as the “developed interfacial area ratio” and is a proportional expression for an increase in actual surface area beyond that of a completely flat surface. A flat surface is assigned a Sdr of zero, and the value increases with the slope of the surface. Larger numerical values correspond with greater increases in surface area. This allows for numerical comparison of the degree of surface area increase of a sample. It represents additional surface area arising from texture or surface features as compared to a planar area.

The surface roughness features of Sa, Sz and Sdr are well-known parameters in the underlying technical field and, for example, described in ISO standard 25178-2-2012, section 4.3.2.

The present disclosure relates to a specific ceramic sintered body and/or component made therefrom having a corrosion resistant surface before an etch or deposition process providing an arithmetical mean height, Sa, in an unetched area of less than 15 nm, more preferably loss than 13 nm, more preferably less than 10 nm, more preferably less than 08 nm, according to ISO standard 25178-2-2012, section 4.1.7. surface roughness and not exceeding a specific value.

The present disclosure relates to a specific ceramic sintered body and/or component made therefrom having a corrosion resistant surface before an etch or deposition process providing a maximum height, Sz, of less than 5.0 μm, more preferably loss than 4.0 μm, most preferably less than 3.5 μm, more preferably less than 2.5 μm, more preferably less than 2 μm, more preferably less than 1.5 μm, according to ISO standard 25178-2-2012, section 4.1.7. surface roughness and not exceeding a specific value.

The present disclosure relates to a specific ceramic sintered body and/or component made therefrom having a corrosion resistant surface before an etch or deposition process providing a developed interfacial area, Sdr, of less than 1500×10⁻⁵, more preferably loss than 1200×10⁻⁵, more preferably less than 1000×10⁻⁵, more preferably less than 800×10⁻⁵, more preferably less than 600×10⁻⁵, more preferably less than 400×10⁻⁵, according to ISO standard 25178-2-2012, section 4.1.7. surface roughness and not exceeding a specific value.

The present disclosure relates to a specific ceramic sintered body and/or component made therefrom having a corrosion resistant surface after the etch or deposition process as disclosed herein providing an arithmetical mean height, Sa, of less than 25 nm, less than 20 nm, more preferably loss than 18 nm, more preferably less than 16 nm, more preferably less than 14 nm, more preferably less than 12 nm, according to ISO standard 25178-2-2012, section 4.1.7. surface roughness and not exceeding a specific value.

The present disclosure relates to a specific ceramic sintered body and/or component made therefrom having a corrosion resistant surface after the etch or deposition process as disclosed herein providing a maximum height, Sz, of less than 4.8 μm, more preferably less than 3.8 μm, most preferably less than 3.2 μm, more preferably less than 2.5 μm, more preferably less than 2 μm, more preferably less than 1.5 μm, according to ISO standard 25178-2-2012, section 4.1.7. surface roughness and not exceeding a specific value.

The present disclosure relates to a specific ceramic sintered body and/or component made therefrom having a corrosion resistant surface after the etch or deposition process as disclosed herein providing a developed interfacial area, Sdr, of less than 3000×10⁻⁵, more preferably less than 2500×10⁻⁵, more preferably less than 2000×10⁻⁵, more preferably less than 1500×10⁻⁵, more preferably less than 1000×10⁻⁵, more preferably less than 800×10⁻⁵, according to ISO standard 25178-2-2012, section 4.1.7. surface roughness and not exceeding a specific value.

In one embodiment, the ceramic sintered body comprising from 90% to 99.8% by volume of polycrystalline yttrium aluminum garnet (YAG) and a volumetric porosity of from 0.1 to 4% as calculated from density measurements performed in accordance with ASTM B962-17 has an arithmetical mean height (Sa) in an unetched area of 15 nm or less, and an arithmetical mean height (Sa) in an etched area of 20 nm or less 20 nm when exposed to an etch method having a pressure of 10 millitorr, a bias of 600 volts, ICP powder of 2000 watts, the etch method further comprising a first etch step having a CF₄ flow rate of 90 standard cubic centimetres per minute (sccm), an oxygen flow rate of 30 standard cubic centimetres per minute (sccm), an argon flow rate of 20 standard cubic centimetres per minute (sccm), and a second etch step having an oxygen flow rate of 100 standard cubic centimetres per minute (sccm) and an argon flow rate of 20 standard cubic centimetres per minute (sccm) wherein steps one and two are performed for 300 seconds each and repeated for a combined duration of 6 hours. In one embodiment, the ceramic sintered body has an arithmetical mean height (Sa) in an unetched area of 12 nm or less and an arithmetical mean height (Sa) in an etched area of 16 nm or less. In another embodiment, the ceramic sintered body has an arithmetical mean height (Sa) in an unetched area of 10 nm or less and an arithmetical mean height (Sa) in an etched area of 12 nm or less.

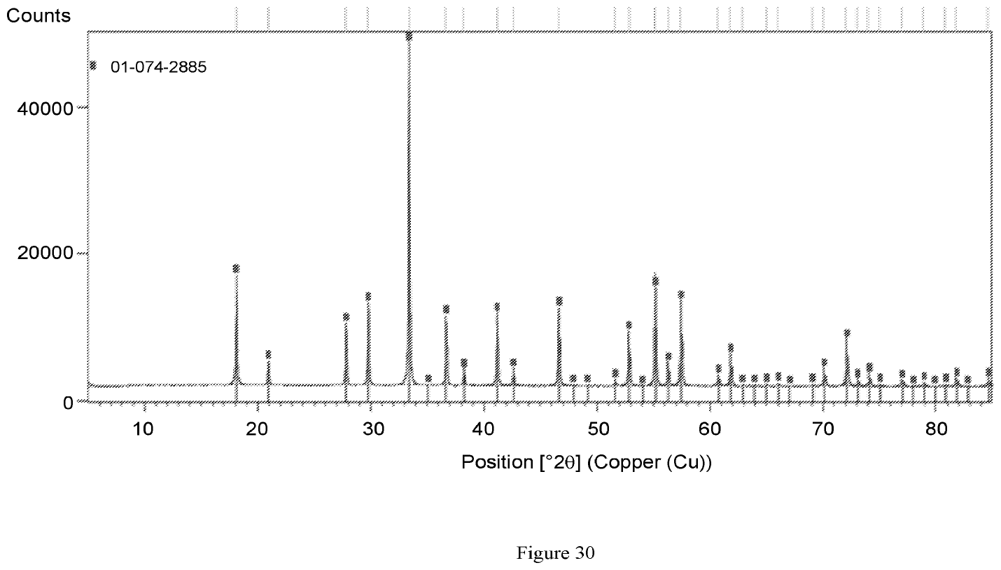

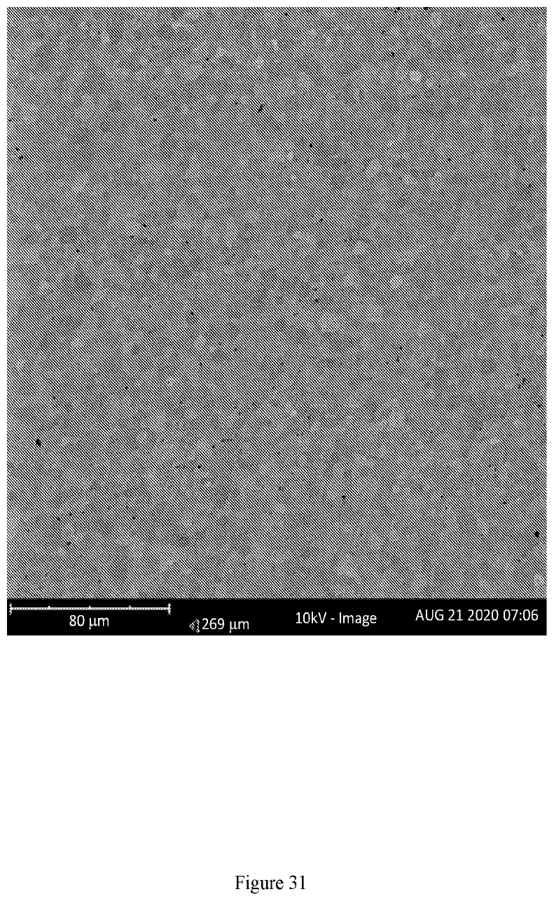

Embodiments as disclosed herein include a polycrystalline ceramic sintered body and components fabricated therefrom which are adapted for use in exemplary semiconductor processing chambers depicted in FIGS. 30 and 31.

The embodiments of the ceramic sintered body as disclosed herein can be combined in any specific ceramic sintered body. Thus, two or more of the characteristics disclosed herein can be combined to describe the ceramic sintered body in more detail as, for example, outlined in the embodiments.

The ceramic sintered body and related corrosion resistant sintered components as disclosed herein have an improved behaviour in etch and deposition processes and improved ability to be handled and can easily be used as materials for the preparation of components for etch chambers.

The yttrium aluminium oxide materials, and in particular yttrium aluminum oxide materials comprising the YAG phase and in embodiments further comprising an aluminum oxide phase, proposed for use as etch/deposition chamber parts until today suffer, as already mentioned above, from a problem that under harsh conditions particles are generated which contaminate the products to be processed. Furthermore, it is known to be difficult to produce solid body, phase pure parts of high purity and large dimension from 100 mm to 610 mm comprising yttrium aluminium oxide, and in particular embodiments comprising phase pure yttrium aluminium garnet cubic phase (YAG). Oftentimes other phases may be present in addition to the YAG phase owing to compositional variances, insufficient mixing and/or powder contamination.

In contrast to this, the present disclosure provides a method to fabricate corrosion resistant sintered bodies and components formed therefrom for the use in plasma etching and/or deposition chambers with a focus on the phase purity, density, chemical purity, strength, hardness, surface condition, and handleability. According to the present disclosure, it was determined that the density and crystalline phase characteristics may have an important influence on the etch stability in addition to the sintered body purity, hardness and mechanical strength of the yttrium aluminium oxide materials and in particular sintered ceramic bodies formed of the YAG phase.

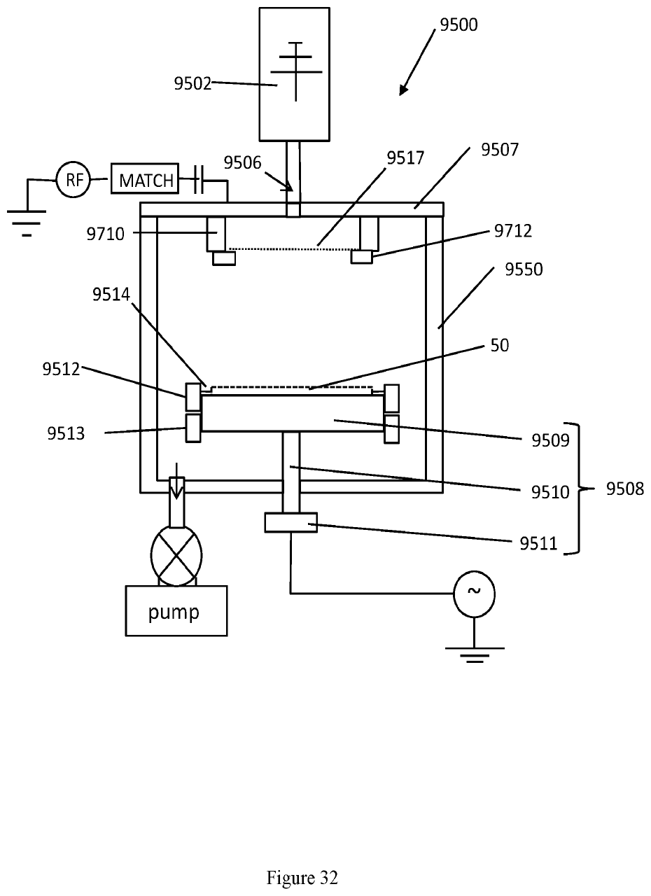

As shown in FIG. 32, embodiments of the technology as disclosed herein may be useful as components for use in a plasma processing system 9500, which may be configured for use in semiconductor etching processes, also denoted as “etch processing system”. Etch processing system 9500 may in embodiments include a remote plasma region. The remote plasma region may include a remote RF source/matching network 9502, which is also denoted as remote plasma source (“RPS”).

Etch processing system 9500 may comprise a vacuum chamber 9550 having a corrosion resistant chamber liner (not shown), a vacuum source, and a chuck or electrostatic chuck (“ESC”) 9509 on which a wafer 50, also denoted as substrate, is supported. A cover ring or electrode cover 9514, a top shield ring 9512 and shield ring 9513 surrounds the wafer 50 and puck 9509. A top plate/window/lid 9507 forms an upper wall of the vacuum chamber 9550. A showerhead 9517 forms an upper wall or is mounted beneath an upper wall of the vacuum chamber 9650. Top plate/window/lid 9507 (which may comprise an RF window or dielectric window), gas distribution system 9506, showerhead 9517, cover ring or electrode cover 9514, top shield ring 9512, shield ring 9513, chamber liner (not shown), and chuck or electrostatic chuck (ESC) 9508 and puck 9509 may be made at least in part of embodiments of the multilayer sintered ceramic bodies as disclosed herein.

Parts of the surface of the showerhead 9517 may be covered with a shield ring 9712. Parts of the surface of the showerhead 9517, especially radial sides of the surface of the showerhead 9517 may be covered with a top shield ring 9710. Shield ring 9712, showerhead 9517 and top shield ring 9710 may be made at least in part from embodiments of the multilayer sintered ceramic bodies as disclosed herein.

The remote plasma source 9502 is provided outside of the window 9507 of the chamber 9550 for accommodating the wafer 50 to be processed. The remote plasma region may be in fluid communication with the vacuum chamber 9550 through a gas delivery system 9506. In the chamber 9550, a reactive plasma may be generated by supplying a processing gas to the chamber 9550 and a high frequency power to the plasma source 9502. By using the reactive plasma thus generated, a predetermined plasma processing is performed on the wafer 50. A planar antenna having a predetermined pattern is widely used for the high frequency antenna of the etch processing system 9500.

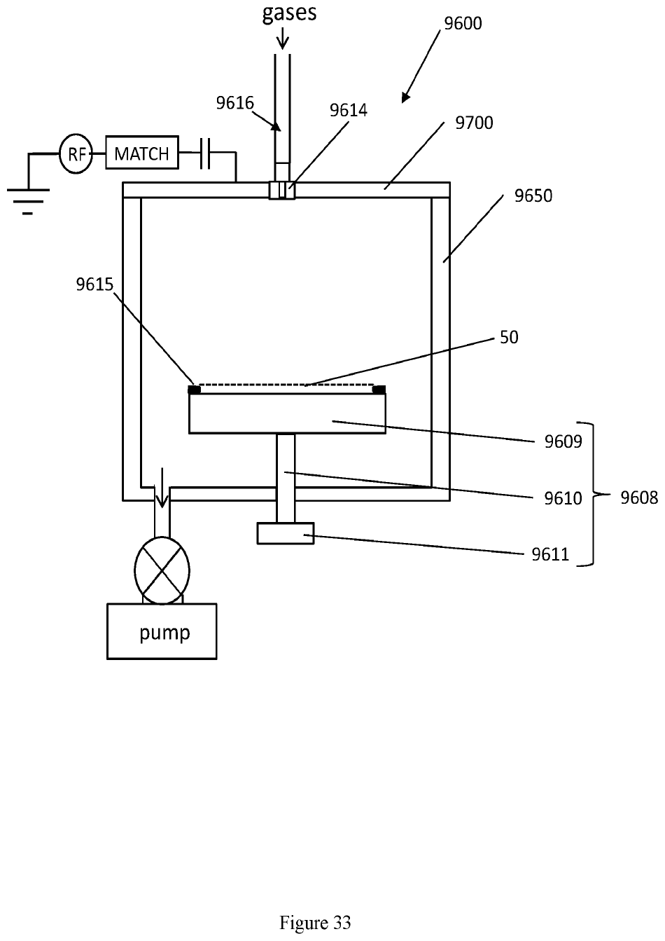

As shown in FIG. 33, embodiments of the technology as disclosed herein may be useful as components in a plasma processing system 9600 which may be configured for use in semiconductor deposition processes, also called “deposition processing system”. Deposition processing system 9600 comprises a vacuum chamber 9650, a vacuum source, and a puck 9609 on which a wafer 50, also denoted as semiconductor substrate, is supported. The processing system may further include a nozzle or injector 9614 which is in fluid communication with a gas delivery system 9616 for supplying process gases to the interior of the vacuum chamber 9650. A top wall 9700 of the chamber 9650 may comprise a central opening configured to receive a central gas injector (also referred to as nozzle), 9614. In certain embodiments, the top wall 9700 of the chamber may comprise an RF or dielectric window configured with a central opening to accommodate injector, 9614. An RF energy source energizes the process gas into a plasma state to process the substrate 50. Embodiments of the top wall, comprising an RF or dielectric window 9700, the gas delivery system 9616 and the central gas injector 9614 may be made entirely or partially from embodiments of the multilayer sintered ceramic body as disclosed herein.

Deposition processing system 9600 may further include an electrostatic chuck 9608 that is designed to carry a wafer 50. The chuck 9608 may comprise a puck 9609, for supporting the wafer 50. Parts of the supporting surface of the puck 9609 may be covered with a deposition ring, 9615. Other names for deposition ring 9615 such as deposition shield or deposition ring assembly are taken as synonymous and may be used interchangeably herein. Deposition ring 9615 may be made entirely or partially from embodiments of the multilayer sintered ceramic body as disclosed herein.

The puck 9609 may be formed fully or in part from embodiments of the multilayer sintered ceramic body as disclosed herein and may have a chucking electrode disposed within the puck proximate a support surface of the puck 9609 to electrostatically retain the wafer 50 when disposed on the puck 9609. The chuck 9608 may comprise a base 9611 having a ring-like extending to support the puck 9609; and a shaft 9610 disposed between the base and the puck to support the puck above the base such that a gap is formed between the puck 9609 and the base 9610, wherein the shaft 9610 supports the puck proximate a peripheral edge of the puck 9609. Chuck 9608, puck 9609, and deposition ring 9615 may be made entirely or partially from embodiments of the unitary, multilayer sintered ceramic body as disclosed herein.

The aforementioned Ceramic sintered bodies, comprised in certain embodiments of phase-pure YAG, and in alternate embodiments of at least one phase of YAG, YAP, YAM and combinations thereof, may lend itself to fabrication of large corrosion resistant components of dimensions from 100 mm to 625 mm, with regard to the greatest dimension of the sintered body. The large component dimensions described herein may be enabled by the increased density, density uniformity and hardness of the ceramic sintered body from which chamber components may be fabricated.

Disclosed herein is the use in semiconductor processing chambers of a ceramic sintered body in embodiments comprising the yttrium aluminum garnet (YAG) phase, and in other embodiments comprising the yttrium aluminum garnet (YAG) phase and aluminum oxide, and in other embodiments comprising at least one of the forms of yttrium aluminum oxide including YAG, YAP and YAM and, optionally, minor phases of yttrium oxide and/or aluminum oxide, and combinations thereof, providing a ceramic sintered body which displays improved plasma corrosion and erosion resistance over other materials when subjected to halogen-based plasma etch conditions as well as under deposition conditions.

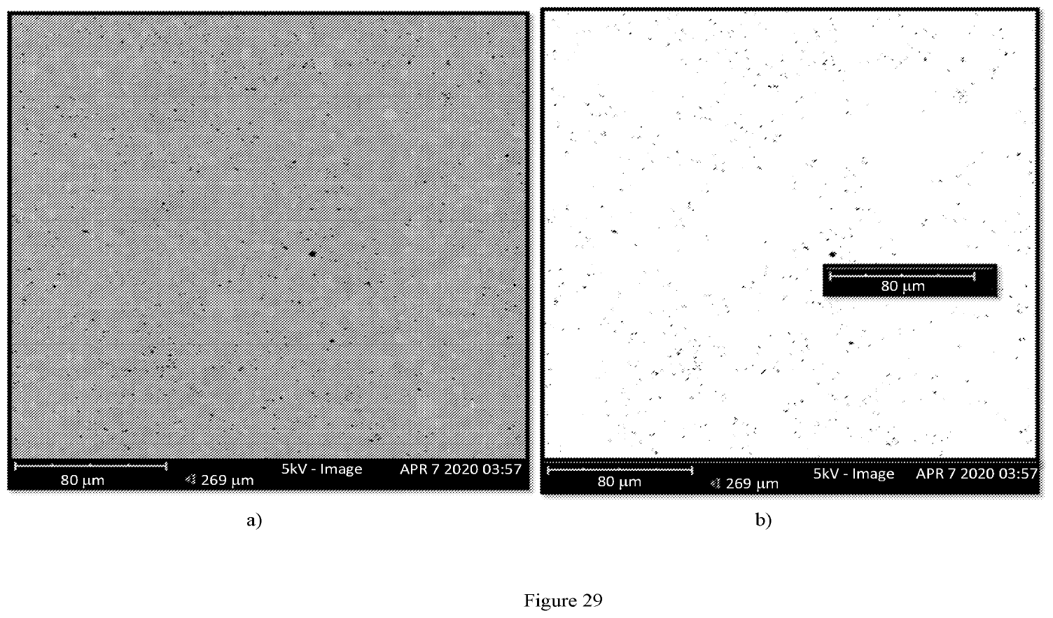

The ceramic sintered body disclosed herein may have an aluminum oxide phase both on a surface and throughout the body. Thus, in embodiments, the ceramic sintered body may comprise an integral body comprising YAG made according to the process disclosed herein which further comprises an aluminum oxide phase distributed throughout the body. In other words, a structure measured on a surface is representative of a structure within a volume of the bulk ceramic sintered body comprising YAG and in embodiments further comprising aluminum oxide. Thus, disclosed herein is a ceramic sintered body comprising yttrium aluminum oxide having garnet crystallographic structure (YAG) in an amount of about 99.6% by volume and an aluminum oxide phase in an amount of about 0.4% by volume, as depicted in FIG. 29 a) and b).

In other embodiments, the ceramic sintered body disclosed herein may have an aluminum oxide phase on a surface and a substrate

### EXAMPLES

Measurements for all examples were performed as described in the specification. Tables 1 to 13 disclose process conditions and properties for the exemplary ceramic sintered body examples. Table 12 discloses purity as measured using ICPMS methods for the ceramic sintered body examples.

The apparatus used to prepare the Examples below is the spark plasma sintering (SPS) tool described above comprising a die comprising a sidewall comprising an inner wall and an outer wall, wherein the inner wall has a diameter that defines an inner volume capable of receiving at least one ceramic powder; and an upper punch and a lower punch operably coupled with the die, wherein each of the upper punch and the lower punch have an outer wall defining a diameter that is less than the diameter of the inner wall of the die thereby defining a gap between each of the upper punch and the lower punch and the inner wall of the die when at least one of the upper punch and the lower punch are moved within the inner volume of the die, wherein the gap is from 10 μm to 100 μm wide.

### Comparator Example One (562)

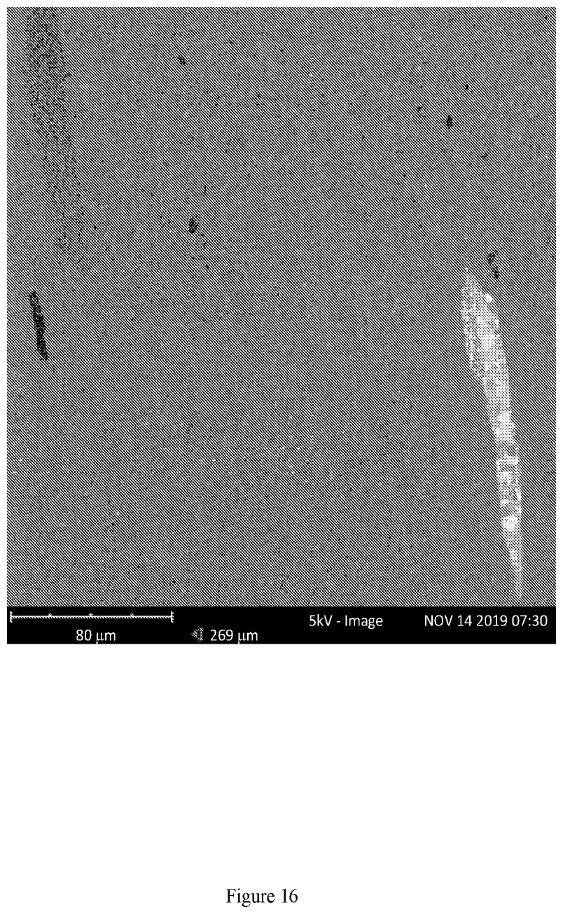

A commercially available yttrium aluminum garnet (YAG) powder (Shin-Etsu lot RYAG-OCX-102) having a specific surface area of 4.3 m²/g, a d10 particle size of 2.4 μm, a d50 particle size of 9 μm and a d90 particle size of 50 μm was sintered at 1450° C. at a pressure of 30 MPa for 30 minutes under vacuum to form a sintered body. FIG. 16 depicts SEM results, illustrating phases of yttria (white regions), YAP and/or YAM (each depicted by light gray regions in the image), and alumina (black regions) in the sintered body. Phase pure YAG is represented by the dark gray regions in the SEM image. Poor compositional control and insufficient mixing of the starting powder during powder processing will result in the mixed crystalline phases upon sintering apparent in this example. Conditions for powder batching and mixing were unavailable. The microstructure reveals compositional inhomogeneities and mixed phase regions which are evident at SEM magnifications of at least 1000× and higher. The ceramic sintered body was found to have purity of from 99.99 to 99.995%, with iron levels of from 11 to 18 ppm, as well as Titanium contamination. These non-uniform microstructures and contaminant elements and their respective amounts may result in unacceptable performance during use in semiconductor etch and deposition applications.

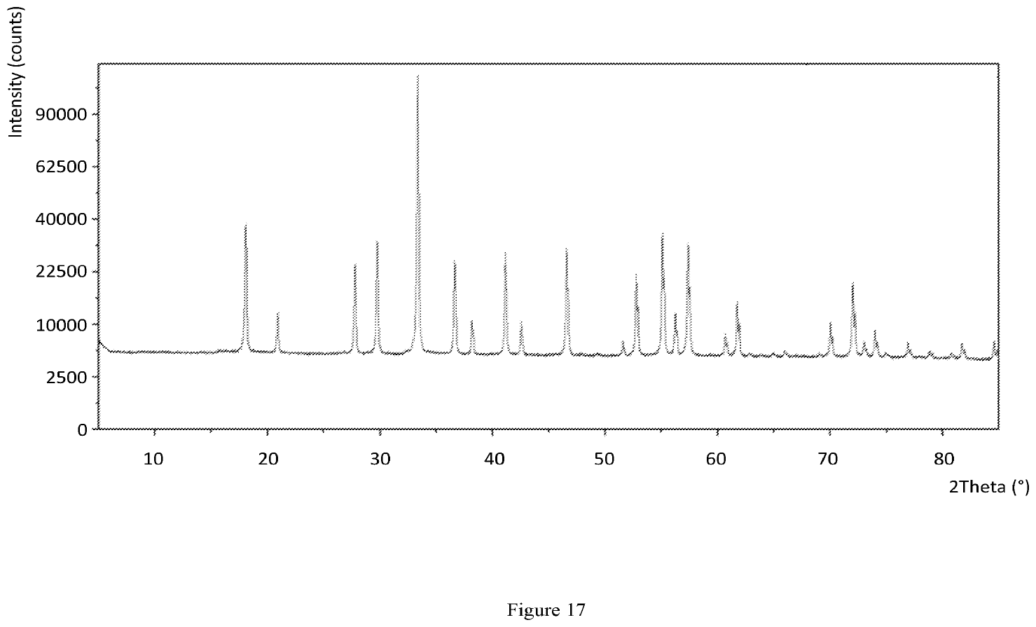

FIG. 17 shows x ray diffraction results of the commercially available starting powder used to form the comparator material of FIG. 16, illustrating 100% of the YAG phase.

### Comparator Example Two (592)

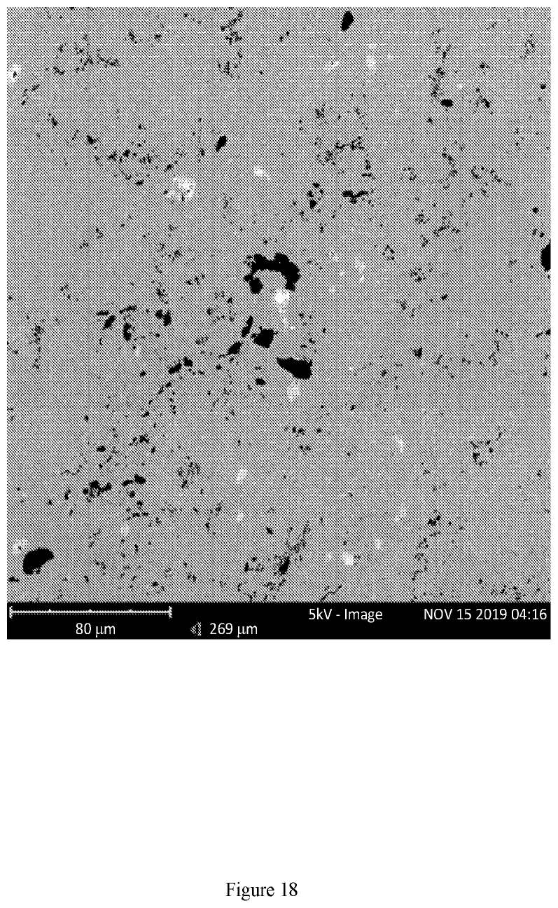

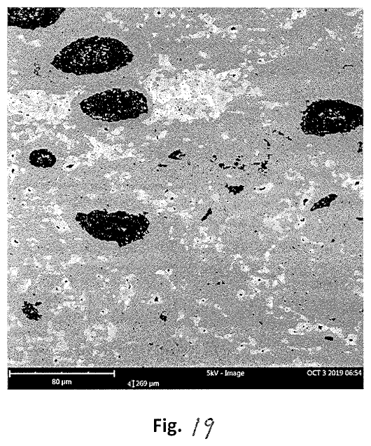

A commercially available powder mixture of yttria and alumina having a specific surface area of 7.3 m²/g, a d10 particle size of 0.15 μm, a d50 particle size of 3.5 μm and a d90 particle size of 64 μm was sintered at 1450° C. at a pressure of 30 MPa for 30 minutes under vacuum to form a sintered body having 100 mm diameter. The powder had total impurities of 48 ppm, including iron contamination of 7 ppm. FIG. 18 depicts SEM results, illustrating numerous phases of yttria, YAP and/or YAM (each depicted by light regions in the image), and alumina (black regions) resulting from powder composition inhomogeneity and/or insufficient mixing. YAG is represented by the predominately gray regions in the SEM image, while yttria regions appear white, and aluminum oxide regions appear black. Poor compositional control during powder processing will result in mixed crystalline phases upon sintering. Conditions for powder batching and mixing were unavailable. The microstructure displays compositional inhomogeneities and mixed phase regions which are evident at SEM magnifications of 1000× and higher. These non-uniform microstructures and contaminant elements and their respective amounts may result in unacceptable performance during use in semiconductor etch and deposition applications.

FIG. 19 illustrates SEM micrographs at from 1000 and 5000× of a ceramic sintered body comprising about 78% YAG (gray regions), about 13% YAP or YAM (light gray regions), white regions which may comprise yttria, and about 10% alumina (black regions) as confirmed by EDS. Mixing was performed for a duration of about 4 hours using 3N pure (99.9%) media at a loading of about 5% by powder weight. The presence of non-uniformly distributed alumina from starting materials may indicate that an improved mixing process may be necessary in order to form phase-pure yttrium aluminum oxide having the garnet structure.

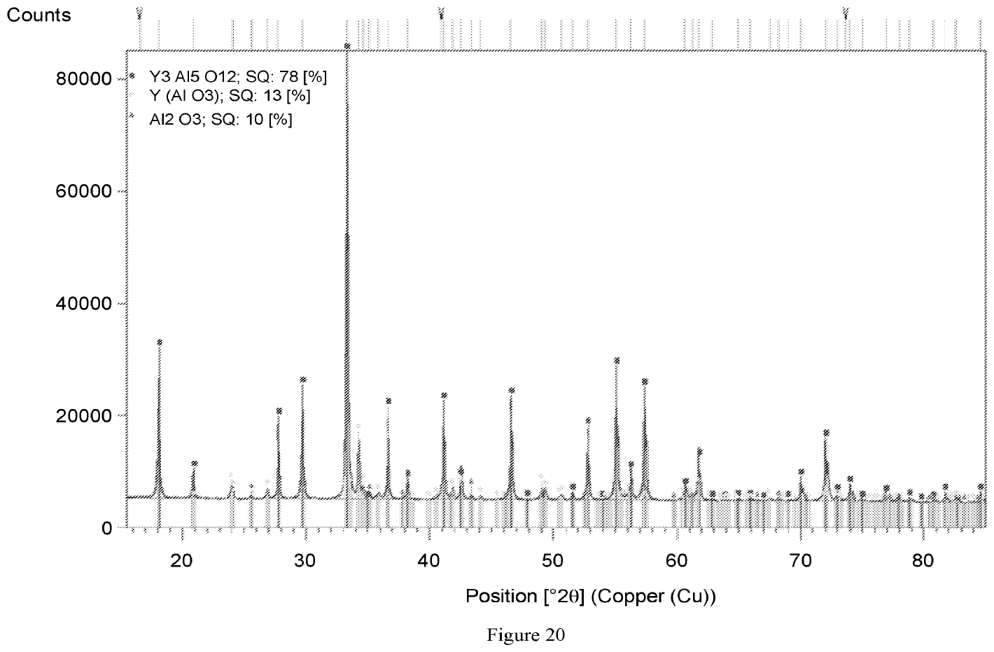

FIG. 20 illustrates x ray diffraction results for the ceramic sintered body of FIG. 19, confirming a sintered body comprising multiple phases of about 78% YAG (gray regions), about 13% YAP (light gray regions) and about 10% alumina (black regions).

### Comparator Example Three (Sample 094/Powder 092-2)

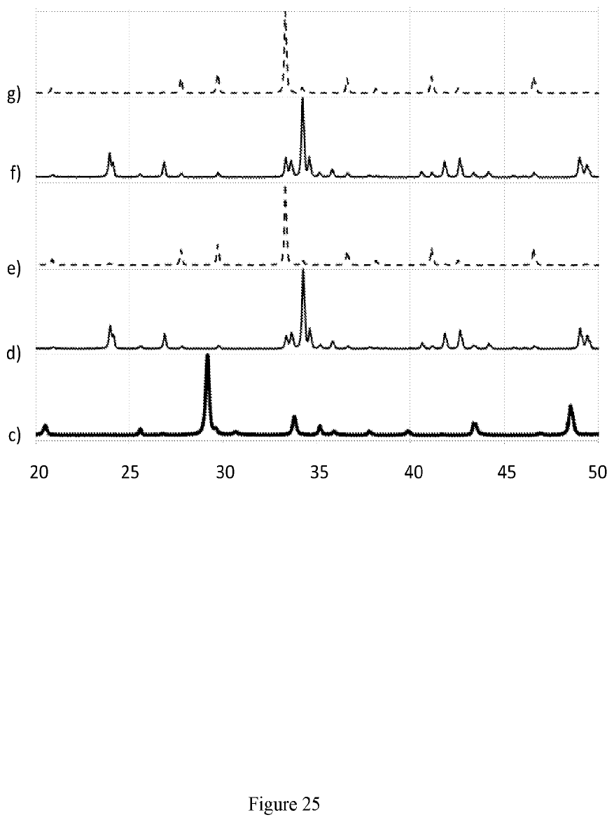

A powder of yttria having a specific surface area of 6 to 8 m²/g, and an average d10 particle size of from 2 to 4 μm, an average d50 particle size of from 4.5 μm to 6.5 μm, and d90 average particle size of from 7 to 9 μm, and a powder of alumina having a specific surface area of from 22 to 24 m²/g, a d10 particle size of from 0.08 to 0.15 μm, a d50 particle size of from 0.65 to 1.0 μm and a d90 particle size of from 2.5 to 5 μm were combined with about 50% by powder weight of high purity alumina media (99.995%) and ethanol to form a slurry in about 40 volume %. Ball milling was performed at about 120 RPM for a duration of 12 hours and the powder was thereafter dried using methods as known to those skilled in the art. Upon calcination at 1200° C. for 8 hours in air, x ray diffraction according to pattern e) of FIG. 25 indicated the calcined powder mixture comprised YAG, and the powder mixture was measured to have a specific surface area of 0.25 m²/g. The calcined powder mixture was sintered at 1500° C. at a pressure of 30 MPa for 30 minutes under vacuum and thereafter annealed at 1400° C. for 8 hours in air, forming a body having 150 mm diameter. Density measurements as disclosed herein were performed, and an average density of 4.245 g/cc was measured, corresponding to 93.2% of theoretical density for YAG, and having volumetric porosity of 6.8%. This density and porosity may result in handling issues and unacceptable performance during use in semiconductor processing applications.

FIG. 25 shows x ray diffraction results across a range of calcination conditions of the calcined powder mixtures at c) 1000° C./8 hours (powder 092-3), d) 1100° C./8 hours (powder 092-1), e) 1200° C./8 hours (powder 092-2) 1100° C./8 hours (powder 125-1), and g) 1100° C./8 hours (powder 127-1). With respect to powder c as depicted, the crystalline phases from the starting powders of yttria and alumina are present after calcination and the powder has a specific surface area of from 7 to 8 m²/g. Powder d) comprises predominately YAP crystalline phase, with the YAG crystalline phase present in amounts of less than 10% by volume, preferably less than 5% by volume as determined by XRD. A specific surface area of from 2.5 to 3.5 m²/g was measured for powder d). Powder e) comprises the YAG phase having a specific surface area of about 0.25 m²/g. Powder 0 comprises a mixture of YAP and YAG phases, having a specific surface area of about 1 m²/g. Powder g) comprises the YAG phase having a specific surface area of about 0.01 m²/g.

Formation of a ceramic sintered body comprising highly phase pure YAG may be accomplished through an in-situ, reactive sintering process using the calcined powder mixtures as disclosed herein. The driving force for this in situ/reactive phase sintering may be affected by the presence and/or amount of YAG phase in the calcined powder mixture, and/or the specific surface area for the calcined powder mixture. Thus, in certain embodiments, the calcined powder mixture is substantially free of, or free of, the yttrium aluminum garnet phase (YAG). In other embodiments, the calcined powder mixture comprises YAG phase in amounts of less than 10% by volume, preferably less than 5% by volume as measured using XRD. In certain embodiments, the calcined powder mixture may have a specific surface area of greater than 2 m²/g, preferably greater than 4 m²/g, preferably from 2 and 14 m²/g. In alternate embodiments, the calcined powder may be substantially free of, or free of, the yttrium aluminum garnet phase (YAG). In other embodiments, the calcined powder comprises the yttrium aluminum garnet phase (YAG) in amounts of less than 10% by volume, preferably less than 5% by volume and has a specific surface area of greater than 2 m²/g.

### Example One (Sample 519): Dry Mixing

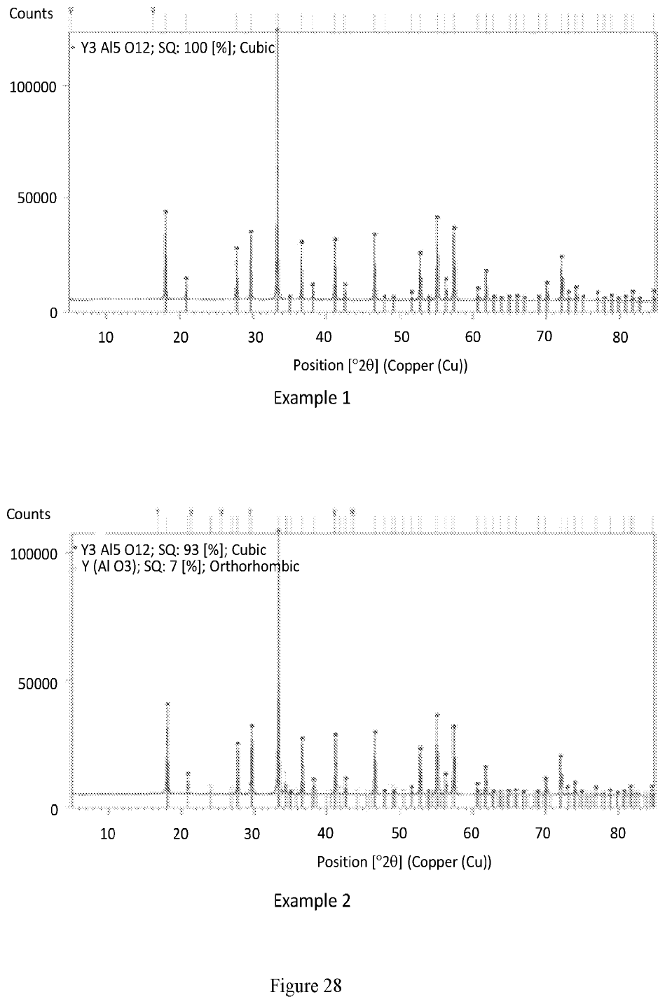

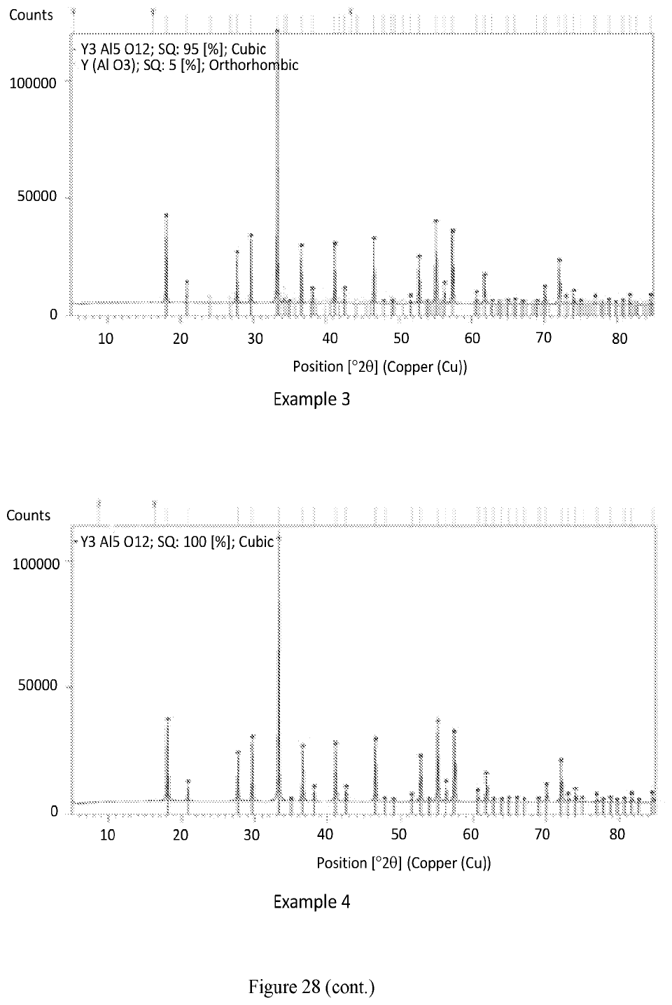

A powder of yttria having a surface area of 6-8 m²/g and a powder of alumina having surface area of 16-18 m²/g were weighed and combined to create a powder mixture in a molar ratio to form the yttrium aluminum garnet (YAG) phase upon sintering. The powder mixture was then transferred to a vertical (end over end) mixer. A single media agitator of 30 mm diameter was used during the dry mixing process, performed at about 20 RPM. After 12 hours of dry mixing, the powder was removed from the mixer. Thereafter calcination was performed at 1000° C. for 8 hours. The BET specific surface area was measured from 4.5 to 5.5 g/cc. The calcined powder mixture had a purity of 99.9996% and impurities of about 4 ppm. The powder mixture may be sieved, blended and/or milled at various process steps according to known methods. The calcined powder mixture was then sintered at a temperature of 1450° C., a pressure of 30 MPa for a duration of 30 minutes under vacuum in accordance with the method as disclosed herein. The XRD of FIG. 28 depicts 100% YAG phase formation. A total impurity content of 28 ppm, corresponding to purity of 99.9972%, was measured using ICPMS on the ceramic sintered body. The ceramic sintered body was polished according to methods known in the art, and surface roughness measurements performed using the methods and equipment as disclosed herein. Sa and Sz values of about 0.010 μm and about 3.40 μm were measured, respectively. An Sdr value of about 498×10⁻⁵ was also measured. Dry etch testing was performed using a Plasma-Therm Versaline DESC PDC Deep Silicon Etch. The etch method was performed having a pressure of 10 millitorr, a bias of 600 volts and ICP power of 2000 watts. The etch method was conducted with a first etch step having a CF₄ flow rate of 90 standard cubic centimetres per minute (sccm), an oxygen flow rate of 30 standard cubic centimetres per minute (sccm), an argon flow rate of 20 standard cubic centimetres per minute (sccm), and a second etch step having an oxygen flow rate of 100 standard cubic centimetres per minute (sccm) and an argon flow rate of 20 standard cubic centimetres per minute (sccm), wherein first and second etch steps are performed for 300 seconds each and repeated for a combined duration of 6 hours. After etching, a Sa value of about 0.016 μm and Sz value of about 3.2 μm were measured, and Sdr value of about 681×10⁻⁵ was measured after the etching process as disclosed. Tables 1, 2, 3, 8, 11 and 13 summarize results of the polycrystalline ceramic sintered bodies of example 1 according to embodiments as disclosed herein.

### Example Two (sample 529): Wet Mixing

A powder of yttria having a surface area of 6-8 m²/g and a powder of alumina having surface area of 6-8 m²/g were weighed and combined to create a powder mixture in a molar ratio to form the yttrium aluminum garnet (YAG) phase upon sintering. The powder mixture was then transferred to a vertical (end over end) mixer. Ethanol was added to the powder mixture in the end over end mixer to form a slurry of about 50% by powder weight. A single media agitator of 30 mm diameter was used during the wet mixing process, conducted at about 20 RPM. After 12 hours of wet mixing, the slurry containing the powder mixture was removed from the mixer and the ethanol was extracted using a rotary evaporator. Thereafter calcination was performed at 1000° C. for 8 hours on the powder mixture. The powder mixture may be sieved, blended and/or milled at various process steps according to known methods. The calcined powder mixture had a purity of 99.9956% and impurities of about 44 ppm. The calcined powder mixture was then sintered at a temperature of 1450° C., a pressure of 30 MPa for a duration of 30 minutes under vacuum in accordance with the method as disclosed herein. XRD of FIG. 28 depicts 93% YAG and 7% YAP phase. The YAP phase is reported to have a theoretical density of 5.35 g/cc, thus overall densities for mixed phase samples may be higher than those of pure YAG, which has theoretical density of 4.556 g/cc. The polycrystalline ceramic sintered body was polished according to methods known in the art, and surface roughness measurements performed using the methods and equipment as disclosed herein. Sa and Sz values of about 0.010 μm and about 3.75 μm were measured, respectively. An Sdr value of about 720×10⁻⁵ was also measured. Tables 1, 2, 3, 11, 12 and 13 summarize results of the ceramic sintered bodies of Example 2 according to embodiments as disclosed herein.

### Example Three (sample 531): Wet Ball Milling

A powder of yttria having a surface area of 6-8 m²/g and a powder of alumina having surface area of 6 to 8 m²/g were weighed and combined to create a powder mixture in a molar ratio to form a yttrium aluminum garnet (YAG) phase upon sintering. The powder mixture was then transferred to a container for ball milling. Alumina media at about a 50% loading by weight and ethanol in about 50% by weight were added to the container to form a slurry and enhance mixing. Ball milling using a rolling action about a horizontal axis was performed for a duration of 12 hours and thereafter the ethanol was extracted from the powder mixture using a rotary evaporator. The powder mixture was calcined at 1000° C. for 8 hours. The powder mixture may be sieved, blended and/or milled at various process steps according to known methods. The calcined powder mixture had a purity of 99.9968% and impurities of about 33 ppm. The calcined powder mixture was then sintered at a temperature of 1450° C., a pressure of 30 MPa for a duration of 30 minutes under vacuum in accordance with the method as disclosed herein. XRD of FIG. 28 depicts 95% YAG and 5% YAP phase. The YAP phase is reported to have a theoretical density of 5.35 g/cc, thus overall densities for mixed phase sintered bodies may be higher than those of pure YAG, having theoretical density of 4.556 g/cc. The polycrystalline ceramic sintered body was polished according to methods known in the art, and surface roughness measurements performed using the methods and equipment as disclosed herein. Sa and Sz values of about 0.010 μm and about 3.9 μm were measured, respectively. An Sdr value of about 885×10⁻⁵ was also measured. Tables 1, 2, 3, 11 and 12 summarize results of the ceramic sintered bodies of example 3 according to embodiments as disclosed herein.

### Example Four (Sample 514): Wet Ball Milling

A powder of yttria having a surface area of 6-8 m²/g and a powder of alumina having surface area of 16 to 18 m²/g were weighed and combined to create a powder mixture in a molar ratio to form a yttrium aluminum garnet (YAG) phase upon sintering. The powder mixture was then transferred to a container for ball milling. Alumina media at about a 50% loading by powder weight and ethanol in about 50% by weight were added to the container to form a slurry and enhance mixing. In other instances, ball milling may be performed with water or under dry conditions using only yttria or zirconia media. Ball milling using a rolling action about a horizontal axis was performed for a duration of 12 hours and thereafter the ethanol was extracted from the powder mixture using a rotary evaporator. The powder mixture was calcined at 1000° C. for 4 hours. The powder mixture may be sieved, blended and/or milled at various process steps according to known methods. The calcined powder mixture was then sintered at a temperature of 1450° C., a pressure of 30 MPa for a duration of 30 minutes under vacuum in accordance with the method as disclosed herein. 100% YAG phase was found using x ray diffraction as depicted in FIG. 28. The polycrystalline ceramic sintered body was polished according to methods known in the art, and surface roughness measurements performed using the methods and equipment as disclosed herein. Sa and Sz values of about 0.012 μm and about 3.63 μm were measured, respectively. An Sdr value of about 1138×10⁻⁵ was also measured. Tables 1, 2, 11, 12 and 13 summarize results of the ceramic sintered bodies of example 4 according to embodiments as disclosed herein.

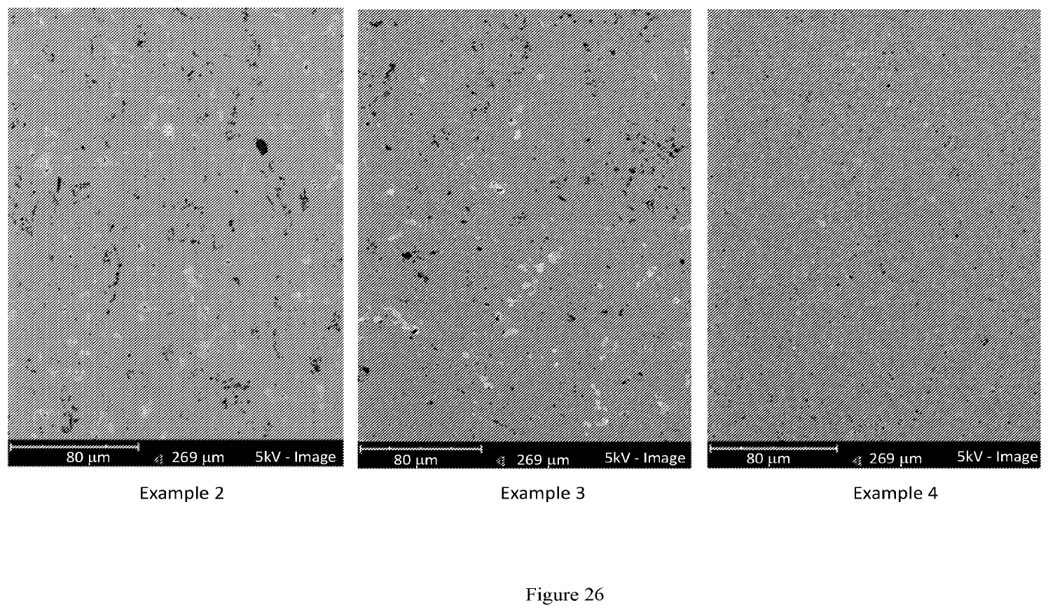

FIG. 26 illustrates 1000×SEM micrographs of sintered ceramic bodies comprising at least one yttrium aluminum oxide as disclosed herein in accordance with Examples 2, 3 and 4. As depicted, Example 2 illustrates about 93% YAG phase with about 7% YAP phase, while Example 3 illustrates about 95% YAG phase and about 5% YAP phase, and Example 4 confirms formation of about 100% YAG phase.

FIG. 27 illustrates 5000× micrographs of sintered ceramic bodies comprising at least one yttrium aluminum oxide as disclosed herein in accordance with Examples 1, 2, 3 and 4. As depicted, example 1 depicts about 100% YAG formation with a grain size of about 8 um and less; Example 2 illustrates about 93% YAG phase with about 7% YAP phase (lighter regions), while Example 3 illustrates about 95% YAG phase and about 5% YAP phase (lighter regions), and Example 4 confirms formation of about 100% YAG phase. FIG. 17 depicting example 1 further depicts a microstructure having a maximum grain size of about 8 um and less.

FIG. 28 illustrates x ray diffraction results for the ceramic sintered bodies of examples 1 through 4 of FIG. 26 as disclosed herein. Examples 1 and 4 depict formation of a ceramic sintered body comprising 100% of the YAG phase. Examples 2 and 3 comprise YAG and from 5 and 7% of the YAP phase.

### Example Five: (Sample 399, Powder 359-09) YAG Polycrystalline Ceramic Sintered Body, Low Temperature Calcination

A powder of yttria having a specific surface area of 2 to 3 m²/g, a d10 particle size of from 3 to 4 μm, a d50 particle size of from 6.5 to 7.5 μm and a d90 particle size of from 11.5 to 13 μm and a powder of alumina having a specific surface area of from 5.75 to 6.75 m²/g, a d10 particle size of from 0.10 to 0.2 μm, a d50 particle size of from 2 to 3.5 μm and a d90 particle size of from 15 to 30 μm were combined in a molar ratio to form a yttrium aluminum garnet (YAG) phase upon sintering. High purity alumina media (>99.99% as measured by ICPMS) was added at 50% loading by powder weight, and ethanol was added to form about a 40 volume % slurry. Ball milling using a rolling action about a horizontal axis was performed for a duration of 16 hours and thereafter the ethanol was extracted from the powder mixture using a rotary evaporator. Upon calcination at 850° C. for 6 hours in air, the calcined powder mixture was measured to have a specific surface area of from 4 to 5 m²/g, a d10 particle size of from 0.15 to 0.25 μm, a d50 particle size of from 5 to 7 μm and a d90 particle size of from 18 to 22 μm. X ray diffraction confirmed only yttria and alumina phases present in the calcined powder mixture according to Table 9. The powder mixture may be sieved, blended and/or milled at various process steps according to known methods. The calcined powder mixture was sintered at 1600° C. at a pressure of 20 MPa for 120 minutes under vacuum and thereafter annealed at 1400° C. for 8 hours in air to form a polycrystalline ceramic sintered body of 572 mm greatest dimension. Density measurements were performed in accordance with ASTM B962-17, and an average density of 4.458 g/cc was measured across 5 measurements, corresponding to 97.859% of theoretical density for YAG and volumetric porosity of 2.141% as calculated from density measurements. Tables 1, 8, 9, and 11 summarize results of the ceramic sintered body and calcined powder of example 5 according to embodiments as disclosed herein.

### Example Six: (Sample 195, Powder 194-2) YAG Polycrystalline Ceramic Sintered Body, High Temperature Calcine

A powder of yttria having a specific surface area of from 4.5 to 6 m²/g, a d10 particle size of from 2 to 3 μm, a d50 particle size of from 4 to 7 μm and a d90 particle size of from 7 to 8 μm and a powder of alumina having a specific surface area of from 5.5 to 6.5 m²/g, a d10 particle size of from 0.10 to 0.2 μm, a d50 particle size of from 2 to 3.5 μm and a d90 particle size of from 15 to 30 μm were combined in a molar ratio to form a yttrium aluminum garnet (YAG) phase upon sintering. High purity alumina media (>99.99% as measured by ICPMS) was added at 50% loading by powder weight, and ethanol was added to form about a 40 volume % slurry. Ball milling using a rolling action about a horizontal axis was performed for a duration of 12 hours and thereafter the ethanol was extracted from the powder mixture using a rotary evaporator. Upon calcination at 1000° C. for 10 hours in air, the calcined powder mixture was measured to have a specific surface area of from 4 to 5 m²/g, a d10 particle size of from 0.75 to 2 μm, a d50 particle size of from 26 to 32 μm and a d90 particle size of from 220 to 240 μm. The powder mixture may be sieved, blended and/or milled at various process steps according to known methods. X ray diffraction confirmed the presence of yttria, alumina and YAM (yttrium aluminum monoclinic) phases in the calcined powder mixture according to Table 9. The calcined powder mixture was sintered at 1500° C. at a pressure of 20 MPa for 30 minutes under vacuum and thereafter annealed at 1500° C. for 8 hours in air to form a ceramic sintered body of 150 mm dimension. Density measurements were performed in accordance with ASTM B962-17, and an average density of 4.492 g/cc was measured across 5 measurements, corresponding to 98.604% of theoretical density for YAG and volumetric porosity of 1.396% as calculated from density measurements. SEM results indicated a uniform microstructure depicting presence of only the YAG phase in the polycrystalline ceramic sintered body. Tables 1, 8, 9, and 11 summarize results of the ceramic sintered body and calcined powder of example 6 according to embodiments as disclosed herein.

### Example Seven: (Sample 93/Powder 092-1) YAG Polycrystalline Ceramic Sintered Body, High Temperature Calcine

A powder of yttria having a specific surface area of 6 to 8 m²/g, and an average d10 particle size of from 1.5 to 3.5 to μm, an average d50 particle size of 4.5 μm to 6.5 μm, and d90 average particle size of 6.5 to 8.5 μm, and a powder of alumina having a specific surface area of from 5 to 7 m²/g, a d10 particle size of from 0.10 to 0.5 μm, a d50 particle size of from 2 to 6 μm and a d90 particle size of from 15 to 40 μm were combined in a molar ratio to form a yttrium aluminum garnet (YAG) phase upon sintering. High purity alumina media (>99.99% as measured by ICPMS) was added at 50% loading by powder weight, and ethanol was added to form about a 40 volume % slurry. Ball milling using a rolling action about a horizontal axis was performed for a duration of 12 hours and thereafter the ethanol was extracted from the powder mixture using a rotary evaporator. Upon calcination at 1100° C. for 8 hours in air, the calcined powder mixture was measured to have a specific surface area of from 2.5 to 3 m²/g, a d10 particle size of from 1.5 to 3.5 μm, a d50 particle size of from 10 to 13 μm and a d90 particle size of from 180 to 220 μm. The powder mixture may be sieved, blended and/or milled at various process steps according to known methods. X ray diffraction as listed in Table 9 and according to pattern d) of FIG. 25 confirmed the presence of the YAP phase and about 10% and less by volume of YAG (yttrium aluminum garnet) (arrow indicators) phases in the calcined powder mixture. The calcined powder mixture was sintered at 1500° C. at a pressure of 30 MPa for 30 minutes under vacuum to form a ceramic sintered body of 150 mm dimension. Density measurements were performed in accordance with ASTM B962-17, and an average density of 4.544 g/cc was measured across 5 measurements, corresponding to 99.730% of theoretical density for YAG and volumetric porosity of 0.270% as calculated from density measurements. SEM results indicated a uniform microstructure depicting presence of only the YAG phase in the polycrystalline ceramic sintered body. Tables 1, 8, 9, and 11 summarize results of the ceramic sintered body and calcined powder mixture according to embodiments as disclosed herein.

### Example Eight: (Sample 258) YAG Polycrystalline Ceramic Sintered Body

A powder of yttria having a specific surface area of from 4.5 to 6 m²/g and a powder of alumina having a specific surface area of from 3.5 to 5 m²/g were combined in a molar ratio to form the yttrium aluminum garnet (YAG) phase upon sintering. High purity alumina media (>99.99% as measured by ICPMS) was added at 50% loading by powder weight, and ethanol was added to form about a 40 volume % slurry. Ball milling using a rolling action about a horizontal axis was performed for a duration of 12 hours and thereafter the ethanol was extracted from the powder mixture using a rotary evaporator. Upon calcination at 1000° C. for 10 hours in air, the calcined powder mixture was measured to have a specific surface area of from 7 to 8 m²/g, a d10 particle size of from 0.75 to 1.75 μm, a d50 particle size of from 90 to 110 μm and a d90 particle size of from 240 to 280 μm. The powder mixture may be sieved, blended and/or milled at various process steps according to known methods. The calcined powder mixture was sintered at 1550° C. at a pressure of 20 MPa for 60 minutes under vacuum to form a ceramic sintered body of 407 mm greatest dimension. Density measurements were performed in accordance with ASTM B962-17 across a greatest dimension of the sintered body, and an average density of 4.543 g/cc was measured across 135 measurements, corresponding to 99.709% of theoretical density for YAG and volumetric porosity of 0.291% as calculated from density measurements. The density was found to vary across the greatest dimension of the polycrystalline ceramic sintered body from 4.526 to 4.553 g/cc (or from 99.335 to 99.936% of theoretical for YAG) and the density variance was determined to be 0.601%. The polycrystalline ceramic sintered body had a thickness of 31 mm and the density variance across the thickness was measured, however it was determined to be less than accuracy of the methods used for measurement. Using the methods as disclosed herein, density measurements may have an accuracy of about 0.1%, thus density variation across the thickness of the ceramic sintered body may be 0.1% and less. SEM results indicated a uniform microstructure depicting presence of only the YAG phase in the polycrystalline ceramic sintered body. The SEM image of FIG. 31 reveals a highly dense and uniform microstructure depicting presence of only the YAG phase (dark gray) in the ceramic sintered body. Tables 1, 8, 9, 11 and 13 summarize results of the ceramic sintered body and calcined powder mixture according to embodiments as disclosed herein.

### Example Nine: (Sample 408/Powder 359-06) YAG Polycrystalline Ceramic Sintered Body Formed at Low Pressure

A powder of yttria having a specific surface area of 2 to 3 m²/g, a d10 particle size of from 3 to 4 μm, a d50 particle size of from 6.5 to 7.5 μm and a d90 particle size of from 11.5 to 13 μm and a powder of alumina having a specific surface area of from 5.75 to 6.75 m²/g, a d10 particle size of from 0.10 to 0.2 μm, a d50 particle size of from 2 to 3.5 μm and a d90 particle size of from 15 to 30 μm were combined in a molar ratio to form a yttrium aluminum garnet (YAG) phase with 0.5% by volume excess aluminum oxide upon sintering. High purity alumina media (>99.99% as measured by ICPMS) was added at 50% loading by powder weight, and ethanol was added to form about a 40 volume % slurry. Ball milling using a rolling action about a horizontal axis was performed for a duration of 12 hours and thereafter the ethanol was extracted from the powder mixture using a rotary evaporator. Upon calcination at 850° C. for 6 hours in air, the calcined powder mixture was measured to have a specific surface area of from 3.5 to 4.5 m²/g, a d10 particle size of from 0.3 to 0.6 μm, a d50 particle size of from 8 to 11 μm and a d90 particle size of from 20 to 24 μm. X ray diffraction confirmed only yttria and alumina phases present in the calcined powder mixture according to Table 9. The powder mixture may be sieved, blended and/or milled at various process steps according to known methods. The calcined powder mixture was sintered at 1600° C. at a pressure of 15 MPa for 90 minutes under vacuum and thereafter annealed at 1400° C. for 8 hours in air to form a polycrystalline ceramic sintered body of 572 mm greatest dimension comprising YAG with excess alumina to the extent it remains in the polycrystalline ceramic sintered body. Density measurements were performed in accordance with ASTM B962-17, and an average density of 4.378 g/cc was measured across 5 measurements, corresponding to 96.088% of theoretical density for YAG and volumetric porosity of 3.912% as calculated from density measurements. Tables 1, 8, 9, and 11 summarize results of the ceramic sintered body and calcined powder according to embodiments as disclosed herein.

### Example Ten: (Sample 395, 359-11) YAG Polycrystalline Ceramic Sintered Body

A powder of yttria having a specific surface area of 2 to 3 m²/g, a d10 particle size of from 3 to 4 μm, a d50 particle size of from 6.5 to 7.5 μm and a d90 particle size of from 11.5 to 13 μm and a powder of alumina having a specific surface area of from 5.75 to 6.75 m²/g, a d10 particle size of from 0.10 to 0.3 μm, a d50 particle size of from 2.5 to 5 μm and a d90 particle size of from 15 to 30 μm were combined in a molar ratio to form a yttrium aluminum garnet (YAG) phase upon sintering. High purity alumina media (>99.99% as measured by ICPMS) was added at 50% loading by powder weight, and ethanol was added to form about a 40 volume % slurry. Ball milling using a rolling action about a horizontal axis was performed for a duration of 16 hours and thereafter the ethanol was extracted from the powder mixture using a rotary evaporator. Upon calcination at 850° C. for 6 hours in air, the calcined powder mixture was measured to have a specific surface area of from 4 to 5 m²/g, a d10 particle size of from 0.15 to 0.25 μm, a d50 particle size of from 5 to 7 μm and a d90 particle size of from 18 to 21 μm. X ray diffraction confirmed only yttria and alumina phases present in the calcined powder mixture according to Table 9. The powder mixture may be sieved, blended and/or milled at various process steps according to known methods. The calcined powder mixture was sintered at 1600° C. at a pressure of 20 MPa for 90 minutes under vacuum to form a polycrystalline ceramic sintered body of 572 mm greatest dimension. Density measurements were performed in accordance with ASTM B962-17, and an average density of 4.389 g/cc was measured across 5 measurements, corresponding to 96.334% of theoretical density for YAG and volumetric porosity of 3.656% as calculated from density measurements. The density variation was measured across the greatest dimension and found to be 1.712%. Tables 1, 8, 9, 11 and 13 summarize results of the ceramic sintered body and calcined powder according to embodiments as disclosed herein.

### Example Eleven: Multilayer Sintered Ceramic Body of Large Dimension (YAG/ZTA Sample 421

A multilayer sintered ceramic body was formed from first and second powder mixtures. The first powder mixture comprised alumina and zirconia to form a particle composite of the crystalline phases of zirconia and alumina wherein the zirconia was present in an amount by volume of 16%. The second powder comprised alumina and yttria to form a layer comprising the YAG phase. The first powder mixture comprised an alumina powder wherein the alumina powder has a specific surface area of from 6 to 8 m²/g, a d10 particle size of from 0.05 to 0.15 um, a d50 particle size of from 0.2 to 0.5 um, a d90 particle size of from 0.4 to 1 um, and a zirconia powder having a surface area of from 6 to 8 m²/g, a d10 particle size of from 0.5 to 0.2 um, a d50 particle size of from 0.2 to 0.5 um, and a d90 particle size of from 1.2 to 3 um. Total impurity content of the alumina powder was from about 2 to 10 ppm. The zirconia powder comprised from about 2 to 4 mol % Hf and was stabilized with yttria in an amount of about 3 mol %. Hf and Y are not considered impurities in zirconia as disclosed herein. Excluding Hf and Y, the zirconia powder had total impurities of about 20 ppm. The powders were combined in ratios to form at least one particle composite layer upon sintering comprising about 16% by volume of zirconia and the balance alumina. Combining the alumina and zirconia powders to make a powder mixture was performed using the conventional powder preparation techniques of wet ball milling wherein high purity (>99.99%) alumina media was used at about 75 to 80% loading relative to powder weight. A slurry was formed at about 40 volume % by adding ethanol. The slurry was ball milled for about 20 hours at an RPM of about 150 and thereafter dried, tumbled, and sieved according to methods known to those skilled in the art to form the first powder mixture. The first powder mixture was calcined at 600° C. for 8 hours. The first calcined powder mixture had a specific surface area of from 6 to 8 m²/g. The first calcined powder mixture had total impurities of about 15 ppm and comprised about 14 ppm or less of Si and Mg in an amount of about 5 ppm or less. The powder mixture may be sieved, tumbled, blended, etc. as known to those skilled in the art.

The second powder mixture comprised an alumina powder wherein the alumina powder has a specific surface area of from 6 to 8 m²/g, a d10 particle size of from 0.05 to 0.15 um, a d50 particle size of from 0.2 to 0.5 um, a d90 particle size of from 0.4 to 1 um, and a yttria powder having a specific surface area of 2 to 3 m²/g, a d10 particle size of from 2 to 4 μm, a d50 particle size of from 6 to 8 μm and a d90 particle size of from 11 to 13 μm. Total impurity content of the alumina and yttria powders was from about 2 to 10 ppm. The powders were combined in ratios to form a corrosion resistant layer comprising YAG (yttrium aluminum oxide, garnet phase) upon sintering. Combining the alumina and yttria powders to make a second powder mixture was performed using the conventional powder preparation techniques of wet ball milling wherein high purity (>99.9%) media was used at about 60% loading relative to powder weight. A slurry was formed at about 40 volume % by adding ethanol. The slurry was milled for about 15 hours at an RPM of 150 and thereafter dried, tumbled, and sieved according to methods known to those skilled in the art to form the first powder mixture. The second powder mixture was calcined at 850° C. for 6 hours. The second calcined powder mixture had a specific surface area of from 2 to 4 m²/g, and a d50 particle size of from 9 to 13 um. The second calcined powder mixture had total impurities of about 8 ppm and may be sieved, tumbled, blended, etc. as known to those skilled in the art.

A die of a spark plasma sintering apparatus was lined with a graphite foil having properties as disclosed herein, and the die and each of upper and lower punches comprised a graphite material as disclosed herein. The first and second calcined powder mixtures were separately disposed to form at least two separate layers inside an inner volume of a spark plasma sintering tool having a gap width of from about 25 to about 45 μm whereby the gap is configured between an inwardly facing surface of at least one foil and an outer wall of each of an upper punch and a lower punch of the sintering apparatus.

The first and second calcined powder mixtures were sintered at a temperature of 1600° C. for 60 minutes at 15 MPa to form a multilayer sintered ceramic body having a greatest dimension of 572 mm corresponding to sample 421 of Table 11. Due to the multilayer structure comprising regions of different densities, density measurements were unable to be performed accurately on the multi-layered body.

An additional multilayer sintered ceramic body corresponding to sample 597 of Table 11 having a greatest dimension of 622 mm was prepared in accordance with this Example and sintered at 1625° C. for 60 minutes at 15 MPa.

### Example 12: Multilayer Sintered Ceramic Body Comprising at Least One YAG First Layer

A multilayer sintered ceramic body was formed from first, second and third powder mixtures. The first powder mixture comprised alumina and yttria combined in ratios to form a first layer 100 comprising YAG as disclosed herein. The second powder mixture comprised alumina and partially stabilized zirconia in ratios to form a zirconia toughened aluminum oxide (ZTA) second layer comprising about 16% by volume of partially stabilized zirconia as disclosed herein. The third powder mixture comprised a powder mixture of yttria, alumina and partially stabilized zirconia.

The first powder mixture comprised an alumina powder wherein the alumina powder has a specific surface area (SSA) of from 5.5 to 9 m²/g, a d10 particle size of from 0.05 to 1 um, a d50 particle size of from 2 to 6 um, a d90 particle size of from 15 to 30 um, and a yttria powder having a specific surface area of 1.75 to 3.5 m²/g, a d10 particle size of from 2 to 4 μm, a d50 particle size of from 5 to 9 μm and a d90 particle size of from 10 to 14 μm. Average impurity content of the alumina powder was about 6 ppm as measured across 3 powder lots, corresponding to a purity of about 99.9994% relative to 100% pure alumina. Average impurity content of the yttria powder was about 17 ppm as measured across 5 powder lots, corresponding to a purity of about 99.9983 relative to 100% pure yttria powder. Reporting limits to detect presence of lighter elements using ICPMS as disclosed herein are higher than reporting limits of heavier elements. In other words, heavier elements, such as from Sc and higher in atomic number, are detected with greater accuracy than those lighter elements, from for example Li to Ca. Use of ICPMS to detect lighter elements such as Li and Mg may be done within a confidence of about 2 ppm and greater. Si was not detected using ICPMS as known to those skilled in the art in the yttria and alumina powders and as such, the yttria and alumina powders comprise about 14 ppm or less of Si in the form of silica, and 2 ppm and less of Li and Mg, as, lithium fluoride and magnesia. The powders were combined in ratios to form a corrosion resistant first layer comprising YAG (yttrium aluminum oxide, garnet phase) upon sintering.

The yttria and alumina powders were combined in ratios to form an at least one first layer comprising YAG (yttrium aluminum oxide, garnet phase) upon sintering. Combining the alumina and yttria powders to make a first powder mixture was performed using the conventional powder preparation techniques of wet ball milling wherein high purity (>99.9%) media was used at from about 55% to about 65% loading relative to powder weight. A slurry was formed at from about 35% to about 45% by adding ethanol. The slurry was milled for about 15 hours at an RPM of 150 and thereafter dried, tumbled, and sieved according to methods known to those skilled in the art to form the first powder mixture. The first powder mixture was calcined at 850° C. for 6 hours. After calcination, the first powder mixture had a specific surface area of from 2 to 4 m²/g, and a d50 particle size of from 9 to 13 um. The first powder mixture had total impurities of about 8 ppm and comprised about 14 ppm or less of Si and about 2 ppm or less of Mg, in the form of silica and magnesia, each relative to the total powder weight.

The second powder mixture comprised an alumina powder and a partially stabilized zirconia (PSZ) powder.

The alumina powder had a specific surface area (SSA) of from 6.5 to 8.5 m²/g, a d10 particle size of from 0.05 to 0.15 um, a d50 particle size of from 0.16 to 0.35 um, and a d90 particle size of from 0.36 to 0.8 um. Total impurity content of the alumina powder was from about 2 to about 11 ppm as measured using ICPMS methods. Li and Mg were measured in amounts of less than 1 ppm in the powder and as such, the alumina powder comprised about 1 ppm and less of Li and Mg, in the form of Li₂O, LiF and MgO. Calcium (CaO) was measured in an amount of less than 2 ppm. Si was not detected using ICPMS as disclosed herein in the zirconia powder and as such, the alumina powder comprised about 14 ppm or less of Si in the form of SiO₂.

The partially stabilized zirconia (PSZ) powder had a surface area of from 6 to 8 m²/g, a d10 particle size of from 0.08 to 0.25 um, a d50 particle size of from 0.27 to 0.60 um, and a d90 particle size of from 1.0 to 3.0 um. The PSZ powder comprised from about 2 to 4 weight % Hf and was partially stabilized with yttria in an amount of about 3 mol %. Hf and Y are not considered impurities in zirconia as disclosed herein. Hf is present in many commercially available zirconia powders, and yttria was added as a stabilizing compound in order to partially stabilize the zirconia. Excluding Hf and Y, the partially yttria stabilized zirconia powder had total impurities of about 61 ppm relative to the total powder mass. Use of ICPMS to detect lighter elements such as Li, Ca and Mg may be done within a confidence of about 1 ppm and greater. Li and Mg were measured in amounts of less than 1 ppm in the PSZ powder and as such, the partially stabilized zirconia powder comprised about 1 ppm and less of Li and Mg, in the form of Li₂O, LiF and MgO relative to the total powder mass. Calcium (CaO) was measured in an amount of about 15 ppm relative to the total powder mass. Si was not detected using ICPMS as disclosed herein in the PSZ powder and as such, the PSZ powder comprised about 14 ppm or less of Si in the form of silica relative to the total powder mass.

The powders comprising the second powder mixture were combined in ratios to form at least one second layer 102 upon sintering comprising about 16% by volume of partially yttria stabilized (PYSZ) zirconia and the balance alumina. Combining the alumina and PYSZ zirconia powders to make the second powder mixture was performed using the conventional powder preparation techniques of wet ball milling wherein high purity (>99.99%) alumina media was used at about 75 to 80% loading relative to powder weight. A slurry was formed at about 40 volume % by adding ethanol. The slurry was ball milled for about 20 hours at an RPM of about 150 and thereafter dried, tumbled, and sieved according to methods known to those skilled in the art to form the first powder mixture. The second powder mixture was calcined at 600° C. for 8 hours in air. The second calcined powder mixture had a specific surface area of from 6 to 8 m²/g. The second calcined powder mixture had total impurities of about 12 ppm (excluding Hf and Y) and comprised about 14 ppm or less of Si in the form of silica, and about 3 ppm or less of magnesia, MgO, each relative to the total powder mass. The second powder mixture was sieved, tumbled, blended, etc. as known to those skilled in the art.

To make the third powder mixture, about 6 wt % yttria, about 73 wt % alumina, and about 21 wt % of 3 mol % yttria partially stabilized zirconia were combined in ratios to form the multiple phase, at least one third layer 103 upon sintering. Combining the powders to make the third powder mixture was performed using a wet ball milling process wherein high purity (>99.99%) alumina media was added at from about 75% to about 80% loading relative to powder weight. A slurry was formed at about 35 to 45% relative to slurry weight by adding ethanol. The slurry was ball milled for about 20 hours at an RPM of about 150 and thereafter dried, tumbled, and sieved according to methods known to those skilled in the art to form the second powder mixture. The third powder mixture was calcined at 900° C. for 8 hours and was measured to have a specific surface area of from 6 to 8 m²/g. In certain embodiments, the calcination conditions as disclosed herein may result in formation of crystalline phases and agglomeration of the powder mixtures and thus greater variability in particle size distributions overall and in particular larger variance and overall d50 and d90 particle sizes may result. Lot to lot variation and management of heat transfer during calcination may also contribute to particle size distributions. Thus, a broad range of particle size distributions, and in particular d50 and d90 particle sizes, of the powder mixtures may result.

First, second and third powder mixtures may be calcined, sieved, tumbled, blended, etc. as known to those skilled in the art.

First, second and third powder mixtures were separately disposed inside a volume defined by a tool set of a sintering apparatus to form at least one layer of the first powder mixture, at least one layer of the second powder mixture, and at least one layer of the third powder mixture, and creating vacuum conditions of 10⁻² to 10⁻³ torr inside the volume. Disposing the at least one first, second and third powder mixtures inside the volume defined by the tool set typically results in intermixing of the first, second and third powder mixtures, thereby creating a nonlinear interface 104 between the at least one first and second layers, and second interface 105 between the at least one second and third layers upon sintering.

The layers of the powder mixtures were co-compacted by applying a pressure of 15 MPa to the layers of the first, second and third powder mixtures while heating to a sintering temperature of 1625° C. for 60 minutes, wherein the at least one layer of the first powder mixture forms at least one first layer 100, the at least one layer of the second powder mixture forms at least one second layer 102, and the at least one layer of the third powder mixture forms at least one third layer 103, thus forming a unitary, multilayer sintered ceramic body having a greatest dimension of 572 mm.

Density was separately measured for an exemplary partially yttria stabilized zirconia sintered body (prepared under similar conditions of temperature, pressure and duration to that as disclosed herein) comprising about 16% by volume of PSZ and the balance alumina, and the density was measured to be about 4.319 g/cc, corresponding to about 100% of theoretical density (the theoretical density was calculated to be about 4.317 g/cc using the volumetric mixing rule as known to those skilled in the art). The two measurements are within the measurement variance for the Archimedes density measurements as disclosed herein, thus the PSZ comprising the at least one second layer may have a density of about 100% of theoretical.

Density was separately measured for an exemplary YAG sintered body (prepared under similar conditions of temperature, pressure and duration to that as disclosed herein) and the density was measured to be 4.55 g/cc, corresponding to greater than 99% of the theoretical density of YAG (a commercially available, single crystal sample of bulk YAG was measured to have an Archimedes density of 4.56 g/cc across 5 measurements, and this value is taken as the theoretical density of YAG as used herein). The two measurements are within the measurement variance for the Archimedes density measurements as disclosed herein, thus the polycrystalline YAG comprising the at least one first layer may have a density of about 100% of theoretical. The multilayer sintered ceramic body according to this example is CTE matched to the at least one first layer 100 comprising YAG and the at least one second layer.

### Example 13: Multilayer Sintered Ceramic Body Comprising a YAG First Layer and Zirconia Toughened Alumina (ZTA) Second Layer

A multilayer sintered ceramic body was formed from first and second powder mixtures. The first powder mixture comprised alumina and yttria combined in ratios to form at least one first layer 100 comprising YAG as disclosed herein. The second powder mixture comprised alumina and partially stabilized zirconia (partially stabilized zirconia as disclosed according to Example 1) in ratios to form a zirconia toughened aluminum oxide (ZTA) at least one second layer comprising about 16% by volume of partially stabilized zirconia as disclosed herein.

The yttria and alumina powders in accordance with Example 2 are as disclosed within Example 1 and were used to form the first powder mixture. Combining the alumina and yttria powders in accordance with this example to make the first powder mixture was performed using tumble (or vertical/end-over-end) mixing as known to those skilled in the art, wherein high purity (>99.9%) alumina media was used at from 80% to 100% media loading relative to powder weight. Ethanol was added to form a slurry at from about 35% to about 45% relative to slurry weight. The slurry was mixed for about 20 hours at an RPM of about 20, and thereafter dried, tumbled, and sieved according to methods known to those skilled in the art to form the first powder mixture. The first powder mixture was calcined at 950° C. for 4 hours. The first calcined powder mixture had a specific surface area of from 5 to 7 m²/g, and a d50 particle size of from 5 to 20 um. The first calcined powder mixture had total impurities (as measured using ICPMS) of about 5 ppm, comprising about 2 ppm or less of Ca (CaO) and K, and at or below the reporting limits (less than for example 1 ppm) for all other elements, including Mg in the form of magnesia MgO, and Li in the form of Li₂O and LiF. Si was not detected using the ICPMS methods as disclosed herein in the first calcined powder mixture, thus within the accuracy of the ICPMS method, the first calcined powder mixture comprises about 14 ppm or less of Si in the form of silica. The first calcined powder mixture (batched to form YAG upon sintering) may be sieved, tumbled, blended, etc. as known to those skilled in the art.

The partially stabilized zirconia (PSZ) and alumina powders as disclosed in accordance with Example 1 were used to form the second powder mixture. Combining the alumina and PSZ powders in accordance with this example to make the second powder mixture was performed using tumble (or vertical/end-over-end) mixing as known to those skilled in the art, wherein high purity (>99.9%) alumina media was used at from 70% to 90% loading relative to powder weight. Ethanol was added to form a slurry at from about 40% to about 50% relative to slurry weight. The slurry was mixed for between from 16 to 24 hours at an RPM of about 20, and thereafter dried, tumbled, and sieved according to methods known to those skilled in the art to form the second powder mixture. The second powder mixture was calcined at 900° C. for 8 hours. The second calcined powder mixture had a specific surface area of from 6 to 8 m²/g, and a d50 particle size of from 90 to 110 um. The second calcined powder mixture had total impurities (as measured using ICPMS and excluding Hf and Y) of about 12 ppm, comprising about 3 ppm or less of Mg in the form of magnesia MgO, about 4 ppm of Ti, and about 0.75 ppm and less of all other elements, including Li in the form of Li₂O and LiF. Si was not detected using the ICPMS methods as disclosed herein in the second calcined powder mixture, thus within the accuracy of the ICPMS method, the second calcined powder mixture comprises about 14 ppm or less of Si in the form of silica. The second calcined powder mixture (batched to form about 16% by volume of PSZ upon sintering) may be sieved, tumbled, blended, etc. as known to those skilled in the art.

The first and second calcined powder mixtures were separately disposed inside a volume defined by a tool set of a sintering apparatus as disclosed herein to form at least one first layer of the first calcined powder mixture, and at least one second layer of the second calcined powder mixture, and vacuum conditions of from 10⁻² to 10⁻³ torr were created inside the volume.

Disposing the at least one first and at least one second calcined powder mixtures inside the volume defined by the tool set typically results in intermixing of the first and second calcined powder mixtures, thereby creating a nonlinear interface between the at least one first and second layers upon sintering.

The layers of the calcined powder mixtures were co-compacted by applying a pressure of 20 MPa was applied to the layers of first and second calcined powder mixtures while heating to a sintering temperature of 1500° C. for a duration of 30 minutes to perform sintering and form a unitary, multilayer sintered ceramic body having a greatest dimension of 150 mm.

The sintered ceramic bodies are machined into components for use in a plasma etch chamber such as, for example, a dielectric window, a showerhead, ant number of process rings, and a gas distribution nozzle.

### Miscellaneous Examples

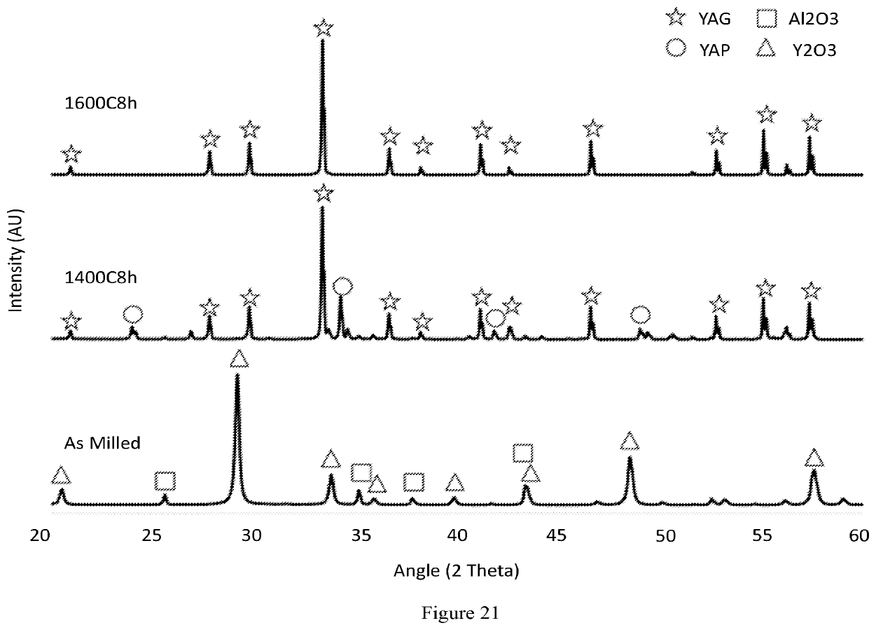

FIG. 21 depicts x ray diffraction results for a starting yttria/alumina powder mixture and ceramic sintered bodies formed using pressureless sintering methods. As illustrated, a mixed phase sintered body comprising YAP and YAG results from pressureless sintering at 1400° C. for 8 hours. In order to obtain phase-pure yttrium aluminum garnet (YAG) phase, pressureless sintering temperatures of 1600° C. and higher, combined with sintering durations of 8 hours or more are required. Geometric densities were measured for this sample and found to be about 55%. Use of pressureless sintering methods at elevated temperatures for long (8 hours and more) durations as known in the art results in densities and grain sizes that may not impart sufficient mechanical properties such as strength, hardness and fracture toughness to enable the sintered bodies useful as components in semiconductor etch and deposition chambers. As such, a pressure and current assisted sintering method as disclosed herein is required in order to form phase pure, high (>97%) density/low porosity (<3%) ceramic sintered bodies comprising YAG.

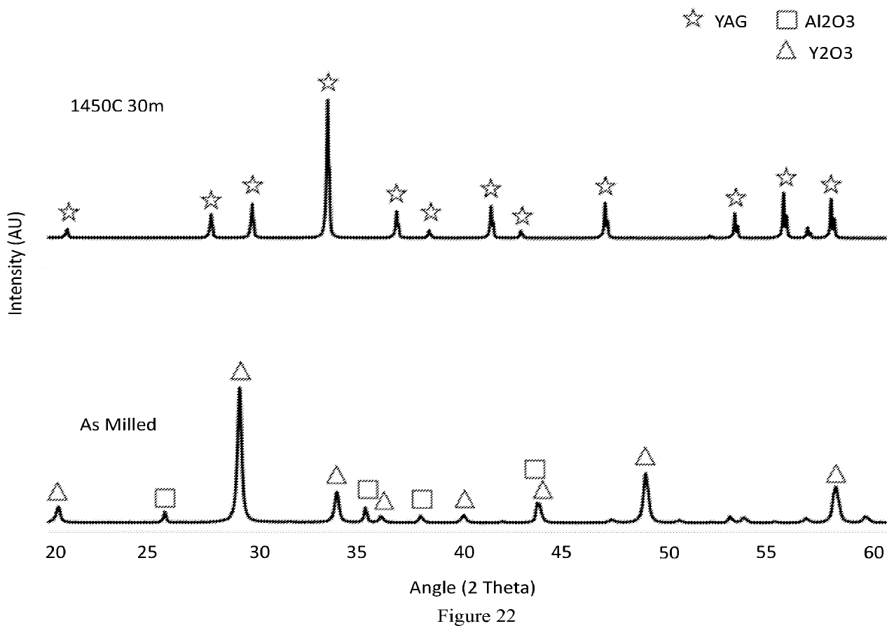

FIG. 22 depicts x ray diffraction results illustrating formation of a ceramic sintered body comprising about 100% of yttrium aluminum garnet (YAG) phase from yttria and alumina powders using sintering conditions of 1450° C. for 30 minutes at 30 MPa under vacuum in accordance with the method disclosed herein.

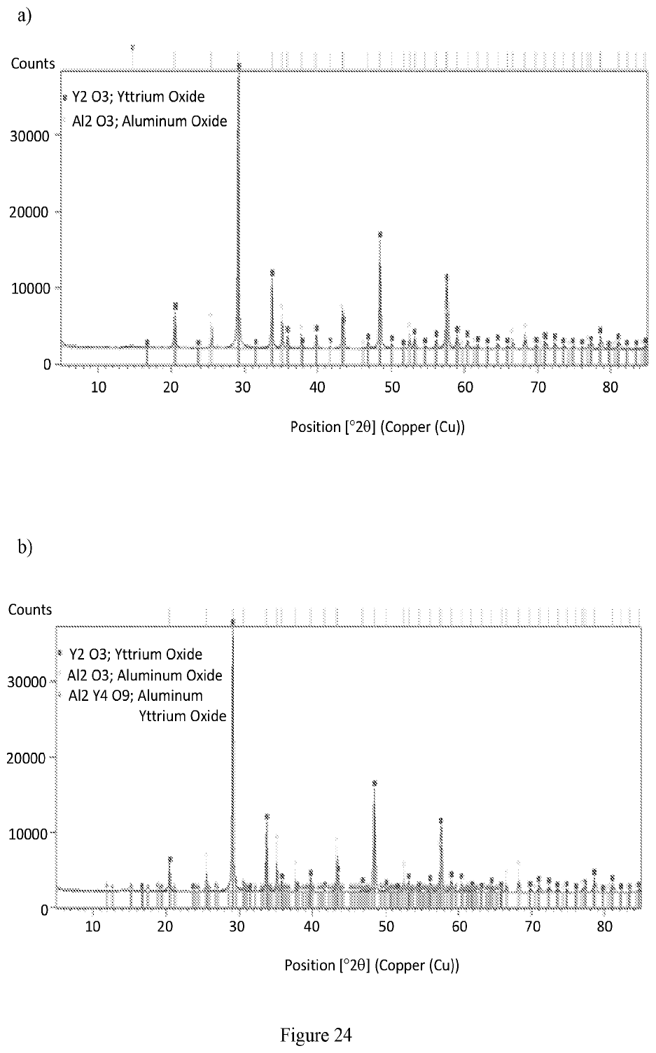

FIG. 24 illustrates x ray diffraction results for calcined powder mixtures calcined at a) 950° C. for 8 hours (powder 008) and b) 1000° C. for 10 hours in air (powder 194-2). With respect to calcined powder mixture 008 depicted in FIG. 24 a), the crystalline phases from the starting powders of yttria and alumina are present after calcination, and the powder has a specific surface area of 2.5 to 3.5 m²/g. For calcined powder mixture 194-2 depicted in FIG. 24 b), the crystalline phases from the starting powders of yttria and alumina are present, and a crystalline phase of YAM was further detected after calcination. The powder had a specific surface area of 4 to 5 m²/g.

FIG. 29 a) depicts SEM results at 1000× for sample 153 having 150 mm diameter, comprising YAG which was prepared to have excess alumina, the sample having an Archimedes density of 4.541 g/cc or 99.674% of theoretical for YAG, and volumetric porosity of 0.33%. All SEM images of the ceramic sintered body and powder mixtures disclosed herein were obtained from a Nano Science Instruments scanning electron microscope (SEM) model Phenom XL equipped with an energy-dispersive X-ray spectroscopy (EDS/EDX) detector. SEM images allow for phase identification to about +/−1% by area of the ceramic sintered body as disclosed herein. The ceramic sintered body comprising YAG made according to the process disclosed herein is an integral body. As such, phase purity and other features measured on a surface may be representative of phase purity and other features within the bulk, or volume of, the ceramic sintered body. In alternate embodiments, the ceramic sintered body disclosed herein comprising YAG may have an excess aluminum oxide phase up to and including 3% by volume, and as such, an aluminum oxide phase measured on a surface may be representative of an aluminum oxide phase present within the bulk ceramic sintered body comprising YAG and excess alumina. In other words, features such as porosity, grain size, amounts of crystalline phases, among others measured on a surface may be representative of these features within the bulk yttrium oxide body to within about +/−1% by volume.

SEM images for sample 153 were imported into ImageJ Software for phase analysis using thresholding techniques as depicted in FIG. 29 b). ImageJ has been developed at the National Institute of Health (NIH), USA, and is a Java-based public domain image processing and analysis program for image processing of scientific multi-dimensional images. Using SEM images combined with ImageJ processing software, SEM images of sample 153, a ceramic sintered body comprising yttrium aluminum garnet (YAG) having excess aluminum oxide was analyzed for phase purity. The combination of these analytical tools provides for the determination of phase purity to about 0.1%. FIG. 29 b) depicts the same region within the ceramic sintered body as FIG. 29 a) after ImageJ analysis, whereby regions of the aluminum oxide phase are shown in black from EDS/EDX analysis. As illustrated in FIG. 29 b), the area of regions depicted in black, representing aluminum oxide, comprise about 0.40% by area and having a diameter of from about 1 to 10 um, preferably from about 1 to 5 um, more preferably from about 1 to 3 um as compared to the reference scale in FIG. 29 b). The starting powders of yttria and alumina, and the calcined powder mixtures may be mixed/blended/sieved prior to sintering, thus the ceramic sintered body as disclosed herein will have features measured on the surface which are indicative of the bulk or volume of the sintered body. As such, features and properties of a surface may be representative of a structure and properties within a volume of the bulk ceramic sintered body. Results from image analysis of FIG. 29 b) verify that the ceramic sintered body comprises about 99.6% YAG phase by volume and an excess alumina phase (black regions) of about 0.4% by volume. XRD results according to FIG. 30 further confirm formation of the YAG phase.

FIG. 30 illustrates x ray diffraction results for the ceramic sintered body of FIG. 29 a) and b) confirming formation of a ceramic sintered body having the YAG phase in an amount up to and including 99.6%. Aluminum oxide phase was confirmed via SEM and image analysis at 5000× as described in FIG. 29. Table 11 lists the processing conditions for formation of sample 153.

FIG. 31 depicts an SEM micrograph corresponding to sample 258 as listed in Tables 1 and 11, also in accordance with Example 8. A highly dense microstructure is illustrated, having minimal volumetric porosity.

A number of embodiments have been described as disclosed herein. Nevertheless, it will be understood that various modifications may be made without departing from the spirit and scope of the embodiments as disclosed herein. Accordingly, other embodiments are within the scope of the following claims.

1-60. (canceled)

61. A process ring for use in a plasma vacuum processing chamber, the process ring comprising:
an annular body comprising
at least one first layer comprising a surface having a surface area and at least one crystalline phase of from 90% to 99.8% by volume of polycrystalline yttrium aluminum garnet (YAG),
at least one second layer comprising alumina and zirconia wherein the zirconia comprises at least one of stabilized and partially stabilized zirconia, and
optionally, at least one third layer comprising at least one selected from the group consisting of YAG, alumina, and zirconia,
wherein the at least one second layer is disposed between the at least one first layer and the at least one third layer,
wherein an absolute value of the difference in coefficient of thermal expansion (CTE) between the at least one first, second and third layers is from 0 to 0.75×10⁻⁶/° C. as measured in accordance with ASTM E228-17, and
wherein the at least one first, second and third layers form a unitary sintered ceramic body; and
an opening surrounded by the annular body, wherein the surface comprises pores having a pore size not exceeding 5 μm and having a maximum pore size of 1.5 μm for at least 95% of the pores,
wherein the pores occupy less than 0.2% of the surface area.

62. The process ring of claim 61 wherein the polycrystalline yttrium aluminum garnet comprises pores having a pore size not exceeding 1.75 μm for at least 97% or more of all pores.

63. The process ring of claim 61 wherein the at least one polycrystalline yttrium aluminum garnet has a maximum pore size not exceeding 2 μm for at least 99% or more of all pores.

64. The process ring according to claim 61 wherein the polycrystalline yttrium aluminum garnet has a volumetric porosity of from 0.1 to 3%.

65. The process ring according to claim 61-wherein the pores occupy less than 0.15% of the surface area.

66. The process ring according to claim 61 wherein the pores occupy less than 0.10% of the surface area.

67. A showerhead assembly of a plasma vacuum processing chamber, the showerhead assembly comprising:
a. a backplate portion comprising at least one gas inlet;
b. a frontplate portion opposite the backplate portion, wherein the frontplate portion comprises a plurality of gas distribution holes; and
c. an inner volume in communication with the gas distribution holes and the gas inlet,
wherein the backplate portion and the frontplate portion each comprise at least one first layer comprising a surface having a surface area and at least one crystalline phase of from 90% to 99.8% by volume of polycrystalline yttrium aluminum garnet (YAG),
at least one second layer comprising alumina and zirconia wherein the zirconia comprises at least one of stabilized and partially stabilized zirconia, and
optionally, at least one third layer comprising at least one selected from the group consisting of YAG, alumina, and zirconia, wherein the at least one second layer is disposed between the at least one first layer and the at least one third layer,
wherein an absolute value of the difference in coefficient of thermal expansion (CTE) between the at least one first, second and third layers is from 0 to 0.75×10⁻⁶/° C. as measured in accordance with ASTM E228-17,
wherein the at least one first, second and third layers form a unitary sintered ceramic body, and wherein the polycrystalline yttrium aluminum garnet comprises pores on the surface wherein the pores have a pore size not exceeding 5 μm and have a maximum pore size of 1.5 μm for at least 95% of the pores,
wherein the pores occupy less than 0.2% of the surface area.

68. The showerhead assembly according to claim 67 wherein the polycrystalline yttrium aluminum garnet has a volumetric porosity of from 0.1 to 3%.

69. The showerhead assembly according to claim 68 wherein the polycrystalline yttrium aluminum garnet (YAG) is present in an amount of from 90 to 99.8% by volume.

70. The showerhead assembly according to claim 67 wherein the polycrystalline yttrium aluminum garnet is present in an amount of from 93 to 99.8% by volume.

71. The showerhead assembly according to claim 67 wherein the polycrystalline yttrium aluminum garnet has a purity of 99.995% or higher as measured using ICPMS.

72. The showerhead assembly according to claim 67 wherein the pores occupy less than 0.15% of the surface area.

73. The showerhead assembly according to claim 67 wherein the pores occupy less than 0.10% of the surface area.

74. A dielectric window for use in a plasma vacuum processing chamber, the dielectric window comprising:
a body comprising at least one first layer comprising a surface having a surface area and at least one crystalline phase of from 90% to 99.8% by volume of polycrystalline yttrium aluminum garnet (YAG),
at least one second layer comprising alumina and zirconia wherein the zirconia comprises at least one of stabilized and partially stabilized zirconia, and
optionally, at least one third layer comprising at least one selected from the group consisting of YAG, alumina, and zirconia,
wherein the at least one second layer is disposed between the at least one first layer and the at least one third layer,
wherein an absolute value of the difference in coefficient of thermal expansion (CTE) between the at least one first, second and third layers is from 0 to 0.75×10⁻⁶/° C. as measured in accordance with ASTM E228-17,
wherein the at least one first, second and third layers form a unitary sintered ceramic body, and wherein the polycrystalline yttrium aluminum garnet comprises pores on the surface wherein the pores occupy less than 0.2% of the surface area.

75. The dielectric window of claim 74 wherein the polycrystalline yttrium aluminum garnet comprises pores having a pore size not exceeding 1.75 iim for at least 97% or more of all pores.

76. The dielectric window of claim 74 wherein the at least one polycrystalline yttrium aluminum garnet has a maximum pore size not exceeding 2 μm for at least 99% or more of all pores.

77. The dielectric window according to claim 74 wherein the polycrystalline yttrium aluminum garnet has a volumetric porosity of from 0.1 to 3%.

78. The dielectric window according to claim 77 wherein the volumetric porosity is from 0.1 to 2%.

79. The dielectric window according to claim 74 wherein the pores occupy less than 0.15% of the surface area.

80. The dielectric window according to claim 74 wherein the pores occupy less than 0.10% of the surface area.
